(19) United States
(12) Patent Application Publication
(10) Pub. No.: US 2010/0283536 A1
(43) Pub. Date: Nov. 11, 2010

(54) SYSTEM, APPARATUS, METHOD AND PROGRAM FOR SIGNAL ANALYSIS CONTROL, SIGNAL ANALYSIS AND SIGNAL CONTROL

(75) Inventors: Toshiyuki Nomura, Tokyo (JP); Osamu Shimada, Tokyo (JP); Akihiko Sugiyama, Tokyo (JP); Osamu Hoshuyama, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC Corporation, Minato-ku, Tokyo (JP)

(21) Appl. No.: 12/812,437

(22) PCT Filed: Dec. 26, 2008
(86) PCT No.: PCT/JP2008/073698

§ 371 Date: Jul. 9, 2010

(30) Foreign Application Priority Data
Jan. 11, 2008 (JP) 2008-003933

(51) Int. Cl. H03B 1/00; H03H 11/40; G01R 13/34

(52) U.S. Cl. 327/551; 327/524; 324/76.38

(57) ABSTRACT

A signal analysis control system is provided with a signal analyzing section for analyzing signals inputted to a transmission section and generating analysis information, and a signal control section for controlling signals inputted to a receiving section by using the analysis information.

### APPLICABLE FIELD IN THE INDUSTRY

The present invention relates to a method of a signal analysis and a signal control for controlling an input signal, which is configured of a plurality of sound sources, for each component element being included in the signal, its apparatus, and its computer program.

### BACKGROUND ART

As a system for suppressing background noise of an input signal having a plurality of sound sources each of which is configured of desired sound and background noise, a noise suppression system (hereinafter, referred to as a noise suppressor) is known. The noise suppressor is a system for suppressing noise superposed upon a desired sound signal. The noise suppressor, as a rule, estimates a power spectrum of a noise component by employing an input signal converted in a frequency region, and subtracts the estimated power spectrum of the noise component from the input signal. With this, the noise coexisting in the desired sound signal is suppressed. In addition, these noise suppressors are applied also for the suppression of non-constant noise by successively estimating the power spectrum of the noise component. There exists, for example, the technique described in Patent document 1 as a prior art related to these noise suppressors (hereinafter, referred to as a first related prior art).

Normally, the noise suppressor of the first related prior art, which is utilized for communication, fulfils a function as a pretreatment of an encoder. An output of the noise suppressor is encoded, and is transmitted to a communication path. In a receiving unit, the signal is decoded, and an audible signal is generated. In a one-input noise suppression system of the first related prior art, as a rule, residual noise that stays as a result of being not suppressed, and distortion of emphasized sound that is outputted are in a relation of trade-off. Reducing the residual noise leads to an increase in the distortion, and reducing the distortion leads to an increase in the residual noise. The best status of a balance between the residual noise and the distortion differs dependent upon individual users. However, with a configuration in which the noise suppressor exists in the upstream side of the encoder, namely, exists in a transmission unit, the user cannot adjust a balance between the residual noise and the distortion to its own taste.

As a noise suppressor assuming a configuration capable of solving this problem, a receiving side noise suppressor shown in FIG. 69 disclosed in Non-patent document 1 is known (hereinafter, referred to as a second related prior art). In the configuration of the second related prior art, a noise suppression unit 9501 is included not in the transmission unit, but in the receiving unit. The noise suppression unit 9501 performs a process of suppressing the noise of the signal inputted from a decoder. This enables the user to adjust a balance between the residual noise and the distortion to its own taste.

Patent document 1: JP-P2002-204175A

Non-patent document 1: IEEE INTERNATIONAL CONFERENCE ON CONSUMER ELECTRONICS, 6.1-4, January 2007

### DISCLOSURE OF THE INVENTION

### Problems to be Solved by the Invention

The foregoing first related prior art causes a problem that the user cannot adjust a balance between the residual noise and the distortion to its own taste. The foregoing second related prior art exists as a means for solving this problem.

However, the second related prior art causes a problem that an arithmetic quantity of the receiving unit is augmented because the receiving unit performs a process of suppressing the noise, which the transmission unit performs in the first related prior art. In addition, the second related prior art causes a problem that a noise suppression function cannot be incorporated when an important function other than the function of the noise suppressor exists in the receiving unit, or a problem that the other functions cannot be incorporated due to the incorporation of the noise suppression function. The reason is that a limit is put to a total of the arithmetic quantity of the receiving unit. Further, the arithmetic quantity of the receiving unit (or a reproduction unit) is much, which incurs a decline in a sound quality and in convenience due to a limit put to a receiver function. In addition, there is a problem that the configurations as well of the first related prior art and the second related prior art cannot be applied for general separation of the signal because they aim for separating the sound from the background noise.

Thereupon, the present invention has been accomplished in consideration of the above-mentioned problems, and an object thereof is to provide a signal analysis control system capable of configuring the receiving unit with a small arithmetic quantity, and of independently controlling all sorts of the input signals for each of elements constituting the input signal.

### Means to Solve the Problem

The present invention for solving the above-mentioned problems is a signal analysis method, comprising: generating analysis information including component element control information for controlling a component element of a signal including a plurality of component elements and a correction value for correcting said component element control information; and multiplexing said signal and said analysis information and generating a multiplexed signal.

In addition, the present invention for solving the above-mentioned problems is a signal control method, comprising: receiving a multiplexed signal including a signal including a plurality of component elements, and analysis information including component element control information for controlling a component element of said signal and a correction value for correcting said component element control information; generating said signal and said analysis information from said multiplexed signal; correcting said component element control information based upon said correction value; and controlling the component element of said signal based upon said corrected component element control information.

In addition, the present invention for solving the above-mentioned problems is a signal control method, comprising: receiving a multiplexed signal including a signal including a plurality of component elements, and analysis information including component element control information for controlling a component element of said signal and a correction value for correcting said component element control information, and component element rendering information; generating said signal and said analysis information from said multiplexed signal; correcting said component element control information based upon said correction value being included in said analysis information; and controlling the component element of said signal based upon said corrected component element control information and said component element rendering information.

In addition, the present invention for solving the above-mentioned problems is a signal analysis control method, comprising: generating analysis information including component element control information for controlling a component element of a signal including a plurality of component elements and a correction value for correcting said component element control information; multiplexing said signal and said analysis information, and generating a multiplexed signal; receiving said multiplexed signal; generating said signal and said analysis information from said multiplexed signal; correcting said component element control information based upon said correction value; and controlling the component element of said signal based upon said corrected component element control information.

In addition, the present invention for solving the above-mentioned problems is a signal analysis control method, comprising: generating analysis information including component element control information for controlling a component element of a signal including a plurality of component elements and a correction value for correcting said component element control information; multiplexing said signal and said analysis information, and generating a multiplexed signal; receiving said multiplexed signal and component element rendering information; generating said signal and said analysis information from said multiplexed signal; correcting said component element control information based upon said correction value; and controlling the component element of said signal based upon said corrected component element control information and said component element rendering information.

In addition, the present invention for solving the above-mentioned problems is a signal analysis apparatus, comprising: a signal analysis unit for generating analysis information including component element control information for controlling a component element of a signal including a plurality of component elements and a correction value for correcting said component element control information; and a multiplexing unit for multiplexing said signal and said analysis information and generating a multiplexed signal.

In addition, the present invention for solving the above-mentioned problems is a signal control apparatus, comprising: a multiplexed signal separation unit for, from a multiplexed signal including a signal including a plurality of component elements, and analysis information including component element control information for controlling a component element of said signal and a correction value for correcting said component element control information, generating said signal and said analysis information; a component element control information correction unit for correcting said component element control information based upon said correction value; and a signal control unit for controlling the component element of said signal based upon said corrected component element control information.

In addition, the present invention for solving the above-mentioned problems is a signal control apparatus, comprising: a multiplexed signal separation unit for, from a multiplexed signal including a signal including a plurality of component elements, and analysis information including component element control information for controlling a component element of said signal and a correction value for correcting said component element control information, generating said signal and said analysis information; a component element control information correction unit for correcting said component element control information based upon said correction value being included in said analysis information; and a signal control unit for receiving component element rendering information, and controlling the component element of said signal based upon said corrected component element control information and said component element rendering information.

In addition, the present invention for solving the above-mentioned problems is a signal analysis control system including a signal analysis apparatus and a signal control apparatus: wherein said signal analysis apparatus comprises: a signal analysis unit for generating analysis information including component element control information for controlling a component element of a signal including a plurality of component elements and a correction value for correcting said component element control information; and a multiplexing unit for multiplexing said signal and said analysis information and generating a multiplexed signal; and wherein said signal control apparatus comprises: a multiplexed signal separation unit for generating said signal and said analysis information from said multiplexed signal; a component element control information correction unit for correcting said component element control information based upon said correction value; and a signal control unit for controlling the component element of said signal based upon said corrected component element control information.

In addition, the present invention for solving the above-mentioned problems is a signal analysis control system including a signal analysis apparatus and a signal control apparatus: wherein said signal analysis apparatus comprises: a signal analysis unit for generating analysis information including component element control information for controlling a component element of a signal including a plurality of component elements and a correction value for correcting said component element control information; and a multiplexing unit for multiplexing said signal and said analysis information, and generating a multiplexed signal; and wherein said signal control apparatus comprises: a multiplexed signal separation unit for generating said signal and said analysis information from said multiplexed signal; a component element control information correction unit for correcting said component element control information based upon said correction value; and a signal control unit for receiving component element rendering information, and controlling the component element of said signal based upon said corrected component element control information and said component element rendering information.

In addition, the present invention for solving the above-mentioned problems is a signal analysis program for causing a computer to execute: a signal analysis process of generating analysis information including component element control information for controlling a component element of a signal including a plurality of component elements and a correction value for correcting said component element control information; and a multiplexing process of multiplexing said signal and said analysis information and generating a multiplexed signal.

In addition, the present invention for solving the above-mentioned problems is a signal control program causing a computer to execute: a multiplexed signal separation process of, from a multiplexed signal including a signal including a plurality of component elements, and analysis information including component element control information for controlling a component element of said signal and a correction value for correcting said component element control information, generating said signal and said analysis information; a component element control information correction process of correcting said component element control information based upon said correction value; and a signal control process of controlling the component element of said signal based upon said corrected component element control information.

In addition, the present invention for solving the above-mentioned problems is a signal control program for causing a computer to execute: a multiplexed signal separation process of, from a multiplexed signal including a signal including a plurality of component elements, and analysis information including component element control information for controlling a component element of said signal and a correction value for correcting said component element control information, generating said signal and said analysis information; a component element control information correction process of correcting said component element control information based upon said correction value being included in said analysis information; and a signal control process of receiving component element rendering information, and controlling the component element of said signal based upon said corrected component element control information and said component element rendering information.

In addition, the present invention for solving the above-mentioned problems is a signal analysis control program for causing a computer to execute: a signal analysis process of generating analysis information including component element control information for controlling a component element of a signal including a plurality of component elements and a correction value for correcting said component element control information; a multiplexing process of multiplexing said signal and said analysis information, and generating a multiplexed signal; a multiplexed signal separation process of generating said signal and said analysis information from said multiplexed signal; a component element control information correction process of correcting said component element control information based upon said correction value; and a signal control process of controlling the component element of said signal based upon said corrected component element control information.

In addition, the present invention for solving the above-mentioned problems is a signal analysis control program for causing a computer to execute: a signal analysis process of generating analysis information including component element control information for controlling a component element of a signal including a plurality of component elements and a correction value for correcting said component element control information; a multiplexing process of multiplexing said signal and said analysis information, and generating a multiplexed signal; a multiplexed signal separation unit for generating said signal and said analysis information from said multiplexed signal; a component element control information correction process of correcting said component element control information based upon said correction value; and a signal control process of receiving component element rendering information, and controlling the component element of said signal based upon said corrected component element control information and said component element rendering information.

That is, the method, the apparatus, and the computer program of the signal analysis and signal control of the present invention are characterized in that a transmission unit (or a recording unit) analyzes the signal and collects analysis information, and the receiving unit (or the reproduction unit) employs the analysis information and controls the signal.

More specifically, the system of the present invention is characterized in including a signal analysis unit for analyzing the input signal of the transmission unit (or the recording unit) and generating the analysis information, a multiplexing unit for multiplexing the analysis information with the input signal and generating a transmission signal, a separation unit for separating the foregoing transmission signal into the analysis information and a main signal, and a signal control unit for employing the foregoing analysis information and controlling the input signal of the receiving unit (or the reproduction unit).

### AN ADVANTAGEOUS EFFECT OF THE INVENTION

With the foregoing means, the present invention enables the receiving unit to reduce the arithmetic quantity relating to a signal analysis because the transmission unit analyzes the signal. In addition, the present invention enables the receiving unit to control the input signal, which is configured of a plurality of the sound sources, for each component element corresponding to each sound source based upon signal analysis information obtained by the transmission unit.

### BRIEF DESCRIPTION OF THE DRAWINGS

FIG. 1 is a block diagram illustrating a first embodiment of the present invention.

FIG. 2 shows a configuration example of an encoding unit 100.

FIG. 3 shows a configuration example of a decoding unit 150.

FIG. 4 shows a configuration example of a signal analysis unit 101.

FIG. 5 shows a configuration example of a signal control unit 151.

FIG. 6 shows a configuration example of an analysis information calculation unit 121.

FIG. 7 shows a configuration example of the analysis information calculation unit 121.

FIG. 8 shows a configuration example of a signal processing unit 172.

FIG. 9 shows a configuration example of the analysis information calculation unit 121.

FIG. 10 shows a configuration example of the analysis information calculation unit 121.

FIG. 11 shows a configuration example of the signal processing unit 172.

FIG. 12 shows a configuration example of the signal processing unit 172.

FIG. 13 shows a configuration example of the analysis information calculation unit 121.

FIG. 14 shows a configuration example of the analysis information calculation unit 121.

FIG. 15 shows a configuration example of the analysis information calculation unit 121.

FIG. 16 shows a configuration example of the analysis information calculation unit 121.

FIG. 17 shows a configuration example of the signal processing unit 172.

FIG. 18 shows a configuration example of the signal processing unit 172.

FIG. 19 shows a configuration example of the signal processing unit 172.

FIG. 20 shows a configuration example of the signal processing unit 172.

FIG. 21 is a block diagram illustrating a third embodiment of the present invention.

FIG. 22 shows a configuration example of a signal control unit 350.

FIG. 23 shows a configuration example of a signal processing unit 360.

FIG. 24 shows a configuration example of a background sound information modification unit 460.

FIG. 25 shows a configuration example of the background sound information modification unit 460.

FIG. 26 shows a configuration example of the background sound information modification unit 460.

FIG. 27 shows a configuration example of the signal processing unit 360.

FIG. 28 shows a configuration example of the signal processing unit 360.

FIG. 29 shows a configuration example of the signal processing unit 360.

FIG. 30 shows a configuration example of the signal processing unit 360.

FIG. 31 shows a configuration example of the signal processing unit 360.

FIG. 32 shows a configuration example of the signal processing unit 360.

FIG. 33 shows a configuration example of the signal processing unit 360.

FIG. 34 shows a configuration example of the signal processing unit 360.

FIG. 35 shows a configuration example of the signal processing unit 360.

FIG. 36 shows a configuration example of the signal processing unit 360.

FIG. 37 shows a configuration example of the signal processing unit 360.

FIG. 38 is a block diagram illustrating a fifth embodiment of the present invention.

FIG. 39 shows a configuration example of an output signal generation unit 550.

FIG. 40 shows a configuration example of the output signal generation unit 550.

FIG. 41 shows a configuration example of the output signal generation unit 550.

FIG. 42 shows a configuration example of a component element information conversion unit 563.

FIG. 43 shows a configuration example of the output signal generation unit 550.

FIG. 44 shows a configuration example of a component element information conversion unit 655.

FIG. 45 is a block diagram illustrating a seventh embodiment of the present invention.

FIG. 46 shows a configuration example of an output signal generation unit 750.

FIG. 47 shows a configuration example of a component element information conversion unit 760.

FIG. 48 shows a configuration example of the output signal generation unit 750.

FIG. 49 shows a configuration example of a component element information conversion unit 761.

FIG. 50 is a block diagram illustrating a ninth embodiment of the present invention.

FIG. 51 shows a configuration example of a signal analysis unit 900.

FIG. 52 shows a configuration example of the signal analysis unit 900.

FIG. 53 shows a configuration example of an analysis information calculation unit 911.

FIG. 54 shows a configuration example of the analysis information calculation unit 911.

FIG. 55 shows a configuration example of the analysis information calculation unit 911.

FIG. 56 is a block diagram illustrating an eleventh embodiment of the present invention.

FIG. 57 shows a configuration example of an encoding unit 1100.

FIG. 58 shows a configuration example of a signal analysis unit 1101.

FIG. 55 shows a configuration example of a decoding unit 1150.

FIG. 60 shows a configuration example of a signal control unit 1151.

FIG. 61 shows a configuration example of the signal analysis unit 101.

FIG. 62 shows a configuration example of the signal control unit 151.

FIG. 63 shows a configuration example of the signal analysis unit 101.

FIG. 64 shows a configuration example of the signal control unit 151.

FIG. 65 is a block diagram illustrating a twelfth embodiment of the present invention.

FIG. 66 is a block diagram illustrating a thirteenth embodiment of the present invention.

FIG. 67 is a view illustrating a relation of a magnification of a coefficient correction lower-limit value to signal control information.

FIG. 68 is a view illustrating a relation of a magnification of the coefficient correction lower-limit value to the signal control information and an objective sound existence probability.

FIG. 69 is a block diagram illustrating the conventional example.

### DESCRIPTION OF NUMERALS

1 transmission/receiving unit
10, 13 and 90 transmission units
15, 18, 35, 55, and 75 receiving units
100 and 1100 encoding units
101, 900, and 1101 signal analysis units
102 multiplexing unit
110, 120, 171, and 920 conversion units
111 quantization unit
121 and 911 analysis information calculation units
150 and 1150 decoding units
151, 350, and 1151 signal control units
152 separation unit
160 inverse quantization unit
161 and 173 inverse conversion units
172 and 360 signal processing units
200, 1020, 1021, 1022, 2051, and 2052 background sound estimation units
2011 and 2012 suppression coefficient calculation units
202 background sound information generation unit
203, 2071, and 2072 signal versus background sound ratio calculation units
2041 and 2042 signal versus background sound ratio encoding unit
2061 and 2062 background sound encoding units
251, 451, and 470 multipliers
253 subtracter
260, 2611, and 2612 background sound information decoding units
2621, and 2622 background sound information conversion units
2631, 2632, 2651, and 2652 background sound decoding units
2641 and 2642 suppression coefficient generation units
460 background sound information modification units
461 suppression coefficient modification unit
466 lower-limit value modification unit
471 comparison unit
472 designated background sound control unit
473 switch
550 and 750 output signal generation units
560 and 565 signal control units
561, 563, 564, 655, 760, and 761 component element information conversion units
562 rendering unit
651, 653, 851, and 853 component element parameter generation units
652 rendering information generation unit
910 quantizing noise calculation unit
1200 signal separation analysis unit
1201 separation filter encoding unit
1202 separation filter decoding unit
1203 filter
1210 sound environment analysis unit
1211 sound environment information encoding unit
1212 sound environment information decoding unit
1213 sound environment information processing unit
1300 and 1301 computers
2021 and 2022 suppression coefficient encoding units

### BEST MODE FOR CARRYING OUT THE INVENTION

Embodiments of the signal analysis control system of the present invention will be explained in details by making a reference to the accompanied drawings.

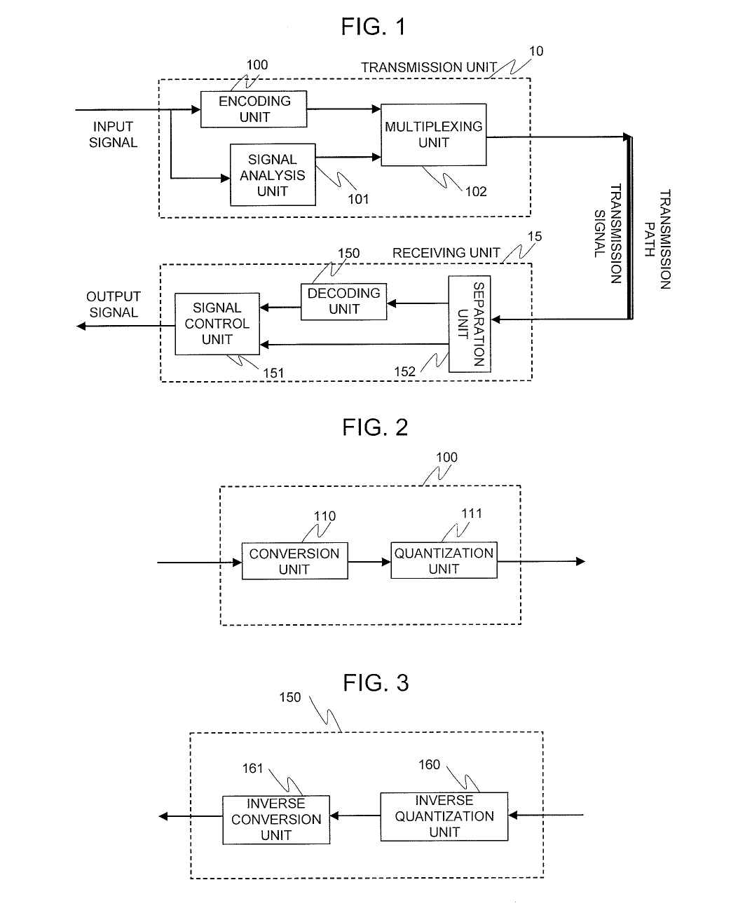

A first embodiment of the signal analysis control system of the present invention will be explained by making a reference to FIG. 1. The signal analysis control system of the present invention assumes a configuration in which a transmission unit 10 and a receiving unit 15 are connected via a transmission path. The transmission unit 10 receives an input signal that is configured of a plurality of the sound sources, and outputs a transmission signal. The transmission signal is inputted into the receiving unit 15 via the transmission path. The receiving unit 15 receives the transmission signal, and outputs an output signal. Further, the transmission unit, the transmission path, and the receiving unit could be a recording unit, a storage medium, and a reproduction unit, respectively.

The transmission unit 10 is configured of an encoding unit 100, a signal analysis unit 101, and a multiplexing unit 102. The input signal is inputted into the encoding unit 100 and the signal analysis unit 101. The input signal may include a plurality of the component elements. The signal analysis unit 101 calculates analysis information indicative of a relation of a component element that corresponds to each component element being included in the input signal. The analysis information may include information for controlling the component elements, namely, component element control information. The signal analysis unit 101 outputs the analysis information to the multiplexing unit 102. The encoding unit 100 encodes the input signal. The encoding unit 100 outputs the encoded signal to the multiplexing unit 102. The multiplexing unit 102 multiplexes the encoded signal being inputted from the encoding unit 100, and the analysis information being inputted from the signal analysis unit 101. The multiplexing unit 102 outputs the multiplexed signal to the transmission path as a transmission signal.

The receiving unit 15 is configured of a decoding unit 150, a signal control unit 151, and a separation unit 152. At first, the transmission signal is inputted into the separation unit 152. The separation unit 152 separates the transmission signal into a main signal and the analysis information. Continuously, the separation unit 152 outputs the main signal to the decoding unit 150, and outputs the analysis information to the signal control unit 151, respectively. The decoding unit 150 decodes the main signal, and generates the decoded signal. And, the decoding unit 150 outputs the decoded signal to the signal control unit 151. Herein, the decoded signal is configured of general plural sound sources. The signal control unit 151 manipulates the decoded signal received from the decoding unit 150 for each component element that corresponds to each sound source, based upon the analysis information received from the separation unit 152. The signal control unit 151 outputs the manipulated signal as an output signal. The signal control unit 151 may manipulate the decoded signal with the component element group, which is configured of a plurality of the component elements, defined as a unit instead of the component element that corresponds to each sound source.

Continuously, a configuration example of the encoding unit 100 will be explained in details by making a reference to FIG. 2. The encoding unit 100 receives the input signal, and outputs the encoded signal. The encoding unit 100 is configured of a conversion unit 110 and a quantization unit 111. At first, the input signal is inputted into the conversion unit 110. Next, the conversion unit 110 decomposes the input signal into frequency components, and generates a first converted signal. The conversion unit 110 outputs the first converted signal to the quantization unit 111. And, the quantization unit 111 quantizes the first converted signal, and outputs it as an encoded signal.

The conversion unit 110 configures one block by collecting a plurality of input signal samples, and applies a frequency conversion for this block. As an example of the frequency conversion, a Fourier transform, a cosine transform, a KL (Karhunen Loeve) transform, etc. are known. The technology related to a specific arithmetic operation of these transforms, and its properties are disclosed in Non-patent document 2.

<Non-patent document 2> DIGITAL CODING OF WAVEFORMS, PRINCIPLES AND APPLICATIONS TO SPEECH AND VIDEO, PRENTICE-HALL, 1990

The conversion unit 110 also can apply the foregoing transforms for a result obtained by weighting one block of the input signal samples with a window function. As such a window function, the window functions such as a Hamming window, a Hanning (Hann) window, a Kaiser window, and a Blackman window are known. Further, more complicated window functions can be employed. The technology related to these window functions is disclosed in Non-patent document 3 and Non-patent document 4.

<Non-patent document 3> DIGITAL SIGNAL PROCESSING, PRENTICE-HALL, 1975

<Non-patent document 4> MULTIRATE SYSTEMS AND FILTER BANKS, PRENTICE-HALL, 1993

An overlap of each block may be permitted at the moment that the conversion unit 110 configures one block from a plurality of the input signal samples. For example, with the case of applying an overlap of 30% of a block length, the last 30% of the signal sample belonging to a certain block is repeatedly employed in a plurality of the blocks as the first 30% of the signal sample belonging to the next block. The technology relating to the blocking involving the overlap and the conversion is disclosed in the Non-patent document 2.

In addition, the conversion unit 110 may be configured of a band-division filter bank. The band-division filter bank is configured of a plurality of band-pass filters. The band-division filter bank divides the received input signal into a plurality of frequency bands, and outputs them to the quantization unit 111. An interval of each frequency band of the band-division filter bank could be equal in some cases, and unequal in some cases. Band-dividing the input signal at an unequal interval makes it possible to lower/raise a time resolution, that is, the time resolution can be lowered by dividing the input signal into narrows bands with regard to a low-frequency area, and the time resolution can be raised by dividing the input signal into wide bands with regard to a high-frequency area. As a typified example of the unequal-interval division, there exists an octave division in which the band gradually halves toward the low-frequency area, a critical band division that corresponds to an auditory feature of a human being, or the like. The technology relating to the band-division filter bank and its design method is disclosed in the Non-patent document 4.

The quantization unit 111 removes redundancy of the inputted signal, and outputs the encoded signal. As a method of removing redundancy, there exists the method of taking a control such that a correlation between the inputted signals is minimized. In addition, the signal component that is not auditorily recognized may be removed by utilizing the auditory feature such as a masking effect. As a quantization method, the quantization methods such as a linear quantization method and a non-linear quantization method are known. The redundancy of the quantized signal can be furthermore removed by employing Huffman coding etc.

A configuration example of the decoding unit 150 will be explained in details by making a reference to FIG. 3. The decoding unit 150 receives the main signal, and outputs the decoded signal. The decoding unit 150 is configured of an inverse quantization unit 160 and an inverse conversion unit 161. The inverse quantization unit 160 inverse-quantizes the received main signal of each frequency, and generates the first converted signal that is configured of a plurality of the frequency components. And, the inverse quantization unit 160 outputs the first converted signal to the inverse conversion unit 161. The inverse conversion unit 161 inverse-converts the first converted signal, and generates the decoded signal. And, the inverse conversion unit 161 outputs the decoded signal.

As an inverse conversion that the inverse conversion unit 161 applies, the inverse conversion corresponding to the conversion that the conversion unit 110 applies is preferably selected. For example, when the conversion unit 110 configures one block by collecting a plurality of the input signal samples, and applies the frequency conversion for this block, the inverse conversion unit 161 applies the corresponding inverse conversion for the samples of which number is identical. Further, when an overlap of each block is permitted at the moment that the conversion unit 110 configures one block by collecting a plurality of the input signal samples, the inverse conversion unit 161, responding to this, applies an identical overlap for the inverse-converted signal. In addition, when the conversion unit 110 is configured of the band-division filter bank, the inverse conversion unit 161 is configured of a band-synthesis filter bank. The technology relating to the band-synthesis filter bank and its design method is disclosed in the Non-patent document 4.

While the encoding unit 100 of FIG. 2 and the decoding unit 150 of FIG. 3 were explained on the assumption that conversion/encoding having the conversion unit included therein was applied, a pulse code modulation (PCM), an adaptive differential pulse code modulation (ADPCM), and analysis-by-synthesis coding, which is typified by CELP etc., in addition hereto may be applied. The technology relating to the PCM/ADPCM is disclosed in the Non-patent document 2. Further, the technology relating to the CELP is disclosed in Non-patent document 5.

<Non-patent document 5> IEEE INTERNATIONAL CONFERENCE ON ACOUSTICS, SPEECH, AND SIGNAL PROCESSING, 25.1.1, March 1985, pp. 937-940

Further, the encoding unit 100 may output the input signal as it stands to the multiplexing unit 102 without performing the encoding process therefor, and the decoding unit 150 may input the main signal as it stands into the signal control unit 151 without performing the decoding process therefor. This configuration makes it possible to eliminate the distortion of the signal accompanied by the encoding/decoding process. In addition, a configuration may be made so that the encoding unit 100 and the decoding unit 150 perform a distortion-less compression/expansion process. This configuration enables the signal control unit 151 to receive the decoded signal without distorting the input signal.

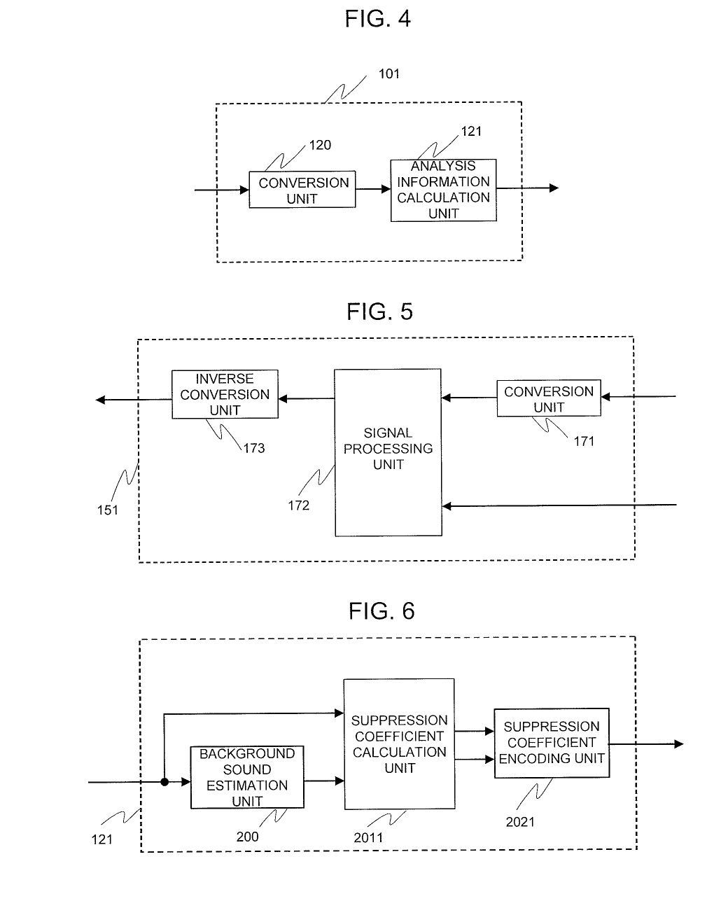

A configuration example of the signal analysis unit 101 will be explained in details by making a reference to FIG. 4. The signal analysis unit 101 receives the input signal, and outputs the analysis information. The signal analysis unit 101 is configured of a conversion unit 120 and an analysis information calculation unit 121. The conversion unit 120 decomposes the received input signal into the frequency components, and generates the second converted signal. The conversion unit 120 outputs the second converted signal to the analysis information calculation unit 121. The analysis information calculation unit 121 decomposes the second converted signal into the component elements that correspond to the sound source, and generates the analysis information indicative of a relation between a plurality of the component elements. And, the analysis information calculation unit 121 outputs the analysis information. Further, the analysis information calculation unit 121 may decompose the second converted signal into component element groups each of which is configured of a plurality of the component elements, and calculate the analysis information. The signal analysis unit 101 may encode the analysis information when the redundancy exists in the analysis information. This makes it possible to minimize the redundancy of the analysis information. The technique of the conversion in the conversion unit 110 may be employed for the technique of the conversion in the conversion unit 120.

A configuration example of the signal control unit 151 will be explained in details by making a reference to FIG. 5. The signal control unit 151 receives the decoded signal and the analysis information, and outputs the output signal. The signal control unit 151 is configured of a conversion unit 171, a signal processing unit 172, and an inverse conversion unit 173. The conversion unit 171 decomposes the received decoded signal into the frequency components, and generates the second converted signal. The conversion unit 171 outputs the second converted signal to the signal processing unit 172. The signal processing unit 172 decomposes the second converted signal into the component elements that correspond to the sound source by employing the analysis information, changes a relation between a plurality of the component elements, and generates the modified decoded signal. And, the signal processing unit 172 outputs the modified decoded signal to the inverse conversion unit 173. Further, the signal processing unit 172 may decompose the second converted signal into component element groups each of which is configured of a plurality of the component elements, and change a relation between a plurality of the component elements. The signal processing unit 172 performs the above-mentioned process after finishing the decoding process in the case that the analysis information has been encoded in the analysis information calculation unit 121. The inverse conversion unit 173 inverse-converts the modified decoded signal, and generates the output signal. And, the inverse conversion unit 173 outputs the output signal. The technique of the inverse conversion in the inverse conversion unit 161 can be employed for the technique of the inverse conversion in the inverse conversion unit 173.

As explained above, the first embodiment of the present invention enables the receiving unit to control the input signal, which is configured of a plurality of the sound sources, for each component element corresponding to each sound source based upon the analysis information of the input signal being outputted from the transmission unit. In addition, the receiving unit can curtail the arithmetic quantity relating to the signal analysis because the transmission unit analyses the signal.

Continuously, a second embodiment of the present invention will be explained in details. In the second embodiment of the present invention, an explanation will be made by employing the input signal that is configured of objective sound and background sound as one example of the input signal that is configured of a plurality of the sound sources. A configuration of the second embodiment is represented in FIG. 1. The second embodiment differs from the first embodiment in the configurations of the signal analysis unit 101 and the signal control unit 151. The signal analysis unit 101 of the second embodiment receives the input signal that is configured of an objective signal or a main signal and a background signal, and outputs the information indicative of a relation between the objective signal or the main signal and the background signal as analysis information to the multiplexing unit 102. Herein, the input signal could be a signal that is configured of the objective sound and the background sound. In addition, the analysis information may include information for controlling the main signal and the background signal. Further, the signal control unit 151 receives the decoded signal and the analysis information, generates the output signal by controlling the objective signal or the main signal and the background signal, and outputs it. The signal control unit 151 may output the signal that is configured of the objective sound and the background sound as an output signal. Hereinafter, an explanation will be made by employing the signal that is configured of the objective sound and the background sound.

In a first example, the signal analysis unit 101 calculates suppression coefficient information as the analysis information or the component element control information. The suppression coefficient information is information that is caused to act upon the input signal that is configured of the objective sound and the background sound in order to suppress the background sound. The signal control unit 151 controls the decoded signal by employing the suppression coefficient information. A configuration of the signal analysis unit 101 is represented in FIG. 4. A configuration of the analysis information calculation unit 121 of this example differs from that of the analysis information calculation unit 121 of the first embodiment. Further, the signal control unit 151 of this embodiment is represented in FIG. 5. A configuration of the signal processing unit 172 of this embodiment differs from that of the signal processing unit 172 of the first embodiment

At first, a configuration example of the analysis information calculation unit 121 will be explained in details by making a reference to FIG. 6. The analysis information calculation unit 121 receives the second converted signal, and outputs the suppression coefficient information as analysis information. The analysis information calculation unit 121 is configured of a background sound estimation unit 200, a suppression coefficient calculation unit 2011, and a suppression coefficient encoding unit 2021.

The background sound estimation unit 200 receives the second converted signal, estimates the background sound, and generates a background sound estimation result. The background sound estimation unit 200 outputs the background sound estimation result to the suppression coefficient calculation unit 2011. As a background sound estimation result, there exist an amplitude absolute value and an energy value of the background sound, an amplitude ratio and an energy ratio of the background sound and the input signal, an average value thereof, an interval maximum value, an interval minimum value, and so on.

The suppression coefficient calculation unit 2011 calculates a correction value for correcting the suppression coefficient by employing the second converted signal and the background sound estimation result. That is, the suppression coefficient calculation unit 2011 calculates the suppression coefficient, and a coefficient correction lower-limit value as a correction value of the suppression coefficient for suppressing the background sound. And the suppression coefficient calculation unit 2011 outputs the suppression coefficient and the coefficient correction lower-limit value to the suppression coefficient encoding unit 2021. As a rule, a signal distortion that occurs after suppressing the background sound is increased when the suppression coefficient becomes too small. Thereupon, employing the coefficient correction lower-limit value expressive of a lower limit of the suppression coefficient makes it possible to avoid an excessive increase in the signal distortion. A specific value may be pre-stored in a memory as the coefficient correction lower-limit value in some cases, and the coefficient correction lower-limit value may be calculated responding to the background sound estimation result in some cases. Such a calculation includes a manipulation of selecting an appropriate value from among a plurality of values stored in a memory. The coefficient correction lower-limit value should be set so that it is a small value when the background sound estimation result is small. The reason is that the small background sound estimation result signifies that the objective sound is dominant in the input signal, and hence, the distortion hardly occurs at the moment of manipulating the component element. As a technology relating to the method of calculating the suppression coefficient, the method founded upon minimum mean square error short-time spectral amplitude (MMSE STSA), which is disclosed in Non-patent document 6, the method founded upon minimum mean square error log spectral amplitude (MMSE LSA), which is disclosed in Non-patent document 7, the method founded upon maximum likelihood spectral amplitude estimation, which is disclosed in Non-patent document 8, or the like may be employed. As one example of the method of calculating the coefficient correction lower-limit value, the method disclosed in the Patent document 1 may be employed. Additionally, instead of calculating the coefficient correction lower-limit value one by one, it is also possible to previously store the fixed values in the memory, and to read out and utilize it one by one.

<Non-patent document 6> IEEE TRANSACTIONS ON ACOUSTICS, SPEECH, AND SIGNAL PROCESSING, VOL. 32, NO. 6, pp. 1109-1121, December 1984

<Non-patent document 7> IEEE TRANSACTIONS ON ACOUSTICS, SPEECH, AND SIGNAL PROCESSING, VOL. 33, NO. 2, pp. 443-445, April 1985

<Non-patent document 8> EURASIP JOURNAL ON ADVANCES IN SIGNAL PROCESSING, VOLUME 2005, Issue 7, July 2005, pp. 1110-1126

The suppression coefficient encoding unit 2021 receives the suppression coefficient and the coefficient correction lower-limit value, and encodes each of them. The suppression coefficient encoding unit 2021 encodes the suppression coefficient and the coefficient correction lower-limit value, outputs an encoding result as suppression coefficient information. A method similar to the method having the content already explained in the quantization unit 111 may be employed for the encoding. The encoding makes it possible to remove the redundancy of the suppression coefficient and the coefficient correction lower-limit value. Further, when the information quantity does not need to be curtailed, the suppression coefficient encoding unit 2021 may output the suppression coefficient and the coefficient correction lower-limit value as suppression coefficient information without performing these encoding processes.

Next, a configuration example of the signal processing unit 172 will be explained in details by making a reference to FIG. 8. The signal processing unit 172 receives the second converted signal, and the suppression coefficient information as analysis information, and outputs the modified decoded signal. The signal processing unit 172 is configured of a suppression coefficient decoding unit 260 and a multiplier 251.

The suppression coefficient decoding unit 260 decodes the suppression coefficient and the coefficient correction lower-limit value from the received suppression coefficient information, calculates a corrected suppression coefficient from the suppression coefficient and the coefficient correction lower-limit value, and outputs the corrected suppression coefficient to the multiplier 251. When the suppression coefficient and the coefficient correction lower-limit value have not been encoded, the suppression coefficient decoding unit 260 directly calculates the corrected suppression coefficient from the suppression coefficient and the coefficient correction lower-limit value without performing the decoding process. As a method of calculating the corrected suppression coefficient from the suppression coefficient and the coefficient correction lower-limit value, the method disclosed in the Patent document 1 may be employed. The method disclosed in the Patent document 1 is a method of comparing the suppression coefficient with the coefficient correction lower-limit value. When the suppression coefficient is larger than the coefficient correction lower-limit value, the suppression coefficient is outputted as a corrected suppression coefficient. Further, when the suppression coefficient is smaller than the coefficient correction lower-limit value, the coefficient correction lower-limit value is outputted as a corrected suppression coefficient. The multiplier 251 multiplies the second converted signal by the corrected suppression coefficient, and generates the modified decoded signal. The multiplier 251 outputs the modified decoded signal.

In a second example, the signal analysis unit 101 calculates the signal versus background signal ratio information as analysis information or component element control information. Further, the signal analysis unit 101 may calculate the signal versus background sound ratio information as analysis information. Hereinafter, the second example will be explained by employing the signal versus background sound ratio. The signal control unit 151, responding to this, controls the decoded signal by employing the signal versus background sound ratio information. With this, the signal of which the background sound has been suppressed can be obtained from the input signal that is configured of the objective sound and the background sound.

At first, the signal analysis unit 101 will be explained. The signal analysis unit 101, similarly to the case of the first example, is represented in FIG. 4. Upon comparing this example with the first example, the former differs from the latter in a configuration of the analysis information calculation unit 121, and the signal analysis unit 101 outputs the signal versus background sound ratio information as analysis information.

The analysis information calculation unit 121 of this example will be explained in details by making a reference to FIG. 9. The analysis information calculation unit 121 receives the second converted signal, and outputs the signal versus background sound ratio information as analysis information. The analysis information calculation unit 121 is configured of a background sound estimation unit 200, a suppression coefficient calculation unit 2011, a signal versus background sound ratio calculation unit 203, and a signal versus background sound ratio encoding unit 2041.

The background sound estimation unit 200, similarly to the case the first embodiment, receives the second converted signal, estimates the background sound, and generates the background sound estimation result. And, the background sound estimation unit 200 outputs the background sound estimation result to the suppression coefficient calculation unit 2011.

The suppression coefficient calculation unit 2011 calculates the coefficient correction lower-limit value as a correction value of the suppression coefficient for suppressing the background sound by employing the second converted signal and the background sound estimation result. And, the suppression coefficient calculation unit 2011 outputs the suppression coefficient to the signal versus background sound ratio calculation unit 203, and outputs the coefficient correction lower-limit value to the signal versus background sound ratio encoding unit 2041. As a method of calculating the suppression coefficient and the coefficient correction lower-limit value, the calculation method of the suppression coefficient calculation unit 2011 of the first example shown in FIG. 6 may be employed. The signal versus background sound ratio calculation unit 203 calculates a signal versus background sound ratio R by employing an inputted suppression coefficient G. Upon defining the input signal as X, the objective sound as S, and the background sound as N, the following relation holds.

$$\begin{matrix}X = S + N & [ Numerical equation 1 ] \\ S = G \times X & [ Numerical equation 2 ] \\ R = \frac{{S}^{2}}{{N}^{2}} & [ Numerical equation 3 ]\end{matrix}$$

R based upon this definition is known as a prior signal-to noise ratio (prior SNR) when the background sound is noise. Upon substituting [Numerical equation 1] and [Numerical equation 2] into [Numerical equation 3], the following equation is yielded.

$$R = \frac{{S}^{2}}{{( X - S )}^{2}} = \frac{{G}^{2}}{1 - {G}^{2}} \qquad [ Numerical equation 4 ]$$

The signal versus background sound ratio calculation unit 203 outputs the calculated signal versus background sound ratio R to the signal versus background sound ratio encoding unit 2041. The signal versus background sound ratio encoding unit 2041 encodes the inputted signal versus background sound ratio R and the coefficient correction lower-limit value. The signal versus background sound ratio encoding unit 2041 outputs the encoded signal versus background sound ratio R and coefficient correction lower-limit value as signal versus background sound ratio information. With regard to the details of the encoding process, an encoding process similar to the encoding process being performed in the suppression coefficient encoding unit 2021 can be employed. This makes it possible to remove the redundancy of the signal versus background sound ratio R and the coefficient correction lower-limit value. Further, when the information quantity does not need to be curtailed, the signal versus background sound ratio encoding unit 2041 may output the signal versus background sound ratio and the coefficient correction lower-limit value as signal versus background sound ratio information without performing the encoding process the signal versus background sound ratio R and the coefficient correction lower-limit value.

In addition, as apparent from [Numerical equation 4], the lower-limit value associated with the signal versus background sound ratio R, namely, the signal versus background sound ratio lower-limit value may be employed instead of the coefficient correction lower-limit value. That is, when the suppression coefficient G becomes small, the signal versus background sound ratio R as well becomes small similarly. This signifies that changing the lower-limit value of the suppression coefficient G into the lower-limit value of the signal versus background sound ratio R by employing the conversion makes it possible to prevent the signal versus background sound ratio R from becoming excessively small. At this time, the suppression coefficient calculation unit 2011 calculates the suppression coefficient and the signal versus background sound ratio lower-limit value. The signal versus background sound ratio lower-limit value is calculated responding to the signal versus background sound ratio similarly to the suppression coefficient lower-limit value in the suppression coefficient calculation unit 2011 of the first example shown in FIG. 6. The suppression coefficient calculation unit 2011 outputs the suppression coefficient to the signal versus background sound ratio calculation unit 203, and outputs the signal versus background sound ratio lower-limit value to the signal versus background sound ratio encoding unit 2041. The signal versus background sound ratio encoding unit 2041 encodes the inputted signal versus background sound ratio R and signal versus background sound ratio lower-limit value. The signal versus background sound ratio encoding unit 2041 outputs the encoded signal versus background sound ratio R and signal versus background sound ratio lower-limit value as signal versus background sound ratio information.

Next, the signal control unit 151 of this example will be explained in details. The signal control unit 151, similarly to the case of the first embodiment, is represented in FIG. 5. This example differs from the first example in a configuration of the signal processing unit 172.

A configuration example of the signal processing unit 172 will be explained in details by making a reference to FIG. 11. The signal processing unit 172 receives the second converted signal and the signal versus background sound ratio information as analysis information, and outputs the modified decoded signal. The signal processing unit 172 is configured of a signal versus background sound ratio decoding unit 2611, a suppression coefficient conversion unit 2621, and a multiplier 251.

The signal versus background sound ratio decoding unit 2611 decodes the signal versus background sound ratio R and the coefficient correction lower-limit value from the received signal versus background sound ratio information, and outputs them to the suppression coefficient conversion unit 2621. When the signal versus background sound ratio R and the coefficient correction lower-limit value have not been encoded, the signal versus background sound ratio decoding unit 2611 directly outputs the signal versus background sound ratio R and the coefficient correction lower-limit value without performing the decoding process.

The suppression coefficient conversion unit 2621 converts the signal versus background sound ratio R into the suppression coefficient G. Thereafter, the suppression coefficient conversion unit 2621 compares the suppression coefficient G with the coefficient correction lower-limit value. When the suppression coefficient G is larger than the coefficient correction lower-limit value, the suppression coefficient conversion unit 2621 outputs the suppression coefficient G as a corrected suppression coefficient. Further, when the suppression coefficient G is smaller than the coefficient correction lower-limit value, the suppression coefficient conversion unit 2621 outputs the coefficient correction lower-limit value as a corrected suppression coefficient. The conversion from the signal versus background sound ratio R to the suppression coefficient G is made based upon [Numerical equation 4]. Upon solving [Numerical equation 4] for G, the following equation is yielded.

$$G = \sqrt{\frac{R}{1 + R}} \qquad [ Numerical equation 5 ]$$

Further, the multiplier 251 multiplies the second converted signal by the corrected suppression coefficient, and generates the modified decoded signal. The multiplier 251 outputs the modified decoded signal.

In the case of employing the signal versus background sound ratio lower-limit value instead of the coefficient correction lower-limit value, the signal versus background sound ratio decoding unit 2611 shown in FIG. 11 decodes the signal versus background sound ratio R and the signal versus background sound ratio lower-limit value from the received signal versus background sound ratio information, and outputs them to the suppression coefficient conversion unit 2621. When the signal versus background sound ratio R and the signal versus background sound ratio lower-limit value have not been encoded, the signal versus background sound ratio decoding unit 2611 directly outputs the signal versus background sound ratio R and the signal versus background sound ratio lower-limit value without performing the decoding process. The suppression coefficient conversion unit 2621 obtains a corrected signal versus background sound ratio from the signal versus background sound ratio R and the signal versus background sound ratio lower-limit value. In addition, the suppression coefficient conversion unit 2621 applies [Numerical equation 5] with the corrected signal versus background sound ratio defined as R, and outputs the obtained G to the multiplier 251 as a corrected suppression coefficient.

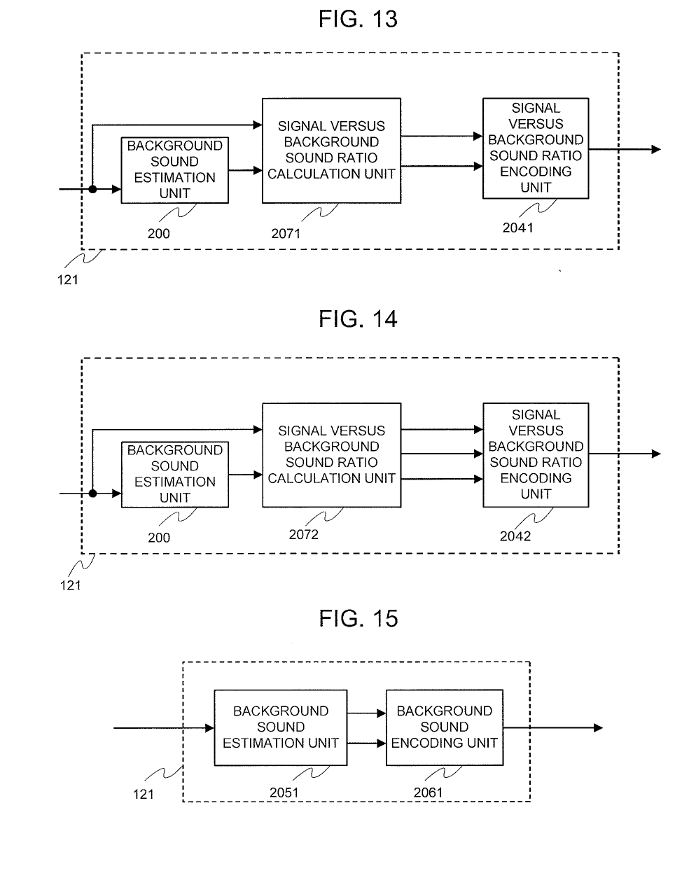

Continuously, another configuration example of the analysis information calculation unit 121 will be explained in details by making a reference to FIG. 13. Upon making a comparison with the analysis information calculation unit 121 shown in FIG. 9, the analysis information calculation unit 121 of this configuration example differs in a point of not including the suppression coefficient calculation unit 2011. Further, a signal versus background sound ratio calculation unit 2071 calculates the signal versus background sound ratio and the coefficient correction lower-limit value based upon the second converted signal and the background sound estimation result. In the analysis information calculation unit 121 shown in FIG. 13, [Numerical equation 6] is employed as a definition of the signal versus background sound ratio R instead of [Numerical equation 3]. The signal versus background sound ratio R based upon this definition is known as a posterior signal-to noise ratio (posterior SNR) when the background sound is noise.

$$R = \frac{{X}^{2}}{{N}^{2}} \qquad [ Numerical equation 6 ]$$

That is, this example is configured to employ the posterior SNR as analysis information instead of the prior SNR when the background sound is noise. R of [Numerical equation 6], which does not demand the suppression coefficient G, is calculated from the input signal and the background sound. This enables the signal versus background sound ratio calculation unit 2071 to calculate the signal versus background sound ratio based upon the second converted signal and the background sound estimation result. Additionally, the coefficient correction lower-limit value can be calculated with a method similar to the method of the suppression coefficient calculation unit 2011 of the first example shown in FIG. 6. And, the signal versus background sound ratio calculation unit 2071 outputs the signal versus background sound ratio and the coefficient correction lower-limit value to the signal versus background sound ratio encoding unit 2041. An operation of the signal versus background sound ratio encoding unit 2041 is similar to that of the signal versus background sound ratio encoding unit 2041 shown in FIG. 9, so its explanation is omitted.

The signal versus background sound ratio lower-limit value associated with the signal versus background sound ratio R may be employed instead of the coefficient correction lower-limit value. In this case, the signal versus background sound ratio calculation unit 2071 calculates the signal versus background sound ratio and the signal versus background sound ratio lower-limit value based upon the second converted signal and the background sound estimation result. The signal versus background sound ratio calculation unit 2071 outputs the signal versus background sound ratio and the signal versus background sound ratio lower-limit value to the signal versus background sound ratio encoding unit 2041. The signal versus background sound ratio encoding unit 2041 encodes the inputted signal versus background sound ratio R and signal versus background sound ratio lower-limit value. The signal versus background sound ratio encoding unit 2041 outputs the encoded signal versus background sound ratio R and signal versus background sound ratio lower-limit value as signal versus background sound ratio information.

On the other hand, [Numerical equation 1] and [Numerical equation 2] are substituted into [Numerical equation 6], and upon assuming that S and N have no relation to each other, the following equation is yielded.

$$R = \frac{1}{1 - {G}^{2}} \qquad [ Numerical equation 7 ]$$

That is, the signal versus background sound ratio calculation unit 203 may calculate the signal versus background sound ratio R by employing [Numerical equation 7].

In this configuration example, the signal processing unit 172 of the receiving side is represented in FIG. 11 similarly to the case of the foregoing configuration example. The signal versus background sound ratio decoding unit 2611 decodes the signal versus background sound ratio R and the coefficient correction lower-limit value from the received signal versus background sound ratio information, and outputs the signal versus background sound ratio R and the coefficient correction lower-limit value to the suppression coefficient conversion unit 2621. The suppression coefficient conversion unit 2621 converts the signal versus background sound ratio R into the suppression coefficient G, and calculates the corrected suppression coefficient from the suppression coefficient G and the coefficient correction lower-limit value. Thereafter, the suppression coefficient conversion unit 2621 outputs the corrected suppression coefficient. The conversion from the signal versus background sound ratio R to the suppression coefficient G is made based upon [Numerical equation 8]. That is, upon solving [Numerical equation 7] for G, the following equation is yielded.

$$G = \sqrt{\frac{R - 1}{R}} \qquad [ Numerical equation 8 ]$$

In the case of employing the signal versus background sound ratio lower-limit value associated with the signal versus background sound ratio R instead of the coefficient correction lower-limit value, the signal versus background sound ratio decoding unit 2611 decodes the signal versus background sound ratio R and the signal versus background sound ratio lower-limit value from the received signal versus background sound ratio information, and obtains a corrected signal versus background sound ratio. Further, the signal versus background sound ratio decoding unit 2611 outputs the corrected signal versus background sound ratio to the suppression coefficient conversion unit 2621. The suppression coefficient conversion unit 2621 applies [Numerical equation 8] with the corrected signal versus background sound ratio defined as R, and outputs the obtained G to the multiplier 251 as a suppression coefficient.

Continuously, a third example will be explained. In the third example, the signal analysis unit 101 outputs the background sound information as analysis information or component element control information. The signal control unit 151, responding to this, controls the decoded signal by employing the background sound information. With this, the signal of which the background sound has been suppressed can be obtained in the input signal that is configured of the objective sound and the background sound.

At first, the signal analysis unit 101 will be explained. The signal analysis unit 101, similarly to the case of the first example, is represented in FIG. 4. A configuration of the analysis information calculation unit 121 of this example differs from that of the analysis information calculation unit 121 of the first example, and the signal analysis unit 101 outputs the background sound information as analysis information.

A configuration example of the analysis information calculation unit 121 of this example will be explained in details by making a reference to FIG. 15. The analysis information calculation unit 121 is configured of a background sound estimation unit 2051 and a background sound encoding unit 2061. The analysis information calculation unit 121 receives the second converted signal, and outputs the background sound information as analysis information.

The background sound estimation unit 2051, similarly to the background sound estimation unit 200 of the first example, receives the second converted signal, and estimates the background sound. And, the background sound estimation unit 2051 generates the background sound estimation result. Further, the background sound estimation unit 2051, similarly to the suppression coefficient calculation unit 2011 of the first example shown in FIG. 6, calculates the coefficient correction lower-limit value as a correction value. The background sound estimation unit 2051 outputs the background sound estimation result and the coefficient correction lower-limit value to the background sound encoding unit 2061.

The background sound encoding unit 2061 encodes the inputted background sound estimation result and coefficient correction lower-limit value, and outputs the encoded background sound estimation result and coefficient correction lower-limit value as background sound information. With regard to the encoding process, an encoding process similar to that of the suppression coefficient encoding unit 2021 can be employed. This makes it possible to remove the redundancy of the background sound estimation result and the coefficient correction lower-limit value. Further, when the information quantity does not need to be curtailed, the background sound encoding unit 2061 may output the background sound estimation result and the coefficient correction lower-limit value as background sound information without performing the encoding process therefor.

The background sound upper-limit value may be employed as a correction value instead of the coefficient correction lower-limit value. Setting the upper-limit value to the background sound allows an upper limit to be placed upon the background sound estimation result. When the upper limit exists in the background sound, which is caused to act upon the second decoded signal, a lower limit occurs in the obtained modified decoded signal. That is, the distortion in the modified decoded signal can be reduced. In this case, the background sound estimation unit 2051 calculates the background sound and the background sound upper-limit value based upon the second converted signal. A specific value may be pre-stored in a memory as the background sound upper-limit value in some cases, and the background sound upper-limit value may be calculated responding to the background sound estimation result in some cases. Such a calculation includes a manipulation of selecting an appropriate value from among a plurality of values stored in the memory. The background sound upper-limit value should be set so that it is a large value when the background sound estimation result is small. The reason is that the small background sound estimation result signifies that the objective sound is dominant in the input signal, and hence, the distortion hardly occurs at the moment of manipulating the component element. The background sound estimation unit 2051 outputs the background sound and the background sound upper-limit value to the background sound encoding unit 2061. The background sound encoding unit 2061 encodes the inputted background sound and background sound upper-limit value. The background sound encoding unit 2061 outputs the encoded background sound and background sound upper-limit value as background sound information.

Next, the signal control unit 151 will be explained. The signal control unit 151, similarly to the case of the first example, is represented in FIG. 5. This example differs from the first example in a configuration of the signal control unit 172.

A configuration example of the signal processing unit 172 will be explained in details by making a reference to FIG. 17. The signal processing unit 172 receives the second converted signal and the background sound information as analysis information, and outputs the modified decoded signal. The signal processing unit 172 is configured of a background sound decoding unit 2631, a suppression coefficient generation unit 2641, and a multiplier 251.

The background sound decoding unit 2631 receives the background sound information as analysis information, and decodes the background sound estimation result and the coefficient correction lower-limit value from the background sound information. The background sound decoding unit 2631 outputs the background sound estimation result and the coefficient correction lower-limit value to the suppression coefficient generation unit 2641. When the background sound estimation result and the coefficient correction lower-limit value have not been encoded, the background sound decoding unit 2631 outputs the background sound estimation result and the coefficient correction lower-limit value without performing the decoding process.

The suppression coefficient generation unit 2641 receives the background sound estimation result, the coefficient correction lower-limit value, and the second converted signal. And, the suppression coefficient generation unit 2641 calculates the suppression coefficient for suppressing the background sound based upon the background sound estimation result and the second converted signal. A calculation method similar to that of the suppression coefficient calculation unit 2011 shown in FIG. 9 may be employed for calculating this suppression coefficient. In addition, the suppression coefficient generation unit 2641 calculates the corrected suppression coefficient from the suppression coefficient and the coefficient correction lower-limit value, and outputs the corrected suppression coefficient. As a technology of the method of calculating the suppression coefficient, the technology disclosed in the foregoing Non-patent document 6, Non-patent document 7, or Non-patent document 8 may be employed.

The multiplier 251 multiplies the second converted signal by the corrected suppression coefficient, and generates the modified decoded signal. The multiplier 251 outputs the modified decoded signal.

In the case of employing the background sound upper-limit value instead of the coefficient correction lower-limit value, the background sound decoding unit 2631 receives the background sound information as analysis information, and decodes the background sound estimation result and the background sound upper-limit value from the background sound information. The background sound decoding unit 2631 outputs the background sound estimation result and the background sound upper-limit value to the suppression coefficient generation unit 2641. When the background sound estimation result and the background sound upper-limit value have not been encoded, the background sound decoding unit 2631 outputs the background sound estimation result and the background sound upper-limit value without performing the decoding process.

The suppression coefficient generation unit 2641 receives the background sound estimation result, the background sound upper-limit value, and the second converted signal. Further, the suppression coefficient generation unit 2641 modifies the background sound estimation result by employing the background sound upper-limit value, and generates the modified background sound estimation result. The modified background sound estimation result is set to the background sound upper-limit value when the background sound estimation result exceeds the background sound upper-limit value, and is set to the background sound estimation result itself when it does not exceed.

In addition, the suppression coefficient generation unit 2641 calculates the suppression coefficient for suppressing the background sound based upon the modified background sound estimation result and the second converted signal, and outputs it to the multiplier 251. It is disclosed in the Non-patent document 6 that a power of the background sound remaining in the after-suppression signal statistically becomes minimized in the case of calculating the suppression coefficient with the MMSE STSA.

The multiplier 251 multiplies the second converted signal by the suppression coefficient, and generates the modified decoded signal. The multiplier 251 outputs the modified decoded signal.

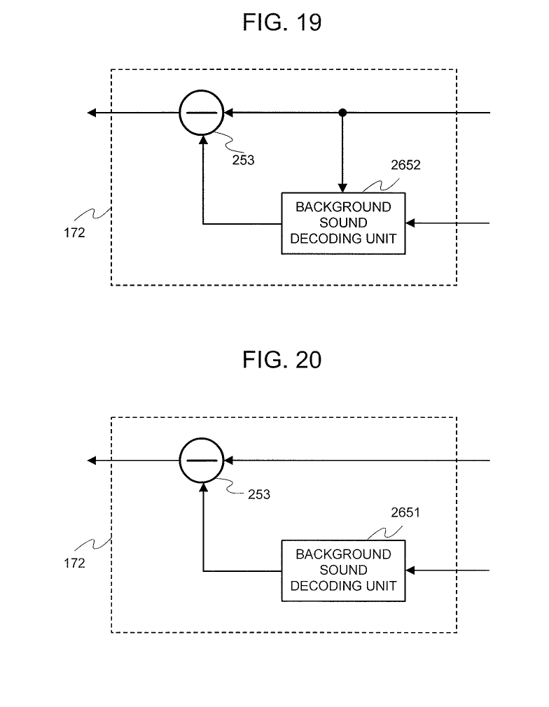

In addition, another configuration example of the signal processing unit 172 will be explained in details by making a reference to FIG. 19. The signal processing unit 172 receives the second converted signal and the background sound information, and outputs the signal of which the background sound has been subtracted as a modified decoded signal. The signal processing unit 172 of this configuration example is configured of a background sound decoding unit 2652 and a subtracter 253. The second converted signal is inputted into the subtracter 253 and the background sound decoding unit 2652, and the background sound information is inputted into the background sound decoding unit 2652 as analysis information. The background sound decoding unit 2652 decodes the background sound estimation result and the coefficient correction lower-limit value from the background sound information, and calculates the signal lower-limit value from the second converted signal and the coefficient correction lower-limit value. And, the background sound decoding unit 2652 calculates the background sound from the background sound estimation result and the signal lower-limit value, and outputs the background sound to the subtracter 253. When the background sound information has not been encoded, the background sound decoding unit 2652 calculates the background sound from the background sound estimation result and the coefficient correction lower-limit value without performing the decoding process. The subtracter 253 subtracts the background sound from the second converted signal. And, the subtracter 253 outputs the signal of which the background sound has been suppressed as a modified decoded signal. Additionally, the signal lower-limit value is expressive of the lower-limit value of the modified decoded signal. The background sound decoding unit 2652 calculates the background sound so that the modified decoded signal, being an output of the subtracter 253 existing in the downstream side thereof, does not fall under the signal lower-limit value. This subtraction is known as spectral subtraction when the background sound is noise. The technology relating to the spectral subtraction is disclosed in Non-patent document 9. Further, the technology relating to the signal lower-limit value is also disclosed in the Non-patent document 9.

<Non-patent document 9> IEEE TRANSACTIONS ON ACOUSTICS, SPEECH, AND SIGNAL PROCESSING, VOL. 27, NO. 2, pp. 113-120, April 1979

Further, an addition function besides the subtraction can be also incorporated into the subtracter 253. For example, the function of, when the subtraction result indicates a negative value, correcting this value to zero or a minute positive value, a limiter function of setting a minimum value of the subtraction result to a positive value, the function of, after correcting the subtraction result by multiplying the background sound information by the coefficient or adding a constant hereto, subtracting the background sound, or the like may be added to the subtracter 253.

In the case of employing the background sound upper-limit value instead of the coefficient correction lower-limit value, the background sound decoding unit 2652 receives the background sound information as analysis information, and decodes the background sound estimation result and the background sound upper-limit value from the background sound information. The background sound decoding unit 2652 calculates a first modified background sound estimation result by employing the background sound estimation result and the background sound upper-limit value. The first modified background sound estimation result is set to the background sound upper-limit value when the background sound estimation result exceeds the background sound upper-limit value, and is set to the background sound estimation result itself when it does not exceed. Further, the background sound decoding unit 2652 calculates the background sound from the second converted signal and the first modified background sound estimation result, and outputs it the subtracter 253. When the background sound information has not been encoded, the background sound decoding unit 2652 calculates the background sound from the background sound estimation result and the background sound upper-limit value without performing the decoding process. The subtracter 253 subtracts the background sound from the second converted signal. And, the subtracter 253 outputs the signal of which the background sound has been suppressed as a modified decoded signal.

The background sound can be obtained by modifying the first modified background sound estimation result, for example, with a modification quantity corresponding to the signal versus background sound ratio obtained from the second converted signal and the first modified background sound estimation result. Addition of the modification quantity and multiplication of the modification coefficient may be employed as such a modification, and magnitude of the addition quantity (subtraction quantity) or the modification coefficient is controlled responding to the signal versus background sound ratio. In particularly, modifying the first modified background sound estimation result so that the first modified background sound estimation result is small when the signal versus background sound ratio is small, and calculating the background sound yields an effect of reducing the distortion of the modified decoded signal that is outputted.

As another configuration of this example, the signal lower-limit value may be calculated in the analysis information calculation unit 121 within the signal analysis unit 101 to define the background sound information as the background sound estimation result and the signal lower-limit value instead of calculating the signal lower-limit value in the background sound decoding unit 2652. A configuration example of the analysis information calculation unit 121 of this example will be explained by making a reference to FIG. 15. The analysis information calculation unit 121 is configured of a background sound estimation unit 2051 and a background sound encoding unit 2061. The analysis information calculation unit 121 receives the second converted signal, and outputs the background sound information as analysis information. The background sound estimation unit 2051, similarly to the background sound estimation unit 200 of the first example, receives the second converted signal, estimates the background sound, and generates the background sound estimation result. Further, the background sound estimation unit 2051 calculates the signal lower-limit value from the second converted signal and the background sound estimation result. The background sound estimation unit 2051 outputs the background sound estimation result and the signal lower-limit value to the background sound encoding unit 2061. The background sound encoding unit 2061 encodes the inputted background sound estimation result and signal lower-limit value, and outputs the encoded background sound estimation result and signal lower-limit value as background sound information. With regard to the encoding process, an encoding process similar to the encoding process being performed in the suppression coefficient encoding unit 2021 can be employed. This makes it possible to suppress the redundancy of the background sound estimation result and the signal lower-limit value. Further, when the information quantity does not need to be curtailed, the background sound encoding unit 2061 may output the background sound estimation result and signal lower-limit value as background sound information without performing the encoding process therefor.

A configuration example of the signal processing unit 172 within the signal control unit 151 will be explained by making a reference to FIG. 20. The signal processing unit 172 receives the second converted signal and the background sound information, and outputs the signal of which the background sound has been subtracted as a modified decoded signal. The signal processing unit 172 of this configuration example is configured of a background sound decoding unit 2651 and a subtracter 253. The second converted signal is inputted into the subtracter 253, and the background sound information is inputted into the background sound decoding unit 2651 as analysis information. The background sound decoding unit 2651 decodes the background sound estimation result and the signal lower-limit value from the background sound information. Further, the background sound decoding unit 2651 calculates the background sound from the background sound estimation result and the signal lower-limit value, and outputs the background sound to the subtracter 253. When the background sound information has not been encoded, the background sound decoding unit 2651 calculates the background sound from the background sound estimation result and the signal lower-limit value without performing the decoding process. The subtracter 253 subtracts the background sound from the second converted signal. And, the subtracter 253 outputs the signal of which the background sound has been subtracted as a modified decoded signal.

In a fourth example, the signal analysis unit 101 calculates the suppression coefficient information as analysis information. A difference with the first example lies in a point that a main signal existence probability is newly included as suppression coefficient information in addition to the suppression coefficient and the coefficient correction lower-limit value. Herein, the main signal existence probability could be an objective sound existence probability. Hereinafter, the fourth example will be explained by employing the objective sound existence probability. The signal control unit 151, responding to this, controls the decoded signal by employing the suppression coefficient information. This makes it possible to obtain the signal of which the background sound has been suppressed in the input signal that is configured of the objective sound and the background sound.

At first, the signal analysis unit 101 will be explained. The signal analysis unit 101 is represented in FIG. 4 similarly to the signal analysis unit 101 of the first example. Upon comparing this example with the first example, this example differs in a configuration of the analysis information calculation unit 121.

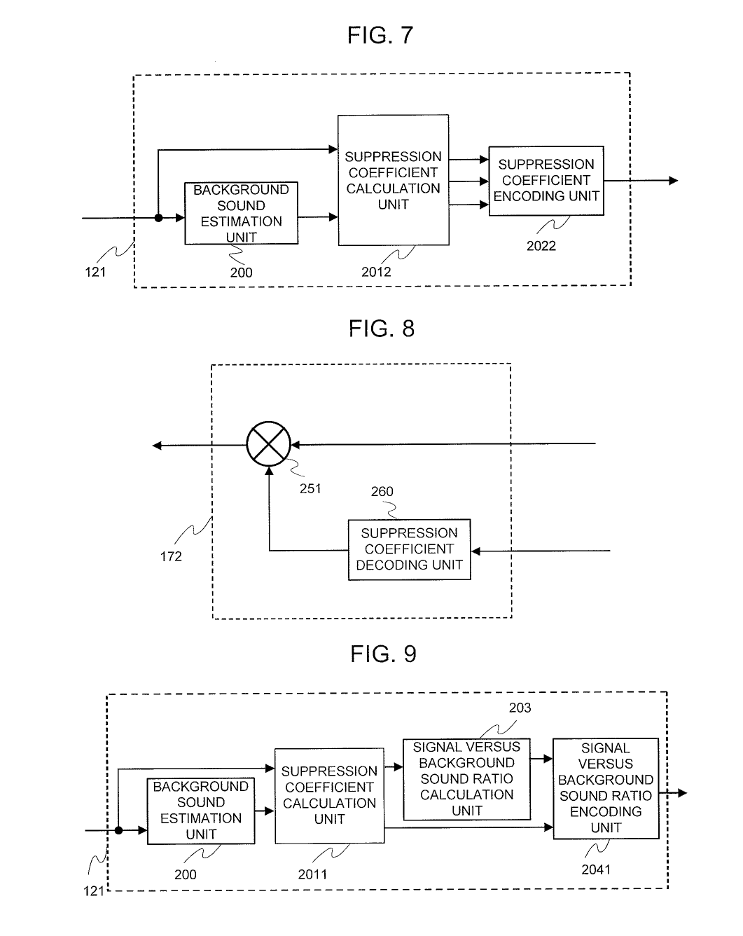

The analysis information calculation unit 121 of this example will be explained by making a reference to FIG. 7. The analysis information calculation unit 121 receives the second converted signal, and outputs the suppression coefficient information as analysis information. The analysis information calculation unit 121 is configured of a background sound estimation unit 200, a suppression coefficient calculation unit 2012, and a suppression coefficient encoding unit 2022.

The background sound estimation unit 200, similarly to the case of the first example, receives the second converted signal, estimates the background sound, generates the background sound estimation result, and outputs it to the suppression coefficient calculation unit 2012.

The suppression coefficient calculation unit 2012 calculates the suppression coefficient for suppressing the background sound, the coefficient correction lower-limit value, the objective sound existence probability by employing the second converted signal and the background sound estimation result. The objective sound existence probability, which is expressive of the extent to which the objective sound is included in the input signal, can be expressed, for example, with a ratio of the amplitude or the power of the objective sound and the background sound. This ratio itself, a short-time average, a maximum value, a minimum value, and so on may be employed as an objective sound existence probability. And, the suppression coefficient calculation unit 2012 outputs the suppression coefficient, the coefficient correction lower-limit value, and the objective sound existence probability to the suppression coefficient encoding unit 2022. As a method of calculating the suppression coefficient, the technology disclosed in the foregoing Non-patent document 6, Non-patent document 7, or Non-patent document 8, or the like may be employed. As a method of calculating the coefficient correction lower-limit value and the objective sound existence probability, the method disclosed in the foregoing Patent document 1 may be employed. Additionally, the fixed value may be pre-stored in the memory to read out and utilize it one by one instead of calculating the coefficient correction lower-limit value one by one.

The suppression coefficient encoding unit 2022 receives the suppression coefficient, the coefficient correction lower-limit value, and the objective sound existence probability, and encodes each of them. The suppression coefficient encoding unit 2022 outputs the encoded suppression coefficient, coefficient correction lower-limit value, and objective sound existence probability as suppression coefficient information. With regard to the details of the encoding process, the process explained in the foregoing quantization unit 111 is employed. The encoding makes it possible to remove the redundancy of the suppression coefficient, the coefficient correction lower-limit value, and the objective sound existence probability. Further, when the information quantity does not need to be curtailed, the suppression coefficient encoding unit 2022 may output the suppression coefficient, the coefficient correction lower-limit value, and the objective sound existence probability as suppression coefficient information without performing these encoding processes.

Next, the signal control unit 151 will be explained. The signal control unit 151, similarly to the case of the first example, is represented in FIG. 5. This example differs from the first example in a configuration of the signal processing unit 172.

A configuration example of the signal processing unit 172 will be explained in details by making a reference to FIG. 8. The signal processing unit 172 receives the second converted signal, and the suppression coefficient information as analysis information, and outputs the modified decoded signal. The signal processing unit 172 is configured of a suppression coefficient decoding unit 260, and a multiplier 251.

The suppression coefficient decoding unit 260 decodes the suppression coefficient, the coefficient correction lower-limit value, and the objective sound existence probability from the received suppression coefficient information, and calculates the corrected suppression coefficient from the suppression coefficient, the coefficient correction lower-limit value, and the objective sound existence probability. When the suppression coefficient, the coefficient correction lower-limit value, and the objective sound existence probability have not been encoded, the suppression coefficient decoding unit 260 directly calculates the corrected suppression coefficient from the suppression coefficient, the coefficient correction lower-limit value, and the objective sound existence probability without performing the decoding process. As a method of calculating the corrected suppression coefficient from the suppression coefficient, the coefficient correction lower-limit value, and the objective sound existence probability, the method disclosed in the Patent document 1 may be employed. The multiplier 251 multiplies the second converted signal by the corrected suppression coefficient, and generates the modified decoded signal. The multiplier 251 outputs the modified decoded signal.

In a fifth example, the signal analysis unit 101 calculates the signal versus background sound ratio information as analysis information. A difference with the second example lies in a point that the objective sound existence probability is newly included as signal versus background sound ratio information in addition to the signal versus background sound ratio and the coefficient correction lower-limit value. The signal control unit 151, responding to this, controls the decoded signal by employing the signal versus background sound ratio information. This makes it possible to obtain the signal of which the background sound has been suppressed in the input signal that is configured of the objective sound and the background sound.

At first, the signal analysis unit 101 will be explained. The signal analysis unit 101 is represented in FIG. 4 similarly to the case of the first example. Upon comparing this example with the first example, this example differs in a configuration of the analysis information calculation unit 121.

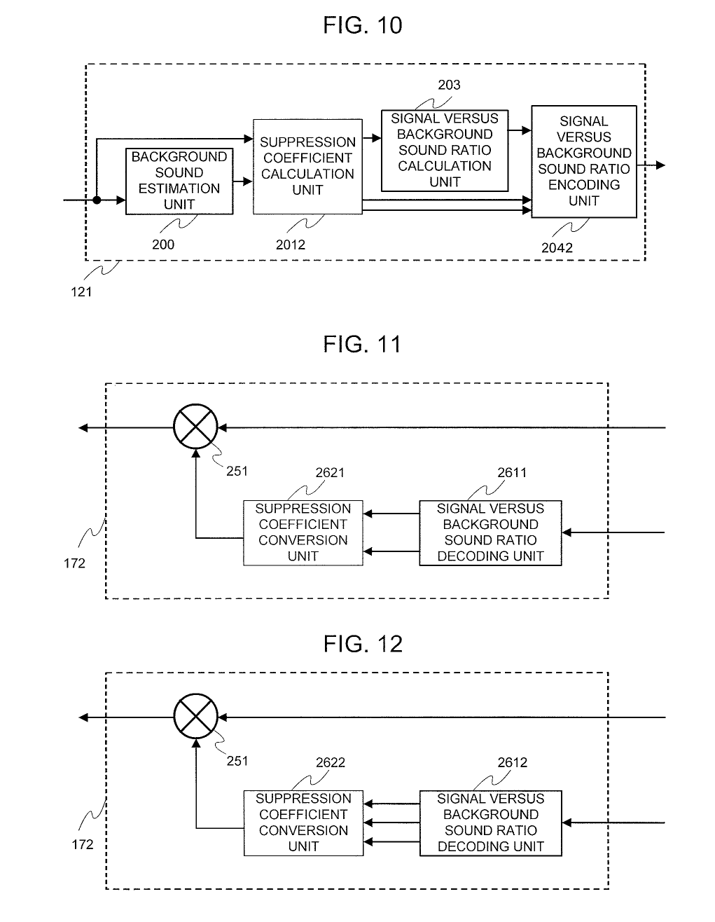

The analysis information calculation unit 121 of this example will be explained by making a reference to FIG. 10. The analysis information calculation unit 121 receives the second converted signal, and outputs the signal versus background sound ratio information as analysis information. The analysis information calculation unit 121 is configured of a background sound estimation unit 200, a suppression coefficient calculation unit 2012, a signal versus background sound ratio calculation unit 203, and a signal versus background sound ratio encoding unit 2042.

The background sound estimation unit 200, similarly to the case of the first example, receives the second converted signal, and estimates the background sound. And, the background sound estimation unit 200 generates the background sound estimation result. And, the background sound estimation unit 200 outputs the background sound estimation result to the suppression coefficient calculation unit 2012.

The suppression coefficient calculation unit 2012 calculates the suppression correction for suppressing the background sound, the coefficient correction lower-limit value, and the objective sound existence probability by employing the second converted signal and the background sound estimation result. And, the suppression coefficient calculation unit 2012 outputs the suppression coefficient to the signal versus background sound ratio calculation unit 203, and outputs the coefficient correction lower-limit value and the objective sound existence probability to the signal versus background sound ratio encoding unit 2042. As a method of calculating the suppression coefficient, the coefficient correction lower-limit value, and the objective sound existence probability, the calculation method of the suppression coefficient calculation unit 2012 of the first example shown in FIG. 7 may be employed. The signal versus background sound ratio calculation unit 203 calculates the signal versus background sound ratio R based upon [Numerical equation 4] by employing the inputted suppression coefficient G.

The signal versus background sound ratio calculation unit 203 outputs the signal versus background sound ratio R calculated with [Numerical equation 4] to the signal versus background sound ratio encoding unit 2042. The signal versus background sound ratio encoding unit 2042 encodes the inputted signal versus background sound ratio R, coefficient correction lower-limit value, and objective sound existence probability. The signal versus background sound ratio encoding unit 2042 outputs the encoded signal versus background sound ratio R, coefficient correction lower-limit value, and objective sound existence probability as signal versus background sound ratio information. With regard to the details of the encoding process, an encoding process similar to the encoding process in the suppression coefficient encoding unit 2022 can be employed. This makes it possible to remove the redundancy of the signal versus background sound ratio R, the coefficient correction lower-limit value, and the objective sound existence probability. Further, when the information quantity does not need to be curtailed, the signal versus background sound ratio encoding unit 2042 may output the signal versus background sound ratio, the coefficient correction lower-limit value, and the objective sound existence probability as signal versus background sound ratio information without performing the encoding process for the signal versus background sound ratio R, the coefficient correction lower-limit value, and the objective sound existence probability.

In addition, similarly to the case of the second example, the signal versus background sound ratio lower-limit value associated with the signal versus background sound ratio R may be employed instead of the coefficient correction lower-limit value. That is, when the suppression coefficient G becomes small, the signal versus background sound ratio R as well becomes small similarly. This signifies that changing the lower-limit value of the suppression coefficient G into that of the signal versus background sound ratio R by employing the appropriate conversion makes it possible to prevent the signal versus background sound ratio R from becoming excessively small. At this time, the suppression coefficient calculation unit 2012 calculates the suppression coefficient, the signal versus background sound ratio lower-limit value, and the objective sound existence probability. Similarly to the suppression coefficient lower-limit value in the suppression coefficient calculation unit 2011 of the first example shown in FIG. 6, the signal versus background sound ratio lower-limit value can be calculated responding to the signal versus background sound ratio. The suppression coefficient calculation unit 2012 outputs the suppression coefficient to the signal versus background sound ratio calculation unit 203, and outputs the signal versus background sound ratio lower-limit value and the objective sound existence probability to the signal versus background sound ratio encoding unit 2042. The signal versus background sound ratio encoding unit 2042 encodes the inputted signal versus background sound ratio R, signal versus background sound ratio lower-limit value, and objective sound existence probability. The signal versus background sound ratio encoding unit 2042 outputs the encoded signal versus background sound ratio R, signal versus background sound ratio lower-limit value, and objective sound existence probability as signal versus background sound ratio information.

Next, the signal control unit 151 will be explained. The signal control unit 151, similarly to the case of the first example, is represented in FIG. 5. This example differs from the first example in a configuration of the signal processing unit 172.

A configuration example of the signal processing unit 172 will be explained in details by making a reference to FIG. 12. The signal processing unit 172 receives the second converted signal, and the signal versus background sound ratio information as analysis information, and outputs the modified decoded signal. The signal processing unit 172 is configured of a signal versus background sound ratio decoding unit 2612, a suppression coefficient conversion unit 2622, and a multiplier 251.

The signal versus background sound ratio decoding unit 2612 decodes the signal versus background sound ratio R, the coefficient correction lower-limit value, and the objective sound existence probability from the received signal versus background sound ratio information, and outputs the signal versus background sound ratio R, the coefficient correction lower-limit value, and the objective sound existence probability to the suppression coefficient conversion unit 2622. When the signal versus background sound ratio R, the coefficient correction lower-limit value, and the objective sound existence probability have not been encoded, the signal versus background sound ratio decoding unit 2612 directly outputs the signal versus background sound ratio R, the coefficient correction lower-limit value, and the objective sound existence probability without performing the decoding process.

The suppression coefficient conversion unit 2622 converts the signal versus background sound ratio R into the suppression coefficient G, and calculates the corrected suppression coefficient from the suppression coefficient G, the coefficient correction lower-limit value, and the objective sound existence probability. And, the suppression coefficient conversion unit 2622 outputs the corrected suppression coefficient. The conversion from the signal versus background sound ratio R into the suppression coefficient G is performed based upon [Numerical equation 4].

The multiplier 251 multiplies the second converted signal by the corrected suppression coefficient, and generates the modified decoded signal. The multiplier 251 outputs the modified decoded signal.

In the case of employing the signal versus background sound ratio lower-limit value instead of the coefficient correction lower-limit value, the signal versus background sound ratio decoding unit 2612 decodes the signal versus background sound ratio R, the signal versus background sound ratio lower-limit value, and the objective sound existence probability from the received signal versus background sound ratio information, and outputs them to the suppression coefficient conversion unit 2622. When the signal versus background sound ratio R, signal versus background sound ratio lower-limit value, and the objective sound existence probability have not been encoded, the signal versus background sound ratio decoding unit 2612 directly outputs the signal versus background sound ratio R, the signal versus background sound ratio lower-limit value, and the objective sound existence probability without performing the decoding process. The suppression coefficient conversion unit 2622 obtains the corrected signal versus background sound ratio from the signal versus background sound ratio R, signal versus background sound ratio lower-limit value, and the objective sound existence probability. In addition, the suppression coefficient conversion unit 2622 applies [Numerical equation 5] with the corrected signal versus background sound ratio defined as R, and outputs the obtained G to the multiplier 251 as a corrected suppression coefficient.

Continuously, another configuration example of the analysis information calculation unit 121 will be explained in details by making a reference to FIG. 14. Upon making a comparison with the analysis information calculation unit 121 shown in FIG. 10, the analysis information calculation unit 121 of this configuration example differs in a point of not including the suppression coefficient calculation unit 2012. Further, a signal versus background sound ratio calculation unit 2072 of this configuration example calculates the signal versus background sound ratio, the coefficient correction lower-limit value, and the objective sound existence probability based upon the second converted signal and the background sound estimation result. In a configuration of the analysis information calculation unit 121 shown in FIG. 14, [Numerical equation 6] is employed as a definition of the signal versus background sound ratio R instead of [Numerical equation 3].

That is, this configuration example is configured to employ the posterior SNR as analysis information instead of the prior SNR when the background sound is noise. R of [Numerical equation 6], which does not demand the suppression coefficient G, is calculated from the input signal and the background sound. This enables the signal versus background sound ratio calculation unit 2072 to calculate the signal versus background sound ratio based upon the second converted signal and the background sound estimation result. Additionally, the coefficient correction lower-limit value and the objective sound existence probability can be calculated similarly to the case of the suppression coefficient calculation unit 2012 of the first example shown in FIG. 7. And, the signal versus background sound ratio calculation unit 2072 outputs the signal versus background sound ratio, the coefficient correction lower-limit value, and the objective sound existence probability to the signal versus background sound ratio encoding unit 2042. An operation of the signal versus background sound ratio encoding unit 2042 is similar to that of the signal versus background sound ratio encoding unit 2042 shown in FIG. 10, so its explanation is omitted. The signal versus background sound ratio calculation unit 203 may calculate the signal versus background sound ratio R by employing [Numerical equation 7].

The signal versus background sound ratio lower-limit value associated with the signal versus background sound ratio R may be employed instead of the coefficient correction lower-limit value. In this case, the signal versus background sound ratio calculation unit 2072 calculates the signal versus background sound ratio, the signal versus background sound ratio lower-limit value, and the objective sound existence probability based upon the second converted signal and the background sound estimation result. The signal versus background sound ratio calculation unit 2072 outputs the signal versus background sound ratio, the signal versus background sound ratio lower-limit value, and the objective sound existence probability to the signal versus background sound ratio encoding unit 2042. The signal versus background sound ratio encoding unit 2042 encodes the inputted signal versus background sound ratio R, signal versus background sound ratio lower-limit value and objective sound existence probability. The signal versus background sound ratio encoding unit 2042 outputs the encoded signal versus background sound ratio R, signal versus background sound ratio lower-limit value, and objective sound existence probability as signal versus background sound ratio information.

In this configuration example, the signal processing unit 172 of the receiving side is represented in FIG. 12 similarly to the case of the foregoing configuration example. The signal versus background sound ratio decoding unit 2612 decodes the signal versus background sound ratio R, the coefficient correction lower-limit value, and the objective sound existence probability from the received signal versus background sound ratio information, and outputs the signal versus background sound ratio R, the coefficient correction lower-limit value, and the objective sound existence probability to the suppression coefficient conversion unit 2622. The suppression coefficient conversion unit 2622 converts the signal versus background sound ratio R into the suppression coefficient G, calculates the corrected suppression coefficient from the suppression coefficient G, the coefficient correction lower-limit value, and the objective sound existence probability, and outputs the corrected suppression coefficient. The conversion from the signal versus background sound ratio R into the suppression coefficient G is performed based upon [Numerical equation 8].

In the case of employing the signal versus background sound ratio lower-limit value associated with the signal versus background sound ratio R instead of the coefficient correction lower-limit value, the signal versus background sound ratio decoding unit 2612 decodes the signal versus background sound ratio R, the signal versus background sound ratio lower-limit value, and the objective sound existence probability from the received signal versus background sound ratio information, corrects the signal versus background sound ratio R with the signal versus background sound ratio lower-limit value and the objective sound existence probability, and obtains the corrected signal versus background sound ratio. Further, the signal versus background sound ratio decoding unit 2612 outputs the corrected signal versus background sound ratio to the suppression coefficient conversion unit 2622. The suppression coefficient conversion unit 2622 applies [Numerical equation 8] with the corrected signal versus background sound ratio defined as R, and outputs the obtained G to the multiplier 251 as a suppression coefficient.

Continuously, a sixth example will be explained. In the sixth example, the signal analysis unit 101 outputs the background sound information as analysis information. A difference with the third example lies in a point that the objective sound existence probability is newly included as background sound information in addition to the background sound estimation result and the coefficient correction lower-limit value. The signal control unit 151, responding to this, controls the decoded signal by employing the background sound information. This makes it possible to obtain the signal of which the background sound has been suppressed in the input signal that is configured of the objective sound and the background sound.

At first, the signal analysis unit 101 will be explained. The signal analysis unit 101 is represented in FIG. 4 similarly to the case of the first example. A configuration of the analysis information calculation unit 121 of this example differs from that of the first example.

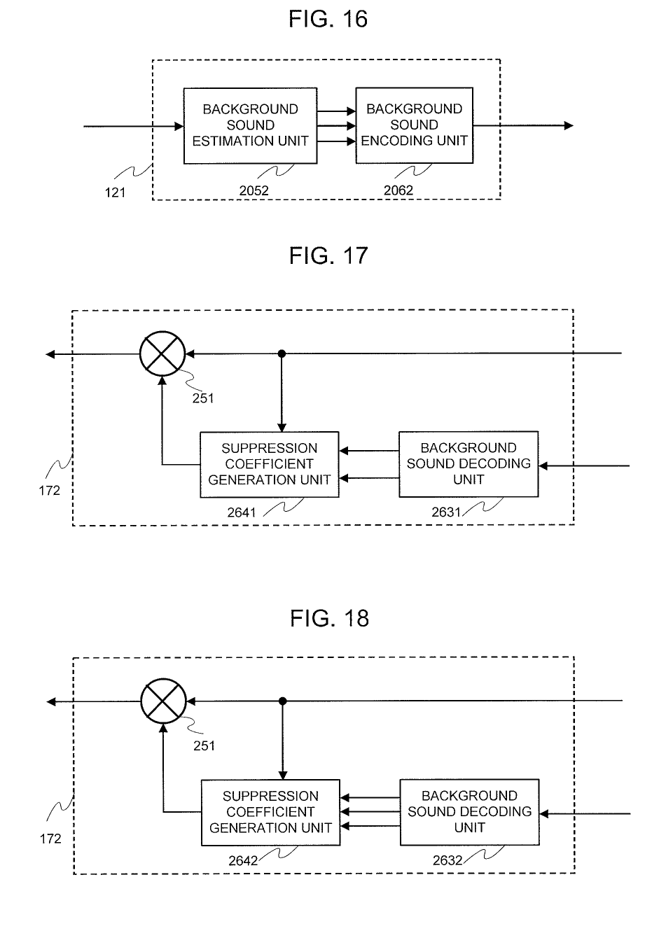

A configuration example of the analysis information calculation unit 121 of this example will be explained in details by making a reference to FIG. 16. The analysis information calculation unit 121 is configured of a background sound estimation unit 2052, and a background sound encoding unit 2062. The analysis information calculation unit 121 receives the second converted signal, and outputs the background sound information as analysis information. The background sound estimation unit 2052, similarly to the background sound estimation unit 200 of the first example, receives the second converted signal, estimates the background sound, and generates the background sound estimation result. Further, the background sound estimation unit 2052, similarly to the suppression coefficient calculation unit 2012 of the first example shown in FIG. 7, calculates the coefficient correction lower-limit value, and the objective sound existence probability. The background sound estimation unit 2052 outputs the background sound estimation result, the coefficient correction lower-limit value, and the objective sound existence probability to the background sound encoding unit 2062. The background sound encoding unit 2062 encodes the inputted background sound estimation result, coefficient correction lower-limit value, and objective sound existence probability, and outputs the encoded background sound estimation result, coefficient correction lower-limit value, and objective sound existence probability as background sound information. With regard to the encoding process, an encoding process similar to the encoding process of the suppression coefficient encoding unit 2022 can be employed. This makes it possible to remove the redundancy of the background sound estimation result, the coefficient correction lower-limit value, and the objective sound existence probability. Further, when the information quantity does not need to be curtailed, the background sound encoding unit 2062 may output the background sound estimation result, the coefficient correction lower-limit value, and the objective sound existence probability without performing the encoding process therefor.

The background sound upper-limit value may be employed instead of the coefficient correction lower-limit value. In this case, the background sound estimation unit 2052 calculates the background sound, the background sound upper-limit value, and the objective sound existence probability based upon the second converted signal. The background sound estimation unit 2052 outputs the background sound, the background sound upper-limit value, and the objective sound existence probability to the background sound encoding unit 2062. The background sound encoding unit 2062 encodes the inputted background sound, background sound upper-limit value, and objective sound existence probability. The background sound encoding unit 2062 outputs the encoded background sound, background sound upper-limit value, and objective sound existence probability as background sound information.

Next, the signal control unit 151 will be explained. The signal control unit 151, similarly to the case of the first example, is represented in FIG. 5. This example differs from the first example in a configuration of the signal processing unit 172.

A configuration example of the signal processing unit 172 will be explained in details by making a reference to FIG. 18. The signal processing unit 172 receives the second converted signal, and the background sound information as analysis information, and outputs the modified decoded signal. The signal processing unit 172 is configured of a background sound decoding unit 2632, a suppression coefficient generation unit 2642, and a multiplier 251.

The background sound decoding unit 2632 decodes the background sound estimation result, the coefficient correction lower-limit value, and the objective sound existence probability from the background sound information, and outputs the background sound estimation result, the coefficient correction lower-limit value, and the objective sound existence probability to the suppression coefficient generation unit 2642. When the background sound estimation result, the coefficient correction lower-limit value, and the objective sound existence probability have not been encoded, the background sound decoding unit 2632 outputs the background sound estimation result, the coefficient correction lower-limit value, and the objective sound existence probability without performing the decoding process.

The suppression coefficient generation unit 2642 receives the background sound estimation result, the coefficient correction lower-limit value, the objective sound existence probability, and the second converted signal. And, the suppression coefficient generation unit 2642 calculates the suppression coefficient for suppressing the background sound based upon the background sound estimation result and the second converted signal. A calculation method similar to the calculation method of the suppression coefficient calculation unit 2012 shown in FIG. 10 may be employed for calculating this suppression coefficient. In addition, the suppression coefficient generation unit 2642 calculates the corrected suppression coefficient from the suppression coefficient, the coefficient correction lower-limit value, and the objective sound existence probability, and outputs the corrected suppression coefficient. As a method of calculating the corrected suppression coefficient, the method disclosed in the foregoing Non-patent document 6, Non-patent document 7, or Non-patent document 8, or the like may be employed.

The multiplier 251 multiplies the second converted signal by the corrected suppression coefficient, and generates the modified decoded signal. The multiplier 251 outputs the modified decoded signal.

In the case of employing the background sound upper-limit value instead of the coefficient correction lower-limit value, the background sound decoding unit 2632 receives the background sound information as analysis information, and decodes the background sound estimation result, the background sound upper-limit value, and the objective sound existence probability from the background sound information. The background sound decoding unit 2632 outputs the background sound estimation result, the background sound upper-limit value, and the objective sound existence probability to the suppression coefficient generation unit 2642. When the background sound estimation result, the background sound upper-limit value, and the objective sound existence probability have not been encoded, the background sound decoding unit 2632 outputs the background sound estimation result, the background sound upper-limit value, and the objective sound existence probability without performing the decoding process.

The suppression coefficient generation unit 2642 receives the background sound estimation result, the background sound upper-limit value, the objective sound existence probability, and the second converted signal. Further, the suppression coefficient generation unit 2642 modifies the background sound estimation result by employing the background sound upper-limit value and the objective sound existence probability, and calculates the modified background sound estimation result. In addition, the suppression coefficient generation unit 2642 calculates the suppression coefficient for suppressing the background sound based upon the modified background sound estimation result and the second converted signal, and outputs it to the multiplier 251. The multiplier 251 multiplies the second converted signal by the suppression coefficient, and generates the modified decoded signal. The multiplier 251 outputs the modified decoded signal.

In addition, another configuration example of the signal processing unit 172 will be explained in details by making a reference to FIG. 19. The signal processing unit 172 receives the second converted signal and the background sound information, and outputs the signal of which the background sound has been subtracted as a modified decoded signal. The signal processing unit 172 of this configuration example is configured of a background sound decoding unit 2652 and a subtracter 253. The second converted signal is inputted into the subtracter 253 and the background sound decoding unit 2652, and the background sound information is inputted into the background sound decoding unit 2652 as analysis information. The background sound decoding unit 2652 decodes the background sound estimation result, the coefficient correction lower-limit value, the objective sound existence probability from the background sound information, calculates the signal lower-limit value from the second converted signal, the coefficient correction lower-limit value, and the objective sound existence probability, calculates the background sound from the background sound estimation result and the signal lower-limit value, and outputs the background sound to the subtracter 253. When the background sound information has not been encoded, the background sound decoding unit 2652 calculates the background sound from the background sound estimation result, the coefficient correction lower-limit value, and the objective sound existence probability without performing the decoding process. The subtracter 253 subtracts the background sound from the second converted signal. And, the subtracter 253 outputs the signal of which the background sound has been suppressed as a modified decoded signal. Additionally, the signal lower-limit value is expressive of the lower-limit value of the modified decoded signal. And, the background sound decoding unit 2652 calculates the background sound so that the modified decoded signal, being an output of the subtracter 253 existing in the downstream side thereof, does not fall under the signal lower-limit value. This subtraction is known as spectral subtraction when the background sound is noise. The technology relating to the spectral subtraction is disclosed in Non-patent document 9. Further, the technology relating to the signal lower-limit value is also disclosed in the Non-patent document 9.

Further, an addition function besides the subtraction can be incorporated into the subtracter 253. For example, the function of, when the subtraction result indicates a negative value, correcting this value to zero or a minute positive value, a limiter function of setting a minimum value of the subtraction result to a positive value, the function of, after correcting the subtraction result by multiplying the background sound information by the coefficient or adding a constant hereto, subtracting the background sound, or the like may be added to the subtracter 253.

In the case of employing the background sound upper-limit value instead of the coefficient correction lower-limit value, the background sound decoding unit 2652 receives the background sound information as analysis information, and decodes the background sound estimation result, the background sound upper-limit value, and the objective sound existence probability from the background sound information. The background sound decoding unit 2652 calculates a first modified background sound estimation result by employing the background sound estimation result, the background sound upper-limit value, and the objective sound existence probability. Further, the background sound decoding unit 2652 calculates the background sound from the second converted signal and the first modified background sound estimation result, and outputs it to the subtracter 253. When the background sound information has not been encoded, the background sound decoding unit 2652 calculates the background sound from the background sound estimation result, the background sound upper-limit value, and the objective sound existence probability without performing the decoding process. The subtracter 253 subtracts the background sound from the second converted signal. And, the subtracter 253 outputs the signal of which the background sound has been suppressed as a modified decoded signal.

The background sound can be obtained by modifying the first modified background sound estimation result, for example, with a modification quantity corresponding to the signal versus background sound obtained from the second converted signal and the first modified background sound estimation result. Addition of the modification quantity and multiplication of the modification coefficient may be employed as such a modification, and magnitude of the addition quantity (subtraction quantity) or the modification coefficient is controlled responding to the signal versus background sound ratio. In particularly, modifying the first modified background sound estimation result so that the first modified background sound estimation result is small when the signal versus background sound ratio is small, and calculating the background sound yields an effect of reducing the distortion of the modified decoded signal that is outputted.

In this example, the signal lower-limit value may be calculated in the analysis information calculation unit 121 within the signal analysis unit 101 to define the background sound information as the background sound estimation result, the signal lower-limit value, and the objective sound existence probability instead of calculating the signal lower-limit value in the background sound decoding unit 2652. A configuration example of the analysis information calculation unit 121 of this example will be explained by making a reference to FIG. 16. The analysis information calculation unit 121 is configured of a background sound estimation unit 2052 and a background sound encoding unit 2062. The analysis information calculation unit 121 receives the second converted signal, and outputs the background sound information as analysis information. The background sound estimation unit 2052, similarly to the background sound estimation unit 200 of the first example, receives the second converted signal, estimates the background sound, and generates the background sound estimation result. Further, the background sound estimation unit 2052 calculates the signal lower-limit value from the second converted signal and the background sound estimation result. The background sound estimation unit 2052 outputs the background sound estimation result, the signal lower-limit value, and the objective sound existence probability to the background sound encoding unit 2062. The background sound encoding unit 2062 encodes the inputted background sound estimation result, signal lower-limit value, and objective sound existence probability, and outputs the encoded background sound estimation result, signal lower-limit value, and objective sound existence probability as background sound information. With regard to the encoding process, an encoding process similar to the encoding process being performed in the suppression coefficient encoding unit 2022 can be employed. This makes it possible to remove the redundancy of the background sound estimation result, the signal lower-limit value, and the objective sound existence probability. Further, when the information quantity does not need to be curtailed, the background sound encoding unit 2062 may output the background sound estimation result, the signal lower-limit value and the objective sound existence probability as background sound information without performing the encoding process therefor.

A configuration example of the signal processing unit 172 within the signal control unit 151 will be explained by making a reference to FIG. 20. The signal processing unit 172 receives the second converted signal and the background sound information, and outputs the signal of which the background sound has been suppressed as a modified decoded signal. The signal processing unit 172 of this configuration example is configured of a background sound decoding unit 2651 and a subtracter 253. The second converted signal is inputted into the subtracter 253, and the background sound information is inputted into the background sound decoding unit 2651 as analysis information. The background sound decoding unit 2651 decodes the background sound estimation result, the signal lower-limit value, and the objective sound existence probability from the background sound information, and calculates the background sound from the background sound estimation result, the signal lower-limit value, and the objective sound existence probability, and outputs the background sound to the subtracter 253. When the background sound information has not been encoded, the background sound decoding unit 2651 calculates the background sound from the background sound estimation result, the signal lower-limit value, and the objective sound existence probability without performing the decoding process. The subtracter 253 subtracts the background sound from the second converted signal. And, the subtracter 253 outputs the signal of which the background sound has been suppressed as a modified decoded signal.

In addition, in this embodiment, the transmission unit 10 may calculate the analysis information of the above-mentioned first to sixth examples independently channel by channel when the input signal is configured of a plurality of channels. Further, the transmission unit 10 may calculate a sum of all channels of the input signal, and calculate the analysis information common to all channels from the summed signals. Or, the transmission unit 10 may divide the input signal into a plurality of groups, calculate a sum of the input signals of respective groups, and calculate the analysis information common to the group from the above summed signals. The receiving unit 15, responding to this, controls the decoded signal by employing the analysis information corresponding to each channel.

Further, the analysis information explained in the above-mentioned first to sixth examples may be calculated as analysis information common to a plurality of the frequency bands. For example, the transmission unit 10 may divide the frequency band at an equal interval, and calculate the analysis information for each divided frequency band. In addition, the transmission unit 10 may divide the input signal into fine frequency bands to an auditory feature of a human being with regard to the low-frequency area, divide the input signal into rough frequency bands with regard to the high-frequency area, and calculate the analysis information in a divided unit. This makes it possible to curtail the information quantity of the analysis information.

As explained above, the second embodiment of the present invention makes it possible to control the input signal, which is configured of the objective sound and the background sound, because the transmission unit analyzes the signal. In addition, the receiving unit can curtail the arithmetic quantity relating to the calculation of the analysis information because the transmission unit calculates the analysis information such as the suppression coefficient and the signal versus background sound ratio.

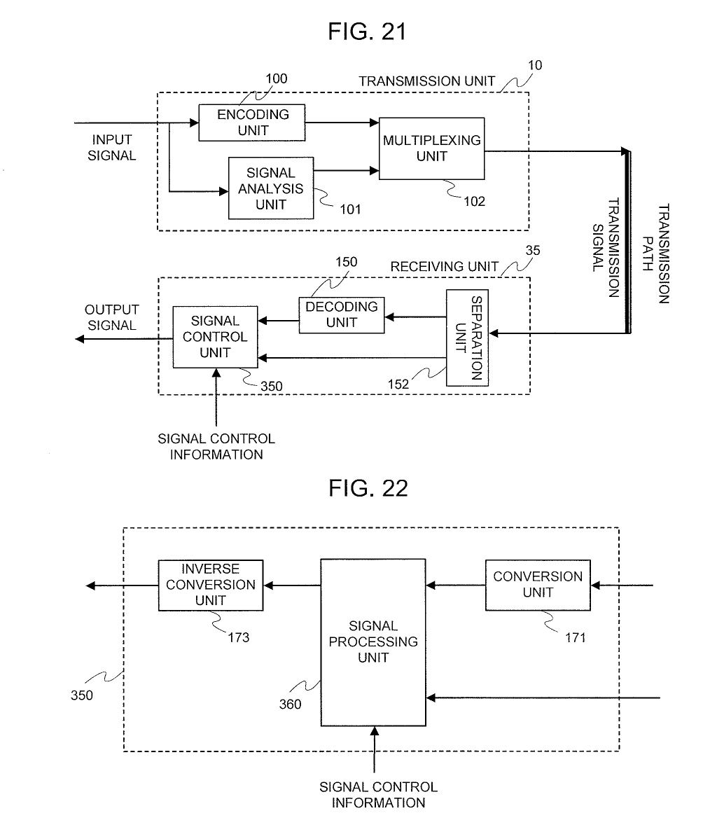

Continuously, a third embodiment of the present invention will be explained in details by making a reference to FIG. 21. In the third embodiment of the present invention, a receiving unit 35, which assumes a configuration in which the signal control information can be received, can control a specific sound source independently. Upon comparing the third embodiment shown in FIG. 21 with the first embodiment shown in FIG. 1, while the receiving unit 15 is configured of the signal control unit 151, the receiving unit 35 is configured of a signal control unit 350. Further, in this example, the transmission unit, the transmission path, and the receiving unit could be a recoding unit, a storage medium, and a reproduction unit, respectively. From now on, explanation of the portion which overlaps FIG. 1 is omitted.

A configuration example of the signal control unit 350 will be explained in details by making a reference to FIG. 22. The signal control unit 350 is configured of a conversion unit 171, a signal processing unit 360 and an inverse conversion unit 173. Upon making a comparison with the first embodiment, while the signal control unit 151 is configured of the signal processing unit 172, the signal control unit 350 is configured of a signal processing unit 360 in this embodiment. The signal control unit 350 receives the analysis information and the signal control information, and outputs the output signal. The signal control unit 350 manipulates the decoded signal received from the decoding unit 150 for each component element corresponding to each sound source, based upon the signal control information and the analysis information. Further, the signal control unit 350 also can manipulate the decoded signal with the component element group, which is configured of a plurality of the component elements, defined as a unit instead of the component element corresponding to each sound source. The signal processing unit 360 receives the second converted signal coming from the conversion unit 171 and the signal control information. The signal processing unit 360 controls the component element of the frequency component of the second converted signal based upon the analysis information and the signal control information, and generates the modified decoded signal. The signal processing unit 360 outputs the modified decoded signal to the inverse conversion unit 173.

In addition, specifically, the signal processing unit 360 derives a by-frequency analysis parameter based upon the analysis information. And, the signal processing unit 360 decomposes the second converted signal into the component elements corresponding to the sound resources based upon the analysis parameter. In addition, the signal processing unit 360 prepares the modified decoded signal in which a relation between of a plurality of the component elements has been changed, responding to the by-frequency analysis parameter based upon the signal control information. The signal processing unit 360 outputs the modified decoded signal to the inverse conversion unit 173. Further, the signal processing unit 360 may decompose the second converted signal based upon the analysis parameter for each component element groups that is configured of a plurality of the component elements.

Continuously, the method of preparing the modified decoded signal will be specifically explained.

Upon defining the frequency component of the decoded signal (namely, the second converted signal) in a certain frequency band f as Xₖ(f), k=1, 2, . . . , P (P is the number of the channels of the decoded signal), the frequency component of the component element as Yⱼ(f), j=1, 2, . . . , M (M is the number of the component elements), the frequency component of the component element modified based upon the signal control information as Y′ⱼ(f), and the modified decoded signal as X′ₖ(f), the following relation holds by employing a conversion function F₅₀₁ being specified with the analysis parameter, and a conversion function F₅₀₂ being specified with the signal control information.

Yⱼ(f)=F₅₀₁(X₁(f),X₂(f), . . . , X_{P}(f)) [Numerical equation 9]

Y′ⱼ(f)=F₅₀₂(Yⱼ(f)) [Numerical equation 10]

X′ₖ(f)=F₅₀₃(Y′ⱼ(f)) [Numerical equation 11]

Where, the conversion function F₅₀₃ is a function for converting the modified component element into the modified decoded signal.

Further, integration of the conversion functions F₅₀₀, F₅₀₁, F₅₀₂, and F₅₀₃ can also lead to the following equation.

X′(f)=F₅₀₄(X(f)) [Numerical equation 12]

At this time, the conversion function F₅₀₄ is specified with the analysis parameter and the signal control information.

As a specific example of the above-mentioned function, upon expressing an analysis parameter B(f) of the frequency band f by the following [Numerical equation 13], and a by-frequency parameter A(f), which is governed responding to the signal control information, by the following [Numerical equation 14], [Numerical equation 9] to [Numerical equation 12] can be expressed by the following [Numerical equation 15].

$$\begin{matrix}B ( f ) = [ \begin{matrix}{C}_{11} ( f ) & {C}_{12} ( f ) & K & {C}_{1 P} ( f ) \\ {C}_{21} ( f ) & {C}_{22} ( f ) & K & {C}_{2 P} ( f ) \\ M & M & O & M \\ {C}_{M 1} ( f ) & {C}_{M 2} ( f ) & K & {C}_{MP} ( f )\end{matrix} ] & [ Numerical equation 13 ] \\ A ( f ) = [ \begin{matrix}{A}_{1} ( f ) & 0 & K & 0 \\ 0 & {A}_{2} ( f ) & K & 0 \\ M & M & O & M \\ 0 & 0 & K & {A}_{M} ( f )\end{matrix} ] & [ Numerical equation 14 ] \\ X ( f ) = [ \begin{matrix}{X}_{1} ( f ) \\ {X}_{2} ( f ) \\ M \\ {X}_{P} ( f )\end{matrix} ] \\ Y ( f ) = B ( f ) \cdot X ( f ) , \\ \begin{matrix}{Y}^{′} ( f ) = A ( f ) \cdot Y ( f ) \\ = A ( f ) \cdot B ( f ) \cdot X ( f ) ,\end{matrix} \\ \begin{matrix}{X}^{′} ( f ) = D ( f ) \cdot {Y}^{′} ( f ) \\ = D ( f ) \cdot A ( f ) \cdot B ( f ) \cdot X ( f )\end{matrix} & [ Numerical equation 15 ]\end{matrix}$$

That is, a matrix for converting the decoded signal into the modified decoded signal can be calculated as D(f)×A(f)×B(f). Where, D(f) is an arbitrary P-row and M-column matrix, and for example, an inverse matrix of B(f) can be employed as D(f). Additionally, as apparent from [Numerical equation 15], it is appropriate as a manipulation of converting the modified component element into the modified decoded signal to employ the inverse matrix of B(f) as D(f).

A configuration may be made so that the signal control information is inputted from the outside by a user. For example, as signal control information being inputted from the outside, there exists personal information such as a taste of the user pre-registered into the receiving unit, an operational status of the receiving unit (including external environment information such as a switched-off loudspeaker), a kind or a format of the receiving unit, a use status of a power source and a cell or its residual quantity, and a kind and a status of an antenna (a shape of being folded in, its direction, etc.). Further, a configuration may be made so that the signal control information is automatically captured in the other formats. A configuration may be made so that the signal control information is automatically captured via a sensor installed inside or near to the receiving unit. For example, as signal control information being automatically captured, there exists a quantity of the external noise, brightness, a time band, a geometric position, a temperature, information synchronous with video, barcode information captured through a camera, and so on.

The third embodiment of the present invention makes it possible to control a specific sound source independently based upon the signal control information received by the receiving unit. Further, the transmission unit can analyze the signal, and the receiving unit can control the input signal, which is configured of a plurality of the sound sources, for each component element corresponding to each sound source. In addition, the arithmetic quantity relating to the signal analysis by the receiving unit can be curtailed because the transmission unit analyzes the signal.

The fourth embodiment of the present invention is for controlling the input signal, which is configured of the objective sound and the background sound, based upon the signal control information being inputted into the receiving unit in such a manner that the objective sound and the background sound are controlled independently from each other. This embodiment will be explained in details by making a reference to FIG. 21. Upon comparing this embodiment with the second embodiment, while the receiving unit 15 shown in FIG. 1 is configured of the signal control unit 151, the receiving unit 35 shown in FIG. 21 is configured of a signal control unit 350. Further, in this embodiment, the signal control information is inputted into the signal control unit 350. Signal control information is similar to the signal control information employed in the third embodiment, so its explanation is omitted. In addition, a configuration of the signal control unit 350 will be explained in details by making a reference to FIG. 22. The signal control unit 350 is configured of a conversion unit 171, a signal processing unit 360, and an inverse conversion unit 173. Upon making a comparison with the second embodiment, while signal control unit 151 shown in FIG. 5 is configured of the signal processing unit 172, the signal control unit 350 is configured of the signal processing unit 360 in this embodiment.

Continuously, a first example will be explained. In the first example, the suppression coefficient information is employed as analysis information.

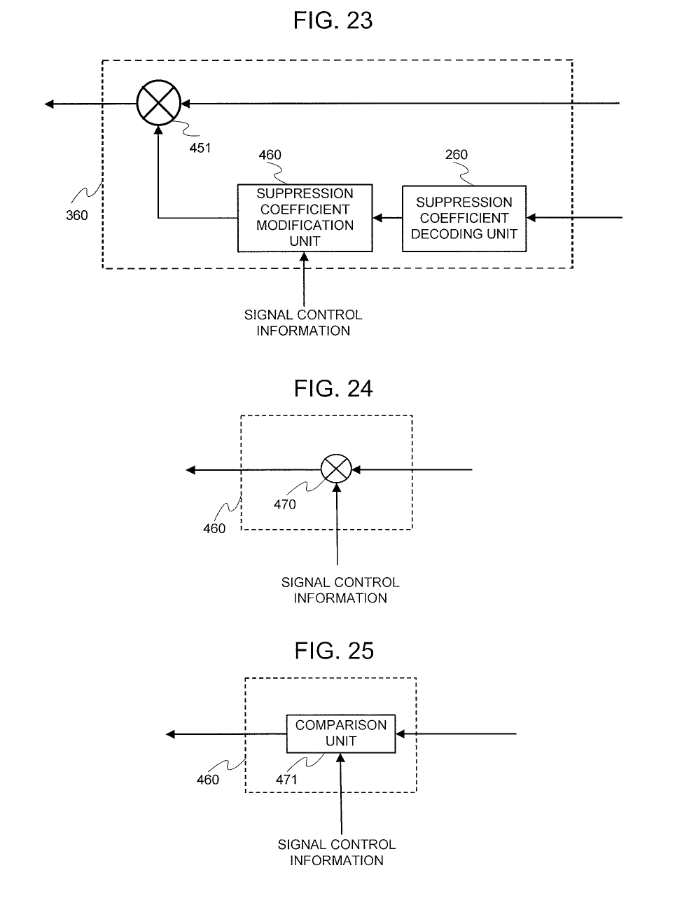

A configuration example of the signal processing unit 360 will be explained in details by making a reference to FIG. 23. The signal processing unit 360 receives the second converted signal, and the suppression coefficient information and the signal control information each of which analysis information, and outputs the modified decoded signal. The signal processing unit 360 is configured of a suppression coefficient decoding unit 260, a suppression coefficient modification unit 460, and a multiplier 451.

The suppression coefficient decoding unit 260 decodes the suppression coefficient and the coefficient correction lower-limit value from the received suppression coefficient information, and calculates the corrected suppression coefficient from the suppression coefficient and the coefficient correction lower-limit value. When the suppression coefficient and the coefficient correction lower-limit value have not been encoded, the suppression coefficient decoding unit 260 calculates the corrected suppression coefficient from the suppression coefficient and the coefficient correction lower-limit value without performing the decoding process. The method of calculating the corrected suppression coefficient was already explained in the first example of the second embodiment by employing FIG. 8. The suppression coefficient decoding unit 260 outputs the corrected suppression coefficient to the suppression coefficient modification unit 460. The suppression coefficient modification unit 460 calculates the modified suppression coefficient by modifying the inputted corrected suppression coefficient by employing the signal control information inputted from the outside, and outputs it. The multiplier 451 multiplies the second converted signal by the modified suppression coefficient, and generates the modified decoded signal. The multiplier 451 outputs the modified decoded signal.

A first configuration example of the suppression coefficient modification unit 460 will be explained in details by making a reference to FIG. 24. The suppression coefficient modification unit 460 receives the corrected suppression coefficient and the signal control information, and outputs the modified suppression coefficient. The suppression coefficient modification unit 460 of this configuration example is configured of a multiplier 470. The multiplier 470 calculates a product of the corrected suppression coefficient and the signal control information, and outputs the modified suppression coefficient. In this configuration example, a magnification for the corrected suppression coefficient is inputted as the signal control information. Such a configuration makes it possible to control the corrected suppression coefficient with the simple signal control information.

A second configuration example of the suppression coefficient modification unit 460 will be explained in details by making a reference to FIG. 25. The suppression coefficient modification unit 460 receives the corrected suppression coefficient and the signal control information, and outputs the modified suppression coefficient. The suppression coefficient modification unit 460 of this configuration example is configured of a comparison unit 471. The comparison unit 471 compares the corrected suppression coefficient with the signal control information, and outputs the signal responding to its comparison result. For example, the comparison unit 471 outputs the corrected suppression coefficient or the signal control information, which is larger, when making a maximum comparison. Further, the comparison unit 471 may make a minimum comparison, and output the corrected suppression coefficient or the signal control information, which is smaller. In these cases, the maximum value or the minimum value of the corrected suppression coefficient is inputted as the signal control information. Such a configuration makes it possible to pre-specify a range of the output signal, and to avoid a decline in the sound quality due to the output of the unexpected signal.

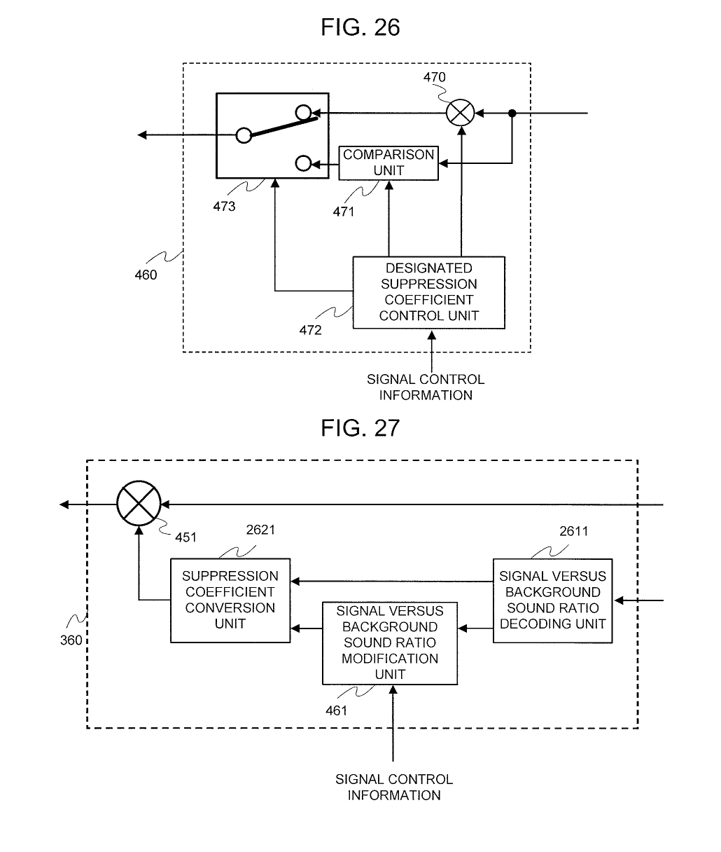

A third configuration example of the suppression coefficient modification unit 460 will be explained in details by making a reference to FIG. 26. The third configuration example of the suppression coefficient modification unit 460 is one obtained by combining the foregoing first configuration example and second configuration example. The suppression coefficient modification unit 460 receives the corrected suppression coefficient and the signal control information, and outputs the modified suppression coefficient. The suppression coefficient modification unit 460 of this configuration example is configured of a multiplier 470, a comparison unit 471, a designated suppression coefficient control unit 472, and a switch 473. The designated suppression coefficient control unit 472 outputs the signal control information to the multiplier 470, the comparison unit 471, or the switch 473. Herein, the signal control information includes at least a magnification of the corrected suppression coefficient being used in the multiplier 470 and the maximum value or the minimum value of the suppression coefficient being used in the comparison unit 471. In addition, the signal control information may include the control information for selection being made by the switch 473. The designated suppression coefficient control unit 472 outputs a magnification of the corrected suppression coefficient to the multiplier 470 when receiving a magnification of the corrected suppression coefficient as signal control information. The multiplier 470 calculates a product of the corrected suppression coefficient and a magnification of the corrected suppression coefficient, and outputs the modified suppression coefficient to the switch 473. The designated suppression coefficient control unit 472 outputs the maximum value or the minimum value of the suppression coefficient to the comparison unit 471 when receiving the maximum value or the minimum value of the suppression coefficient as signal control information. The comparison unit 471 compares the corrected suppression coefficient with the maximum value or the minimum value of the suppression coefficient, and outputs the signal responding to its comparison result as a modified suppression coefficient to the switch 473. The designated suppression coefficient control unit 472 receives the control information for the selection, and output the control information to the switch 473. The switch 473 selects and outputs one of an output of the multiplier 470 and an output of the comparison unit 471 responding to the signal control information inputted from the designated suppression coefficient control unit 472.

In the third configuration example, a function of obtaining the modified suppression coefficient by causing the magnification to act upon the corrected suppression coefficient, and a function of obtaining the modified suppression coefficient by causing the maximum value and the minimum value of suppression coefficient to act upon the corrected suppression coefficient may be appropriately selected with the signal control information in order to obtain the modified suppression coefficient. This configuration makes it possible to realize effects of the first configuration example and the second configuration example in all.

Another configuration of the signal processing unit 360 of the first example will be explained. This configuration differs from the foregoing configuration in a point that, while the suppression coefficient was modified with the signal control information in the latter, the coefficient correction lower-limit value is modified with the signal control information in the former. The signal processing unit 360 receives the suppression coefficient information and the signal control information, and outputs the modified suppression coefficient. The signal processing unit 360 decodes the suppression coefficient and the coefficient correction lower-limit value from the received suppression coefficient information, and modifies the coefficient correction lower-limit value by employing the signal control information inputted from the outside. The signal processing unit 360 calculates the modified suppression coefficient from the suppression coefficient and the modified coefficient correction lower-limit value. The method of calculating the modified suppression coefficient was already explained in the first example of the second embodiment by employing FIG. 8.

Hereinafter, the method of modifying the coefficient correction lower-limit value will be explained. The small suppression coefficient allows the background sound to be strongly suppressed, and simultaneously therewith, allows one part of the objective sound to be also suppressed. That is, as a rule, the residual background sound and magnitude of the distortion of the output signal are in a relation of trade-off, and the small residual background sound and the small distortion of the output signal cannot be satisfied simultaneously. For this, employing the excessively small suppression coefficient leads to an increase in the distortion, which is included in the objective sound that is outputted. Thereupon, there is a necessity for guaranteeing the minimum value of the suppression coefficient with the coefficient correction lower-limit value, and settling the maximum value of the distortion occurring in the output signal into a constant range. Thereupon, it is necessary to accept one of two options, tacit permission of the residual background sound to a certain extent in order to avoid an increase in the distortion of the output signal due to the excessive suppression, and tacit permission of the distortion of the output signal due to the excessive suppression in order to attain the sufficiently small residual background sound. The coefficient correction lower-limit value is employed in order to control this trade-off. Thus, modifying the coefficient correction lower-limit value with the signal control information makes it possible to control the trade-off of the residual background sound and magnitude of the distortion of the output signal. With such a configuration, the suppression coefficient can be easily controlled with the signal control information.

In this configuration example, for example, the magnitude of the residual background sound that is permissible as signal control information may be inputted. In this case, by generating the magnification of the coefficient correction lower-limit value from the magnitude of the permissible residual background sound, and multiplying the coefficient correction lower-limit value by the magnification of the coefficient correction lower-limit value, the coefficient correction lower-limit value may be modified. One example of a relation between the magnification of the coefficient correction lower-limit value and the signal control information in this case is shown in FIG. 67. The relation shown in FIG. 67 has a feature of ever-rising such that the magnification of the coefficient correction lower-limit value becomes larger as the signal control information becomes larger. The coefficient correction lower-limit value is amplified and utilized when the magnification of the coefficient correction lower-limit value is large. For this, it becomes equivalent to employment of the larger coefficient correction lower-limit value

That is, the larger residual noise is permitted, and the distortion of the output signal is made small. To the contrary, when the magnification of the coefficient correction lower-limit value is large, the effect of the coefficient correction lower-limit value is made feeble. This means that stronger suppression is executed. In FIG. 67, the fact that signal control information is 1 signifies the situation in which the residual background sound is permitted, and thus, the distortion of the output signal becomes minimized. On the other hand, the fact that the signal control information is zero signifies the situation in which the distortion of the output signal is permitted, and thus, the residual background sound becomes minimized.

Next, a second example will be explained. The second example is for employing the signal versus background sound ratio information, being a ratio of the objective sound and the background sound as analysis information.

A configuration example of the signal processing unit 360 of the second example will be explained in details by making a reference to FIG. 27. The signal processing unit 360 receives the second converted signal, and the signal versus background sound ratio information and the signal control information each of which is analysis information, and outputs the modified decoded signal. The signal processing unit 360 is configured of a signal versus background sound ratio decoding unit 2611, a signal versus background sound ratio modification unit 461, a suppression coefficient conversion unit 2621 and a multiplier 451.

The signal versus background sound ratio decoding unit 2611 decodes the signal versus background sound ratio and the coefficient correction lower-limit value from the received signal versus background sound ratio information, and outputs the signal versus background sound ratio to the signal versus background sound ratio modification unit 461, and outputs the coefficient correction lower-limit value to the suppression coefficient conversion unit 2621. When the signal versus background sound ratio and the coefficient correction lower-limit value have not been encoded, the signal versus background sound ratio decoding unit 2611 outputs the signal versus background sound ratio and the coefficient correction lower-limit value without performing the decoding process.

The signal versus background sound ratio modification unit 461 modifies the inputted signal versus background sound ratio by employing the signal control information received from the outside, and generates the modified signal versus background sound ratio. A modification method similar to that of the suppression coefficient modification unit 460 in the first example may be applied for modifying the signal versus background sound ratio. That is, the signal versus background sound ratio may be modified by inputting a magnification of the signal versus background sound ratio as signal control information. Further, the signal versus background sound ratio may be modified by inputting the maximum value or the minimum value of the signal versus background sound ratio as signal control information. In addition, the signal versus background sound ratio may be modified by inputting the control information for selecting the signal versus background sound ratio modified with a magnification of the signal versus background sound ratio and the signal versus background sound ratio modified with the maximum value or the minimum value of the signal versus background sound ratio as signal control information. The signal versus background sound ratio modification unit 461 outputs the modified signal versus background sound ratio to the suppression coefficient conversion unit 2621.

The suppression coefficient conversion unit 2621 converts the modified signal versus background sound ratio into the suppression coefficient, and calculates the modified suppression coefficient from the suppression coefficient and the coefficient correction lower-limit value. The suppression coefficient conversion unit 2621 outputs the modified suppression coefficient. As a method of converting the signal versus background sound ratio into the suppression coefficient, a conversion method similar to that of the suppression coefficient conversion unit 2621 shown in FIG. 11 may be employed. The method of calculating the modified suppression coefficient from the suppression coefficient and the coefficient correction lower-limit value was already explained by employing FIG. 8 in the first example of the second embodiment. In the second example, after the signal versus background sound ratio is modified with the signal control information, the modified signal versus background sound ratio is converted into the suppression coefficient. The above signal control information is similar to the signal control information employed in the third embodiment, so its explanation is omitted.

The multiplier 451 multiplies the second converted signal by the modified suppression coefficient, and generates the modified decoded signal, and outputs the modified decoded signal.

A second configuration example of the signal processing unit 360 of the second example will be explained. The above configuration, which differs from the foregoing configuration, is characterized in a point of modifying the coefficient correction lower-limit value with the signal control information. The signal processing unit 360 receives the signal versus background sound ratio information and the signal control information, and outputs the modified suppression coefficient. The signal processing unit 360, similarly to signal versus background sound ratio decoding unit 2611, decodes the signal versus background sound ratio and the coefficient correction lower-limit value from the received signal versus background sound ratio information. Further, the signal processing unit 360 modifies the coefficient correction lower-limit value by employing the signal control information as explained in the first example of this embodiment by employing FIG. 67. In addition, the signal processing unit 360, similarly to the suppression coefficient conversion unit 2621, calculates the modified suppression coefficient from the decoded signal versus background sound ratio and the modified coefficient correction lower-limit value.

In the case of employing the signal versus background sound ratio lower-limit value instead of the coefficient correction lower-limit value, the signal versus background sound ratio decoding unit 2611 decodes the signal versus background sound ratio and the signal versus background sound ratio lower-limit value from the received signal versus background sound ratio information, outputs the signal versus background sound ratio to the signal versus background sound ratio modification unit 461, and outputs the signal versus background sound ratio lower-limit value to the suppression coefficient conversion unit 2621. When the signal versus background sound ratio and the signal versus background sound ratio lower-limit value have not been encoded, the signal versus background sound ratio decoding unit 2611 directly outputs the signal versus background sound ratio and the signal versus background sound ratio lower-limit value without performing the decoding process.

The signal versus background sound ratio modification unit 461 modifies the inputted signal versus background sound ratio by employing the signal control information received from the outside, and generates the modified signal versus background sound ratio. The signal versus background sound ratio modification unit 461 outputs the modified signal versus background sound ratio to the suppression coefficient conversion unit 2621.

The suppression coefficient conversion unit 2621 obtains the corrected signal versus background sound ratio from the modified signal versus background sound ratio and the signal versus background sound ratio lower-limit value. In addition, the suppression coefficient conversion unit 2621 applies [Numerical equation 5] with the corrected signal versus background sound ratio defined as R, and outputs the obtained G to the multiplier 251 as a modified suppression coefficient.

A third configuration example of the signal processing unit 360 of the second example will be explained. Upon making a comparison with the foregoing second configuration example, the third configuration example is characterized in a point of, after converting the signal versus background sound ratio into the suppression coefficient, modifying the suppression coefficient with the signal control information.

A third configuration example of the signal processing unit 360 of the second example will be explained in details by making a reference to FIG. 29. The signal processing unit 360 receives the second converted signal, and the signal versus background sound ratio information and the signal control information each of which is analysis information, and outputs the modified decoded signal. The signal processing unit 360 is configured of a signal versus background sound ratio decoding unit 2611, a suppression coefficient conversion unit 2621, a suppression coefficient modification unit 460, and a multiplier 451.

The signal versus background sound ratio decoding unit 2611 decodes the signal versus background sound ratio and the coefficient correction lower-limit value from the received signal versus background sound ratio information. The signal versus background sound ratio decoding unit 2611 outputs the signal versus background sound ratio and the coefficient correction lower-limit value to the suppression coefficient conversion unit 2621.

The suppression coefficient conversion unit 2621 converts the decoded signal versus background sound ratio and coefficient correction lower-limit value into the corrected suppression coefficient. The suppression coefficient conversion unit 2621 outputs the corrected suppression coefficient to the suppression coefficient modification unit 460.

The suppression coefficient modification unit 460 modifies the corrected suppression coefficient inputted from the background sound information conversion unit 2621 by employing the signal control information received from the outside. The suppression coefficient modification unit 460 outputs the modified suppression coefficient. The above signal control information is similar to the signal control information employed in the third embodiment, so its explanation is omitted. A configuration of the suppression coefficient modification unit 460 is similar to that of the suppression coefficient modification unit 460 of the first example shown in FIG. 23, so its explanation is omitted.

The multiplier 451 multiplies the second converted signal by the modified suppression coefficient, generates the modified decoded signal, and outputs the modified decoded signal.

In the case of employing the signal versus background sound ratio lower-limit value instead of the coefficient correction lower-limit value, the signal versus background sound ratio decoding unit 2611 decodes the signal versus background sound ratio and the signal versus background sound ratio lower-limit value from the received signal versus background sound ratio information, and outputs them to the suppression coefficient conversion unit 2621. When the signal versus background sound ratio and the signal versus background sound ratio lower-limit value have not been encoded, the signal versus background sound ratio decoding unit 2611 directly outputs the signal versus background sound ratio and the signal versus background sound ratio lower-limit value without performing the decoding process.

The suppression coefficient conversion unit 2621 obtains the corrected signal versus background sound ratio from the signal versus background sound ratio and the signal versus background sound ratio lower-limit value. In addition, the suppression coefficient conversion unit 2621 applies [Numerical equation 5] with the corrected signal versus background sound ratio defined as R, and outputs the obtained G to the suppression coefficient modification unit 460 as a suppression coefficient. The suppression coefficient modification unit 460 modifies the inputted suppression coefficient by employing the signal control information received from the outside and generates the modified suppression coefficient. The suppression coefficient modification unit 460 outputs the modified suppression coefficient to the multiplier 451.

Continuously, a third example will be explained. The third example is a configuration example of the case of employing the background sound information as analysis information.

A first configuration example of the signal processing unit 360 of the third example will be explained in details by making a reference to FIG. 31. The signal processing unit 360 receives the second converted signal, the background sound information, and the signal control information, and outputs the modified decoded signal. The signal processing unit 360 is configured of a background sound decoding unit 2631, a background sound modification unit 464, a suppression coefficient generation unit 2641, and the multiplier 451.

The background sound decoding unit 2631 decodes the background sound estimation result and the coefficient correction lower-limit value from the received background sound information, outputs the background sound estimation result to the background sound modification unit 464, and outputs the coefficient correction lower-limit value to the suppression coefficient generation unit 2641. When the background sound estimation result and the coefficient correction lower-limit value have not been encoded, the background sound decoding unit 2631 outputs the background sound estimation result and the coefficient correction lower-limit value without performing the decoding process.

The background sound modification unit 464 calculates the background sound by employing the background sound estimation result, and modifies it with the signal control information inputted from the outside. A modification method similar to that of the suppression coefficient modification unit 460 in the first example may be applied for modifying the background sound. That is, the background sound may be modified by inputting a magnification of the background sound as signal control information. Further, the background sound may be modified by inputting the maximum value or the minimum value of the background sound as signal control information. In addition, the background sound may be modified by inputting the control information for selecting the background sound modified with a magnification of the background sound and the background sound modified with the maximum value or the minimum value of the background sound as signal control information. The background sound modification unit 464 outputs the modified background sound to the suppression coefficient generation unit 2641.

The suppression coefficient generation unit 2641 calculates the modified suppression coefficient for suppressing the background sound by employing the second converted signal, the modified background sound, and the coefficient correction lower-limit value. A calculation method similar to that of the suppression coefficient calculation unit 2011 shown in FIG. 9 may be employed for calculating this suppression coefficient. The suppression coefficient generation unit 2641 outputs the modified suppression coefficient. The above signal control information is similar to the signal control information employed in the third embodiment, so its explanation is omitted.

The multiplier 451 multiplies the second converted signal by the modified suppression coefficient, and generates the modified decoded signal. The multiplier 451 outputs the modified decoded signal.

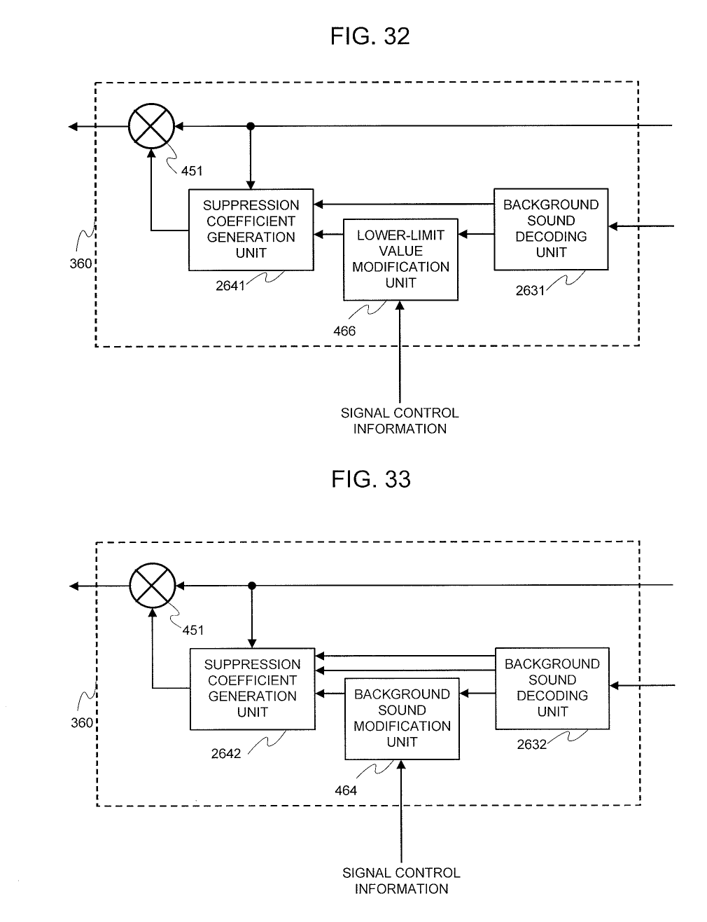

A second configuration example of the signal processing unit 360 of the third example will be explained by making a reference to FIG. 32. The above configuration, which differs from the first configuration, is characterized in point of modifying the coefficient correction lower-limit value with the signal control information. The signal processing unit 360 receives the background sound information and the signal control information, and outputs the modified suppression coefficient. The signal processing unit 360, similarly to background sound decoding unit 2631, decodes the background sound estimation result and the coefficient correction lower-limit value from the received background sound information. Further, the signal processing unit 360 modifies the coefficient correction lower-limit value by employing the signal control information as explained in the first example of this embodiment by employing FIG. 67. In addition, the signal processing unit 360, similarly to the suppression coefficient generation unit 2641, calculates the modified suppression coefficient from the second converted signal, the background sound estimation result, and the modified coefficient correction lower-limit value. The signal processing unit 360 is configured of a background sound decoding unit 2631, a lower-limit modification unit 466, a suppression coefficient generation unit 2641, and a multiplier 451.

The background sound decoding unit 2631 decodes the background sound estimation result and the coefficient correction lower-limit value from the received background sound information, outputs the background sound estimation result to the suppression coefficient generation unit 2641, and outputs the coefficient correction lower-limit value to the lower-limit value modification unit 466. When the background sound estimation result and the coefficient correction lower-limit value have not been encoded, the background sound decoding unit 2631 outputs the background sound estimation result and the coefficient correction lower-limit value to the suppression coefficient generation unit 2641 and the lower-limit value modification unit 466, respectively, without performing the decoding process.

The lower-limit value modification unit 466 modifies the coefficient correction lower-limit value with the signal control information inputted from the outside. A modification method similar to that of the suppression coefficient modification unit 460 in the first example may be employed for modifying the coefficient correction lower-limit value. That is, the coefficient correction lower-limit value may be modified by inputting a magnification of the coefficient correction lower-limit value as signal control information. Further, the coefficient correction lower-limit value may be modified by inputting the maximum value or the minimum value of the coefficient correction lower-limit value as signal control information. In addition, the coefficient correction lower-limit value may be modified by inputting the control information for selecting the coefficient correction lower-limit value modified with a magnification of the coefficient correction lower-limit value, and the coefficient correction lower-limit value modified with the maximum value or the minimum value of the coefficient correction lower-limit value as signal control information. The lower-limit value modification unit 466 outputs the modified coefficient correction lower-limit value to the suppression coefficient generation unit 2641.

The suppression coefficient generation unit 2641 calculates the modified suppression coefficient for suppressing the background sound by employing the second converted signal, the background sound estimation result, and the modified coefficient correction lower-limit value. A calculation method similar to that of the suppression coefficient calculation unit 2011 shown in FIG. 9 may be employed for calculating this suppression coefficient. The suppression coefficient generation unit 2641 outputs the modified suppression coefficient. The above signal control information is similar to the signal control information employed in the third embodiment, so its explanation is omitted.

The multiplier 451 multiplies the second converted signal by the modified suppression coefficient, and generates the modified decoded signal. The multiplier 451 outputs the modified decoded signal.

In the case of employing the background sound upper-limit value instead of the coefficient correction lower-limit value, the background sound decoding unit 2631 decodes the background sound and the background sound upper-limit value from the received background sound information, outputs the background sound to the suppression coefficient generation unit 2641, and outputs the background sound upper-limit value to the lower-limit value modification unit 466. When the background sound and the background sound upper-limit value have not been encoded, the background sound decoding unit 2631 directly outputs the background sound and the background sound upper-limit value to the suppression coefficient generation unit 2641 and the lower-limit value modification unit 466, respectively, without performing the decoding process.

The lower-limit value modification unit 466 modifies the inputted background sound upper-limit value by employing the signal control information received from the outside, and generates the modified background sound upper-limit value. The lower-limit value modification unit 466 outputs the modified background sound upper-limit value to the suppression coefficient generation unit 2641.

The suppression coefficient generation unit 2641 calculates the modified suppression coefficient for suppressing the background sound by employing the second converted signal, the modified background sound upper-limit value, and the background sound. The suppression coefficient generation unit 2641 outputs the modified suppression coefficient to the multiplier 451.

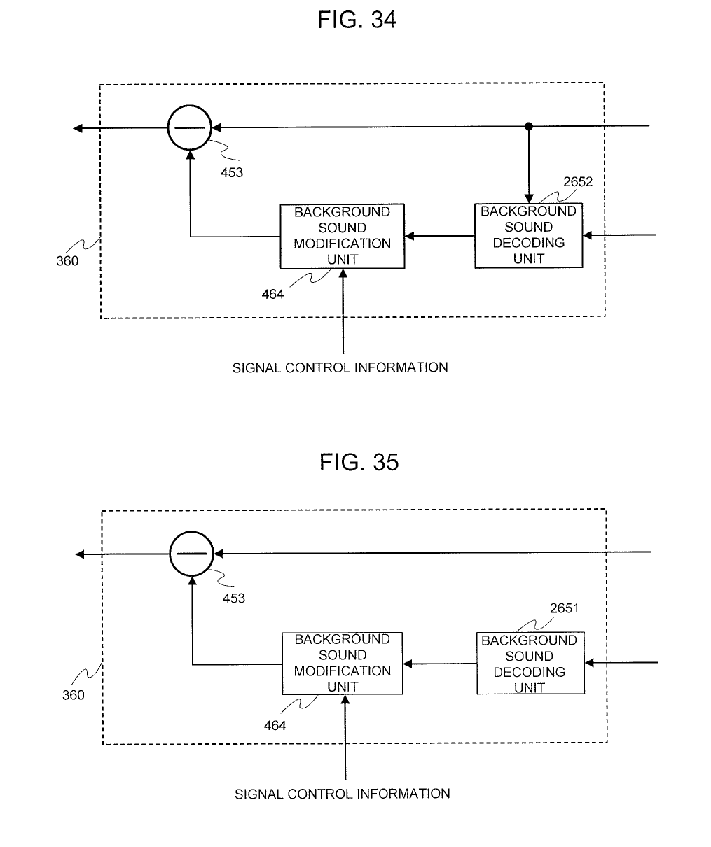

A third configuration example of the signal processing unit 360 will be explained in details by making a reference to FIG. 34. The third configuration differs from the first configuration in calculating the modified decoded signal by subtracting the background sound from the second converted signal. The signal processing unit 360 of this configuration example is configured of a background sound decoding unit 2652, a background sound modification unit 464, and a subtracter 453. The signal processing unit 360 receives the second converted signal, the background sound information, and the signal control information, and outputs the modified decoded signal of which the background sound has been controlled.

The second converted signal is inputted into the subtracter 453 and the background sound decoding unit 2652. Further, the background sound information is inputted as analysis information into the background sound decoding unit 2652. The background sound decoding unit 2652 decodes the background sound estimation result and the coefficient correction lower-limit value from the background sound information, calculates the signal lower-limit value from the second converted signal and the coefficient correction lower-limit value, calculates the background sound from the background sound estimation result and the signal lower-limit value, and outputs the background sound to the background sound modification unit 464. When the background sound information has not been encoded, the background sound decoding unit 2652 calculates the background sound from the background sound estimation result and the signal lower-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs a subtraction result with the signal of which the background sound has been suppressed defined as a modified decoded signal.

In the case of employing the background sound upper-limit value instead of the coefficient correction lower-limit value, the background sound decoding unit 2652 receives the background sound information as analysis information, and decodes the background sound estimation result and the background sound upper-limit value from the background sound information. The background sound decoding unit 2652 calculates a first modified background sound estimation result by employing the background sound estimation result and the background sound upper-limit value. Further, the background sound decoding unit 2652 calculates the background sound from the second converted signal and the first modified background sound estimation result, and outputs the background sound to the background sound modification unit 464. When the background sound information has not been encoded, the background sound decoding unit 2652 calculates the background sound from the background sound estimation result and the background sound upper-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

A fourth configuration example of the signal processing unit 360 will be explained in details by making a reference to FIG. 35. The fourth configuration example differs from the third configuration in a point of calculating the signal lower-limit value in the analysis information calculation unit 121 within the signal analysis unit 101, and defining the background sound information as the background sound estimation result and the signal lower-limit value as explained in the third example of the second embodiment, instead of calculating the signal lower-limit value in the background sound decoding unit 2652.

The signal processing unit 360 receives the second converted signal and the background sound information, and outputs the signal of which the background sound has been suppressed as a modified decoded signal. The signal processing unit 360 of this configuration example is configured of a background sound decoding unit 2651, a background sound modification unit 464, and a subtracter 453. The second converted signal is inputted into the subtracter 453, and the background sound information is inputted as analysis information into the background sound decoding unit 2651. The background sound decoding unit 2651 decodes the background sound estimation result and the signal lower-limit value from the background sound information, calculates the background sound from the background sound estimation result and the signal lower-limit value, and outputs the background sound to the background sound modification unit 464. When the background sound information has not been encoded, the background sound decoding unit 2651 calculates the background sound from the background sound estimation result and the signal lower-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

In the case of employing the background sound upper-limit value instead of the coefficient correction lower-limit value, the background sound decoding unit 2652 receives the background sound information as analysis information, and decodes the background sound estimation result and the background sound upper-limit value from the background sound information. The background sound decoding unit 2652 calculates the first modified background sound estimation result by employing the background sound estimation result and the background sound upper-limit result. Further, the background sound decoding unit 2652 calculates the background sound from the second converted signal and the first modified background sound estimation result, and outputs the background sound to the background sound modification unit 464. When the background sound information has not been encoded, the background sound decoding unit 2652 calculates the background sound from the background sound estimation result and the background sound upper-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been removed as a modified decoded signal.

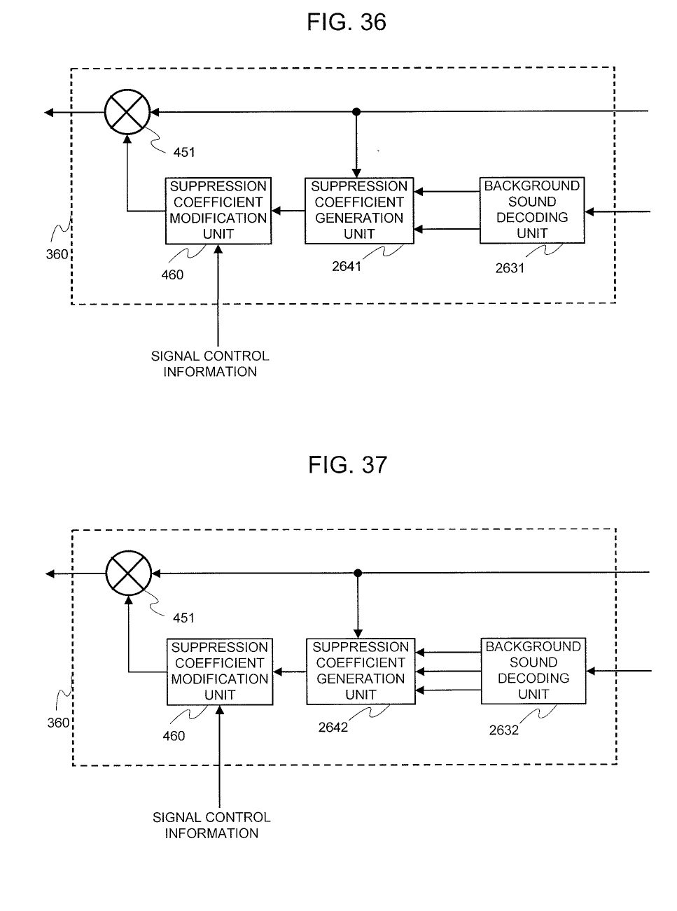

A fifth configuration example of the signal processing unit 360 will be explained in details by making a reference to FIG. 36. This configuration differs from the first configuration in a point of, after generating the suppression coefficient from the decoded background sound, modifying the suppression coefficient with the signal control information. The signal processing unit 360 of this configuration example receives the second converted signal, the background sound information, and the signal control information, and outputs the modified decoded signal of which the background sound has been controlled. The signal processing unit 360 is configured of a background sound decoding unit 2631, a suppression coefficient generation unit 2641, a suppression coefficient modification unit 460, and a multiplier 451.

The background sound decoding unit 2631 decodes the background sound estimation result and the coefficient correction lower-limit value from the background sound information, and outputs the background sound estimation result and the coefficient correction lower-limit value to the suppression coefficient generation unit 2641.

The suppression coefficient generation unit 2641 generates the corrected suppression coefficient from the second converted signal, the background sound estimation result, and the coefficient correction lower-limit value. A calculation method similar to that of the suppression coefficient calculation unit 2011 shown in FIG. 9 may be employed for this calculation. And the suppression coefficient generation unit 2641 outputs the corrected suppression coefficient to the suppression coefficient modification unit 460.

The suppression coefficient modification unit 460 modifies the corrected suppression coefficient by employing the received signal control information, and generates the modified suppression coefficient. A modification method similar to that of the suppression coefficient modification unit 460 shown in FIG. 26 may be applied for modifying the suppression coefficient. That is, the suppression coefficient may be modified by inputting a magnification of the corrected suppression coefficient as signal control information. Further, the suppression coefficient may be modified by inputting the maximum value or the minimum value of the suppression coefficient as signal control information. In addition, the suppression coefficient may be modified by inputting the control information for selecting a magnification of the corrected suppression coefficient, and the maximum value or the minimum value of the suppression coefficient as signal control information. The suppression coefficient modification unit 460 outputs the modified suppression coefficient. The above signal control information is similar to the signal control information employed in the third embodiment, so its explanation is omitted.

The multiplier 451 multiplies the second converted signal by the modified suppression coefficient, generates the modified decoded signal, and outputs the modified decoded signal.

In the case of employing the background sound upper-limit value instead of the coefficient correction lower-limit value, the background sound decoding unit 2631 decodes the background sound and the background sound upper-limit value from the received background sound information, and outputs the background sound and the background sound upper-limit value to the suppression coefficient generation unit 2641. When the background sound and the background sound upper-limit value have not been encoded, the background sound decoding unit 2631 directly outputs the background sound and the background sound upper-limit value without performing the decoding process.

The suppression coefficient generation unit 2641 calculates the suppression coefficient for suppressing the background sound by employing the second converted signal, the background sound, and the background sound upper-limit value. The suppression coefficient generation unit 2641 outputs it to the suppression coefficient modification unit 460.

The suppression coefficient modification unit 460 modifies the inputted suppression coefficient by employing the signal control information received from the outside, and generates the modified suppression coefficient. The suppression coefficient modification unit 460 outputs the modified suppression coefficient to the multiplier 451.

Continuously, a fourth example will be explained. The fourth example is for employing the suppression coefficient information as analysis information. A difference with the first example lies in a point that the objective sound existence probability is newly included as suppression coefficient information in addition to the suppression coefficient and the coefficient correction lower-limit value.

A configuration example of the signal processing unit 360 will be explained in details by making a reference to FIG. 23. The signal processing unit 360 receives the second converted signal, and the suppression coefficient information and the signal control information each of which is analysis information, and outputs the modified decoded signal. The signal processing unit 360 is configured of a suppression coefficient decoding unit 260, a suppression coefficient modification unit 460, and a multiplier 451.

The suppression coefficient decoding unit 260 decodes the suppression coefficient, the coefficient correction lower-limit value, and the objective sound existence probability from the received suppression coefficient information, and calculates the corrected suppression coefficient from the suppression coefficient, the coefficient correction lower-limit value, and the objective sound existence probability. When the suppression coefficient and the coefficient correction lower-limit value have not been encoded, the suppression coefficient decoding unit 260 calculates the corrected suppression coefficient from the suppression coefficient, the coefficient correction lower-limit value, and the objective sound existence probability without performing the decoding process. The method of calculating the corrected suppression coefficient was already explained in the fourth example of the second embodiment by employing FIG. 8. The suppression coefficient decoding unit 260 outputs the corrected suppression coefficient to the suppression coefficient modification unit 460. The suppression coefficient modification unit 460 calculates the modified suppression coefficient by modifying the inputted corrected suppression coefficient by employing the signal control information inputted from the outside, and outputs it. The modification of the corrected suppression coefficient was already explained in the first example.

The multiplier 451 multiplies the second converted signal by the modified suppression coefficient, and generates the modified decoded signal. The multiplier 451 outputs the modified decoded signal.

A second configuration example of the signal processing unit 360 of the fourth example will be explained. This configuration differs from the first configuration in a point that while the suppression coefficient was modified with the signal control information in the latter, the coefficient correction lower-limit value is modified with the signal control information and the objective sound existence probability in the former. The signal processing unit 360 receives the suppression coefficient information and the signal control information, and outputs the modified decoded signal. The signal processing unit 360 decodes the suppression coefficient and the coefficient correction lower-limit value from the received suppression coefficient information, modifies the coefficient correction lower-limit value by employing the signal control information inputted from the outside and the objective sound existence probability, and calculates the modified suppression coefficient from the suppression coefficient and the modified coefficient correction lower-limit value. The method of calculating the modified suppression coefficient was already explained in the fourth example of the second embodiment by employing FIG. 8.

Further, as explained in the first example, modifying the coefficient correction lower-limit value with the signal control information makes it possible to control the trade-off of the residual background sound and magnitude of the distortion of the output signal. In addition, employing the objective sound existence probability enables a control suitable for the signal feature to be taken because the feature of this trade-off differs depending upon a feature of the signal, namely, depending upon whether the main component of the signal is sound or background sound. More specifically, performing the suppression taking precedence of the low distortion in a sound section, and performing the suppression taking precedence of the residual background sound in a non-sound section based upon the objective sound existence probability enables the small residual background sound in a background sound section and the small distortion of the output signal in the sound section to become compatible with each other.

In this example, for example, the magnitude of the residual background sound that is permissible as signal control information may be inputted. In this case, a magnification of the coefficient correction lower-limit value is generated from the permissible magnitude of the residual background sound, and the method of generating a magnification of the coefficient correction lower-limit value is switched responding to the objective sound existence probability. And, the coefficient correction lower-limit value may be modified by multiplying the coefficient correction lower-limit value by the generated magnification of the coefficient correction lower-limit value. One example of a relation between a magnification of the coefficient correction lower-limit value to the signal control information in this case is shown in FIG. 68. Upon comparing FIG. 68 with FIG. 67, FIG. 68 differs in a point that a plurality of the features exist responding to the objective sound existence probability. Fixing the objective sound existence probability makes FIG. 68 identical to with FIG. 67. That is, the feature of FIG. 68 is one that is obtained by changing the feature of FIG. 67 responding to the objective sound existence probability. In FIG. 68 as well, similarly to FIG. 67, the case that the signal control information is 1 signifies the situation in which the residual background sound is permitted, and thus, the distortion of the output signal becomes minimized. On the other hand, the case that the signal control information is zero signifies the situation in which the distortion of the output signal is permitted, and thus, the residual background sound becomes minimized.

Next, a fifth example will be explained. The fifth example is for employing the signal versus background sound ratio information, being a ratio of the configuration of the objective sound and the background sound, as analysis information. A difference with the second example lies in a point that the objective sound existence probability is newly included as signal versus background sound ratio information in addition to the signal versus background sound ratio and the coefficient correction lower-limit value.

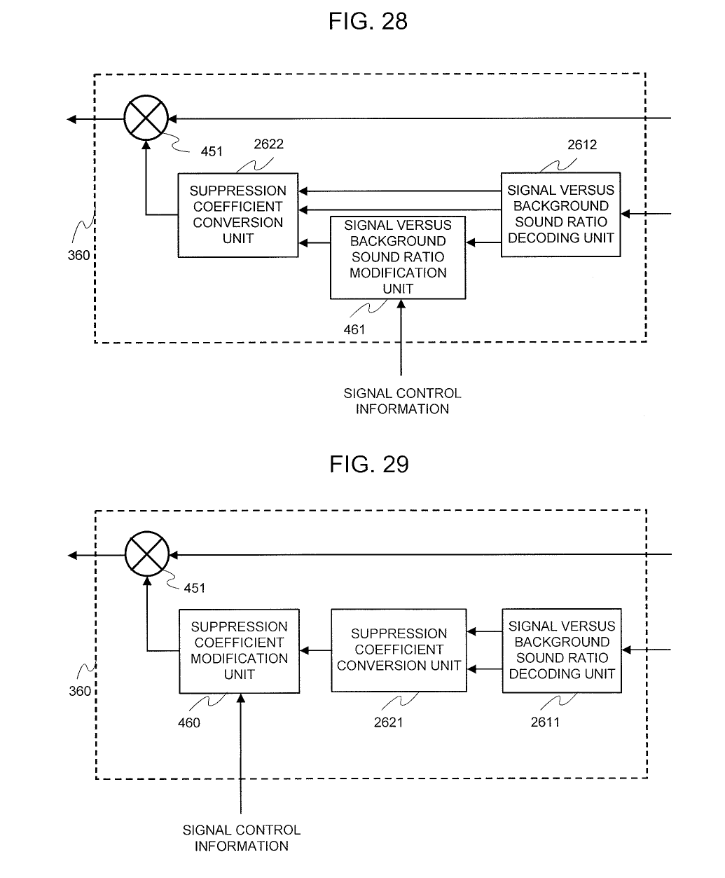

A configuration example of the signal processing unit 360 will be explained in details by making a reference to FIG. 28. The signal processing unit 360 receives the second converted signal, and the signal versus background sound ratio information and the signal control information each of which is analysis information, and outputs the modified decoded signal. The signal processing unit 360 is configured of a signal versus background sound ratio decoding unit 2612, a signal versus background sound ratio modification unit 461, a suppression coefficient conversion unit 2622, and a multiplier 451.

The signal versus background sound ratio decoding unit 2612 decodes the signal versus background sound ratio, the coefficient correction lower-limit value, and the objective sound existence probability from the received signal versus background sound ratio information, and outputs the signal versus background sound ratio to the signal versus background sound ratio modification unit 461, and outputs the coefficient correction lower-limit value and the objective sound existence probability to the suppression coefficient conversion unit 2622. When the signal versus background sound ratio, the coefficient correction lower-limit value, and the objective sound existence probability have not been encoded, the signal versus background sound ratio decoding unit 2612 outputs the signal versus background sound ratio, the coefficient correction lower-limit value, and the objective sound existence probability without performing the decoding process.

The signal versus background sound ratio modification unit 461 modifies the inputted signal versus background sound ratio by employing the signal control information received from the outside, and generates the modified signal versus background sound ratio. A modification method similar to that of the suppression coefficient modification unit 460 in the first example may be applied for modifying the signal versus background sound ratio. That is, the signal versus background sound ratio may be modified by inputting a magnification of the signal versus background sound ratio as signal control information. Further, the signal versus background sound ratio may be modified by inputting the maximum value or the minimum value of the signal versus background sound ratio as signal control information. In addition, the signal versus background sound ratio may be modified by inputting the control information for selecting the signal versus background sound ratio modified with a magnification of the signal versus background sound ratio and the signal versus background sound ratio modified with the maximum value or the minimum value of the signal versus background sound ratio as signal control information. The signal versus background sound ratio modification unit 461 outputs the modified signal versus background sound ratio to the suppression coefficient conversion unit 2622.

The suppression coefficient conversion unit 2622 converts the modified signal versus background sound ratio into the suppression coefficient, and calculates the modified suppression coefficient from the suppression coefficient, the coefficient correction lower-limit value, and the objective sound existence probability, and outputs the modified suppression coefficient. As a method of converting the signal versus background sound ratio into the suppression coefficient, a conversion method similar to that of the suppression coefficient conversion unit 2622 shown in FIG. 12 may be employed. The method of calculating the modified suppression coefficient from the suppression coefficient, the coefficient correction lower-limit value, and the objective sound existence probability was already explained in the fourth example of the second embodiment by employing FIG. 8.

The multiplier 451 multiplies the second converted signal by the modified suppression coefficient, and generates the modified decoded signal, and outputs the modified decoded signal.

A second configuration example of the signal processing unit 360 of the fifth example will be explained. The above configuration, which differs from the first configuration, is characterized in a point of modifying the coefficient correction lower-limit value with the signal control information and the objective sound existence probability. The signal processing unit 360 receives the signal versus background sound ratio information and the signal control information, and outputs the modified suppression coefficient. The signal processing unit 360, similarly to signal versus background sound ratio decoding unit 2612, decodes the signal versus background sound ratio, the coefficient correction lower-limit value, and the objective sound existence probability from the received signal versus background sound ratio information. Further, the signal processing unit 360 modifies the coefficient correction lower-limit value by employing the signal control information and the objective sound existence probability as explained in the fourth example of this embodiment by employing FIG. 68. In addition, the signal processing unit 360 calculates the modified suppression coefficient from the decoded signal versus background sound ratio and the modified coefficient correction lower-limit value.

In the case of employing the signal versus background sound ratio lower-limit value instead of the coefficient correction lower-limit value, the signal versus background sound ratio decoding unit 2612 decodes the signal versus background sound ratio, the signal versus background sound ratio lower-limit value, and the objective sound existence probability from the received signal versus background sound ratio information, outputs the signal versus background sound ratio to the signal versus background sound ratio modification unit 461, and outputs the signal versus background sound ratio lower-limit value, and the objective sound existence probability to the suppression coefficient conversion unit 2621. When the signal versus background sound ratio, the signal versus background sound ratio lower-limit value, and the objective sound existence probability have not been encoded, the signal versus background sound ratio decoding unit 2612 directly outputs the signal versus background sound ratio, the signal versus background sound ratio lower-limit value, and the objective sound existence probability without performing the decoding process.

The signal versus background sound ratio modification unit 461 modifies the inputted signal versus background sound ratio by employing the signal control information received from the outside, and generates the modified signal versus background sound ratio. The signal versus background sound ratio modification unit 461 outputs the modified signal versus background sound ratio to the suppression coefficient conversion unit 2622.

The suppression coefficient conversion unit 2622 obtains the corrected signal versus background sound ratio from the modified signal versus background sound ratio and the signal versus background sound ratio lower-limit value. In addition, the suppression coefficient conversion unit 2622 applies [Numerical equation 5] with the corrected signal versus background sound ratio defined as R, and outputs the obtained G to the multiplier 451 as a modified suppression coefficient.

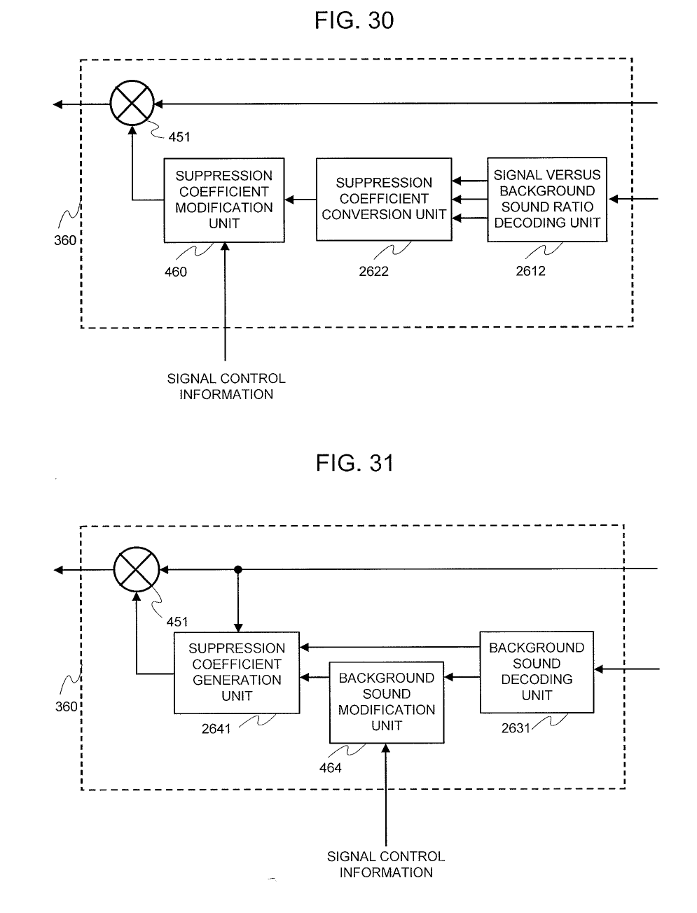

A third configuration example of the signal processing unit 360 of the fifth example will be explained in details by making a reference to FIG. 30. The third configuration differs from the second configuration in a point of, after converting the signal versus background sound ratio into the suppression coefficient, modifying the suppression coefficient with the signal control information. The signal processing unit 360 receives the second converted signal, and the signal versus background sound ratio information and the signal control information each of which is analysis information, and outputs the modified decoded signal. The signal processing unit 360 is configured of a signal versus background sound ratio decoding unit 2612, a suppression coefficient conversion unit 2622, a suppression coefficient modification unit 460, and a multiplier 451.

The signal versus background sound ratio decoding unit 2612 decodes the signal versus background sound ratio, the coefficient correction lower-limit value, and the objective sound existence probability from the received signal versus background sound ratio information. The signal versus background sound ratio decoding unit 2612 outputs the signal versus background sound ratio, the coefficient correction lower-limit value, and the objective sound existence probability to the suppression coefficient conversion unit 2622.

The suppression coefficient conversion unit 2622 converts the decoded signal versus background sound ratio, coefficient correction lower-limit value, and objective sound existence probability into the corrected suppression coefficient. The suppression coefficient conversion unit 2622 outputs the corrected suppression coefficient to the suppression coefficient modification unit 460.

The suppression coefficient modification unit 460 modifies the corrected suppression coefficient inputted from the background sound information conversion unit 2622 by employing the signal control information received from the outside. The suppression coefficient modification unit 460 outputs the modified suppression coefficient. A configuration of the suppression coefficient modification unit 460 is similar to the suppression coefficient modification unit 460 of the fourth example shown in FIG. 23, so its explanation is omitted.

The multiplier 451 multiplies the second converted signal by the modified suppression coefficient, generates the modified decoded signal, and outputs the modified decoded signal.

In the case of employing the signal versus background sound ratio lower-limit value instead of the coefficient correction lower-limit value, the signal versus background sound ratio decoding unit 2612 decodes the signal versus background sound ratio, the signal versus background sound ratio lower-limit value, and the objective sound existence probability from the received signal versus background sound ratio information, and outputs the signal versus background sound ratio, the signal versus background sound ratio lower-limit value, and the objective sound existence probability to the suppression coefficient conversion unit 2622. When the signal versus background sound ratio, the signal versus background sound ratio lower-limit value, and the objective sound existence probability have not been encoded, the signal versus background sound ratio decoding unit 2612 directly outputs the signal versus background sound ratio, the signal versus background sound ratio lower-limit value, and the objective sound existence probability without performing the decoding process.

The suppression coefficient conversion unit 2622 obtains the corrected signal versus background sound ratio from the signal versus background sound ratio, the signal versus background sound ratio lower-limit value, and the objective sound existence probability. In addition, the suppression coefficient conversion unit 2622 applies [Numerical equation 5] with the corrected signal versus background sound ratio defined as R, and outputs the obtained G to the suppression coefficient modification unit 460 as a suppression coefficient. The suppression coefficient modification unit 460 modifies the inputted suppression coefficient by employing the signal control information received from the outside, and generates the modified suppression coefficient. The suppression coefficient modification unit 460 outputs the modified suppression coefficient to the multiplier 451.

Continuously, a sixth example will be explained. The sixth example is a configuration example in the case of employing the background sound information as analysis information. A difference with the third example lies in a point that the objective sound existence probability is newly included as signal versus background sound ratio information in addition to the signal versus background sound ratio and the coefficient correction lower-limit value.

A configuration example of the signal processing unit 360 will be explained in details by making a reference to FIG. 33. The signal processing unit 360 receives the second converted signal, the background sound information, and the signal control information, and outputs the modified decoded signal. The signal processing unit 360 is configured of a background sound decoding unit 2632, a background sound modification unit 464, a suppression coefficient generation unit 2642, and a multiplier 451.

The background sound decoding unit 2632 decodes the background sound estimation result, the coefficient correction lower-limit value, and the objective sound existence probability from the received background sound information, outputs the background sound estimation result to the background sound modification unit 464, and outputs the coefficient correction lower-limit value and the objective sound existence probability to the suppression coefficient generation unit 2642. When the background sound estimation result, the coefficient correction lower-limit value, and the objective sound existence probability have not been encoded, the background sound decoding unit 2632 outputs the background sound estimation result, the coefficient correction lower-limit value, and the objective sound existence probability without performing the decoding process.

The background sound modification unit 464 calculates the background sound by employing the background sound estimation result, and modifies it with the signal control information inputted from the outside. A modification method similar to that of the suppression coefficient modification unit 460 in the sixth example may be applied for modifying the background sound. That is, the background sound may be modified by inputting a magnification of the background sound as signal control information. Further, the background sound may be modified by inputting the maximum value or the minimum value of the background sound as signal control information. In addition, the background sound may be modified by inputting the control information for selecting the background sound modified with a magnification of the background sound and the background sound modified with the maximum value or the minimum value of the background sound as signal control information. The background sound modification unit 464 outputs the modified background sound to the suppression coefficient generation unit 2642.

The suppression coefficient generation unit 2642 calculates the modified suppression coefficient for suppressing the background sound by employing the second converted signal, the modified background sound, the coefficient correction lower-limit value, and the objective sound existence probability. A calculation method similar to the calculation method of the suppression coefficient calculation unit 2012 shown in FIG. 10 may be employed for calculating this suppression coefficient. The suppression coefficient generation unit 2642 outputs the modified suppression coefficient. The above signal control information is similar to the signal control information employed in the third embodiment, so its explanation is omitted. The multiplier 451 multiplies the second converted signal by the suppression coefficient, and outputs the modified decoded signal.

A second configuration of the signal processing unit 360 of the third example will be explained by making a reference to FIG. 32. This configuration, which differs from the first configuration, is characterized in a point of modifying the coefficient correction lower-limit value with the signal control information. The signal processing unit 360 receives the background sound information and the signal control information, and outputs the modified suppression coefficient. The signal processing unit 360, similarly to the background sound decoding unit 2631, decodes the background sound estimation result, the coefficient correction lower-limit value, and the objective sound existence probability from the received background sound information. Further, the signal processing unit 360 modifies the coefficient correction lower-limit value by employing the signal control information and the objective sound existence probability as explained in the fourth example of this embodiment by employing FIG. 68. In addition, the signal processing unit 360, similarly to the suppression coefficient generation unit 2641, calculates the modified suppression coefficient from the second converted signal, the background sound estimation result, and the modified coefficient correction lower-limit value. The signal processing unit 360 is configured of a background sound decoding unit 2631, a lower-limit value modification unit 466, a suppression coefficient generation unit 2641 and a multiplier 451.

The background sound decoding unit 2631 decodes the background sound estimation result, the coefficient correction lower-limit value, and the objective sound existence probability from the received background sound information, outputs the background sound estimation result to the suppression coefficient generation unit 2641, and outputs the coefficient correction lower-limit value, and the objective sound existence probability to the lower-limit value modification unit 466. When the background sound estimation result, the coefficient correction lower-limit value, and the objective sound existence probability have not been encoded, the background sound decoding unit 2631 outputs the background sound estimation result, the coefficient correction lower-limit value, and the objective sound existence probability to the suppression coefficient generation unit 2641 and the lower-limit value modification unit 466 without performing the decoding process.

The lower-limit value modification unit 466 modifies the coefficient correction lower-limit value with the signal control information inputted from the outside and the objective sound existence probability. A modification method similar to that of the suppression coefficient modification unit 460 in the first example may be employed for modifying the coefficient correction lower-limit value. That is, the coefficient correction lower-limit value may be modified by inputting a magnification of the coefficient correction lower-limit value as signal control information. Further, the coefficient correction lower-limit value may be modified by inputting the maximum value or the minimum value of the coefficient correction lower-limit value as signal control information. In addition, the coefficient correction lower-limit value may be modified by inputting the control information for selecting the coefficient correction lower-limit value modified with a magnification of the coefficient correction lower-limit value, and the coefficient correction lower-limit value modified with the maximum value or the minimum value of the coefficient correction lower-limit value as signal control information. The lower-limit value modification unit 466 outputs the modified coefficient correction lower-limit value to the suppression coefficient generation unit 2641.

The suppression coefficient generation unit 2641 calculates the modified suppression coefficient for suppressing the background sound by employing the second converted signal, the background sound estimation result, and the modified coefficient correction lower-limit value. A calculation method similar to that of the suppression coefficient calculation unit 2011 shown in FIG. 9 may be employed for calculating this suppression coefficient. The suppression coefficient generation unit 2641 outputs the modified suppression coefficient. The above signal control information is similar to the signal control information employed in the third embodiment, so its explanation is omitted.

The multiplier 451 multiplies the second converted signal by the modified suppression coefficient, and generates the modified decoded signal. The multiplier 451 outputs the modified decoded signal.

In the case of employing the background sound upper-limit value instead of the coefficient correction lower-limit value, the background sound decoding unit 2631 decodes the background sound, the background sound upper-limit value, and the objective sound existence probability from the received background sound information, outputs the background sound to the suppression coefficient generation unit 2641, and outputs the background sound upper-limit value and the objective sound existence probability to the lower-limit value modification unit 466. When the background sound, the background sound upper-limit value, and the objective sound existence probability have not been encoded, the background sound decoding unit 2631 directly outputs the background sound, the background sound upper-limit value, and the objective sound existence probability to the suppression coefficient generation unit 2641 and the lower-limit value modification unit 466 without performing the decoding process.

The lower-limit value modification unit 466 modifies the inputted background sound upper-limit value by employing the signal control information received from the outside, and the objective sound existence probability, and generates the modified background sound upper-limit value. The lower-limit value modification unit 466 outputs the modified background sound upper-limit value to the suppression coefficient generation unit 2641.

The suppression coefficient generation unit 2641 calculates the modified suppression coefficient for suppressing the background sound by employing the second converted signal and the modified background sound upper-limit value. The suppression coefficient generation unit 2641 outputs the modified suppression coefficient to the multiplier 451.

A third configuration example of the signal processing unit 360 will be explained in details by making a reference to FIG. 34. The signal processing unit 360 of this configuration example is configured of a background sound decoding unit 2652, a background sound modification unit 464 and a subtracter 453. The signal processing unit 360 receives the second converted signal, the background sound information, and the signal control information, and outputs the modified decoded signal.

The second converted signal is inputted into the subtracter 453 and the background sound decoding unit 2652. Further, the background sound information is inputted as analysis information into the background sound decoding unit 2652. The background sound decoding unit 2652 decodes the background sound estimation result, the coefficient correction lower-limit value, and the objective sound existence probability from the background sound information. And, the background sound decoding unit 2652 calculates the signal lower-limit value from the second converted signal, the coefficient correction lower-limit value, and the objective sound existence probability, and calculates the background sound from the background sound estimation result and the signal lower-limit value. Thereafter, the background sound decoding unit 2652 outputs the background sound to the background sound modification unit 464. When the background sound information has not been encoded, the background sound decoding unit 2652 calculates the background sound from the background sound estimation result and the signal lower-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

In the case of employing the background sound upper-limit value instead of the coefficient correction lower-limit value, the background sound decoding unit 2652 receives the background sound information as analysis information, and decodes the background sound estimation result and the background sound upper-limit value from the background sound information. The background sound decoding unit 2652 calculates the first modified background sound estimation result by employing the background sound estimation result and the background sound upper-limit value. Further, the background sound decoding unit 2652 calculates the background sound from the second converted signal and the first modified background sound estimation result, and outputs the background sound to the background sound modification unit 464. When the background sound information has not been encoded, the background sound decoding unit 2652 calculates the background sound from the background sound estimation result and the background sound upper-limit value without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

A fourth configuration of the signal processing unit 360 will be explained in details by making a reference to FIG. 35. The fourth configuration differs from the third configuration in a point of calculating the signal lower-limit value in the analysis information calculation unit 121 within the signal analysis unit 101 and defining the background sound information as the background sound estimation result and the signal lower-limit value as explained in the third example of the second embodiment, instead of calculating the signal lower-limit value in the background sound decoding unit 2652.

The signal processing unit 360 receives the second converted signal and the background sound information, and outputs the signal of which the background sound has been suppressed as a modified decoded signal. The signal processing unit 360 of this configuration example is configured of a background sound decoding unit 2651, a background sound modification unit 464, and a subtracter 453. The second converted signal is inputted into the subtracter 453, and the background sound information is inputted as analysis information into the background sound decoding unit 2651. The background sound decoding unit 2651 decodes the background sound estimation result, the signal lower-limit value, and the objective sound existence probability from the background sound information, calculates the background sound from the background sound estimation result, the signal lower-limit value, and the objective sound existence probability, and outputs the background sound to the background sound modification unit 464. When the background sound information has not been encoded, the background sound decoding unit 2651 calculates the background sound from the background sound estimation result, the signal lower-limit value, and the objective sound existence probability without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

In the case of employing the background sound upper-limit value instead of the coefficient correction lower-limit value, the background sound decoding unit 2652 receives the background sound information as analysis information, and decodes the background sound estimation result, the background sound upper-limit value, and the objective sound existence probability from the background sound information. The background sound decoding unit 2652 calculates the first modified background sound estimation result by employing the background sound estimation result and the background sound upper-limit value. Further, the background sound decoding unit 2652 calculates the background sound from the second converted signal, the first modified background sound estimation result, and the objective sound existence probability, and outputs the background sound to the background sound modification unit 464. When the background sound information has not been encoded, the background sound decoding unit 2652 calculates the background sound from the background sound estimation result, the background sound upper-limit value, and the objective sound existence probability without performing the decoding process. The background sound modification unit 464 modifies the background sound by employing the signal control information, and generates the modified background sound. The background sound modification unit 464 outputs the modified background sound to the subtracter 453. The subtracter 453 subtracts the modified background sound from the second converted signal, and outputs the signal of which the background sound has been suppressed as a modified decoded signal.

A fifth configuration example of the signal processing unit 360 will be explained in details by making a reference to FIG. 37. Upon making a comparison with the fourth configuration, this configuration is characterized in a point of, after generating the suppression coefficient from the decoded background sound, modifying the suppression coefficient with the signal control information. The signal processing unit 360 of this configuration example receives the second converted signal, the background sound information, and the signal control information, and outputs the signal of which the background sound has been controlled. The signal processing unit 360 is configured of a background sound decoding unit 2632, a suppression coefficient generation unit 2642, a suppression coefficient modification unit 460, and a multiplier 451.

The background sound decoding unit 2632 decodes the background sound estimation result, the coefficient correction lower-limit value, and the objective sound existence probability from the background sound information, and outputs the background sound estimation result, the coefficient correction lower-limit value, and the objective sound existence probability to the suppression coefficient generation unit 2642.

The suppression coefficient generation unit 2642 generates the corrected suppression coefficient from the second converted signal, the background sound estimation result, the coefficient correction lower-limit value, and the objective sound existence probability. A calculation method similar to that of the suppression coefficient calculation unit 2012 shown in FIG. 10 may be employed for this calculation. And the suppression coefficient generation unit 2642 outputs the corrected suppression coefficient to the suppression coefficient modification unit 460.

The suppression coefficient modification unit 460 modifies the corrected suppression coefficient by employing the received signal control information, and generates the modified suppression coefficient. A modification method similar to that of the suppression coefficient modification unit 460 shown in FIG. 26 may be applied for modifying the suppression coefficient. That is, the suppression coefficient may be modified by inputting a magnification of the corrected suppression coefficient as signal control information. Further, the suppression coefficient may be modified by inputting the maximum value or the minimum value of the suppression coefficient as signal control information. In addition, the suppression coefficient may be modified by inputting the control information for selecting a magnification of the corrected suppression coefficient, and the maximum value or the minimum value of the suppression coefficient as signal control information. The suppression coefficient modification unit 460 outputs the modified suppression coefficient. The above signal control information is similar to the signal control information employed in the third embodiment, so its explanation is omitted.

The multiplier 451 multiplies the second converted signal by the suppression coefficient, and outputs the modified decoded signal.

In the case of employing the background sound upper-limit value instead of the coefficient correction lower-limit value, the background sound decoding unit 2631 decodes the background sound, the background sound upper-limit value, and the objective sound existence probability from the received background sound information, and outputs the background sound, the background sound upper-limit value, and the objective sound existence probability to the suppression coefficient generation unit 2641. When the background sound, the background sound upper-limit value, and the objective sound existence probability have not been encoded, the background sound decoding unit 2631 directly outputs the background sound, the background sound upper-limit value, and the objective sound existence probability without performing the decoding process.

The suppression coefficient generation unit 2641 calculates the suppression coefficient for suppressing the background sound by employing the second converted signal, the background sound, the background sound upper-limit value, and the objective sound existence probability. The suppression coefficient generation unit 2641 outputs the suppression coefficient to the suppression coefficient modification unit 460.

The suppression coefficient modification unit 460 modifies the inputted suppression coefficient by employing the signal control information received from the outside, and generates the modified suppression coefficient. The suppression coefficient modification unit 460 outputs the modified suppression coefficient to the multiplier 451.

As explained above, the fourth embodiment of the present invention makes it possible to curtail the arithmetic quantity of the receiving unit for controlling only the signal, and to control the input signal, which is configured of the objective sound and the background sound, because the transmission unit (or the recording unit) analyzes the signal. Further, this embodiment makes it possible to independently control only a specific sound source by employing the signal control information received by the receiving unit.

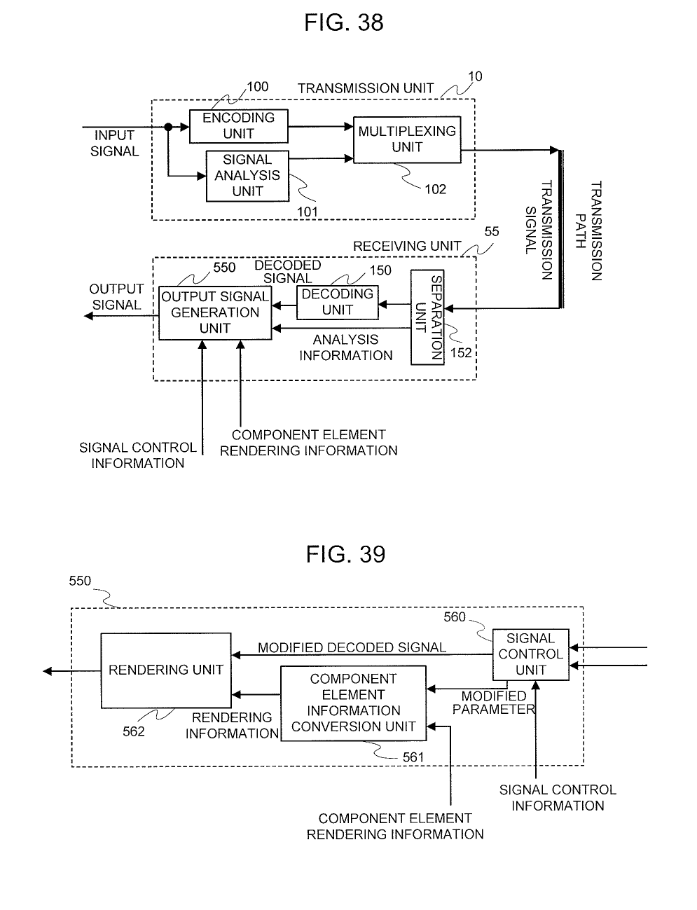

A fifth embodiment of the present invention will be explained by making a reference to FIG. 38. Upon comparing FIG. 38 with FIG. 21 indicative of the third embodiment, the former differs from the latter in a point that the receiving unit 35 is replaced with a receiving unit 55. The receiving unit 55, into which the transmission signal, the signal control information, and the component element rendering information are inputted, outputs the output signal that is configured of a plurality of the channels. Upon making a comparison with the third embodiment, the fifth embodiment differs in a point of having the component element rendering information as well as an input, and a point that the output signal is a signal that is configured of a plurality of the channels.

The so-called component element rendering information is information indicating a relation between the component element being included in the decoded signal and the output signal of the receiving unit 55 for each frequency component. For example, it indicates constant position information of each of the component elements being mixed in the decoded signal. It may include information for manipulating localization feeling, for example, by shading-off the sound image.

Utilizing the component element rendering information makes it possible to control the signal outputted to each channel for each component element. Each component element may be output from a specific one channel (for example, a loudspeaker) in some cases, and may be distributed and outputted to a plurality of the channels in some cases.

Upon making a comparison with the receiving unit 35 of FIG. 21 explained in the third embodiment, the receiving unit 55 differs in a point that the signal control unit 350 is replaced with an output signal generation unit 550. The component element rendering information as well besides the decoded signal, the analysis information, and the signal control information is inputted into the output signal generation unit 550.

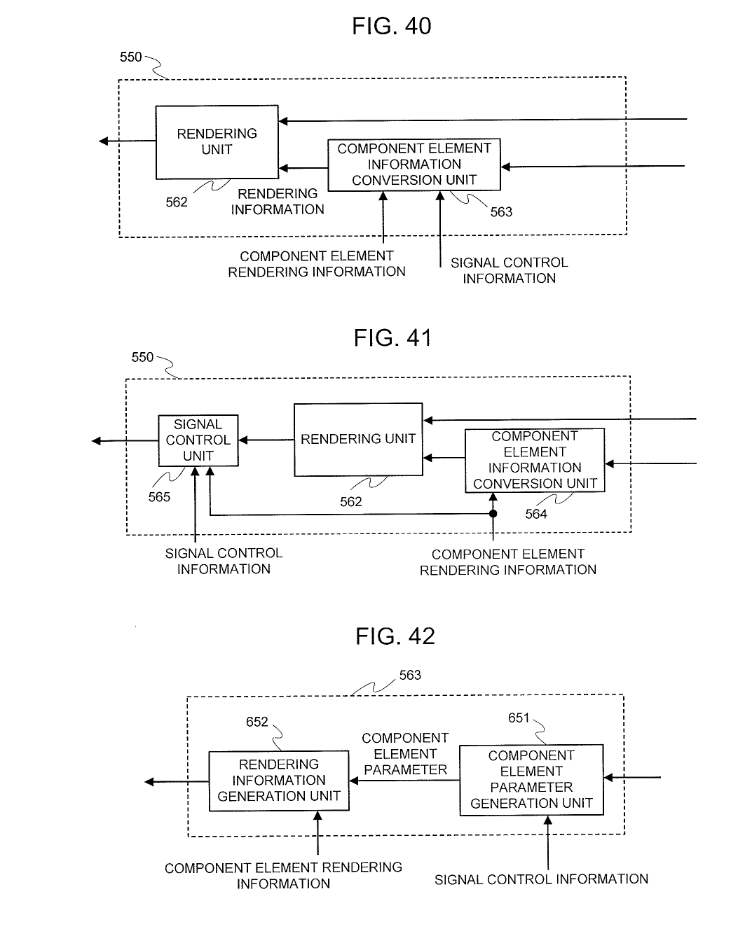

Hereinafter, a configuration example of the output signal generation unit 550, which is characteristic of this embodiment, will be explained. A first example is shown in FIG. 39, a second example in FIG. 40, and a third example in FIG. 41.

The first example is characterized in that the modified decoded signal being inputted into the rendering unit 562 is a signal pre-manipulated for each component element based upon the signal control information. Upon making a reference to FIG. 39, the output signal generation unit 550 in the first example is configured of a signal control unit 560, a component element information conversion unit 561, and a rendering unit 562.

The signal control unit 560 has the decoded signal and the analysis information as an input. At first, the signal control unit 560 decodes the analysis information, and generates the analysis parameter corresponding to each frequency component. Next, the signal control unit 560 decomposes the decoded signal into the respective component elements based upon the analysis parameter. In addition, the signal control unit 560 manipulates each component element by employing the signal control information, generates the modified component element, and outputs the generated signal to the rendering unit 562 as a modified decoded signal. Further, the signal control unit 560 generates a modified parameter indicating a relation between the modified decoded signal and the modified component element for each frequency component, and outputs the modified parameter to the component element information conversion unit 561 as well. Herein, the decoded signal is one that is configured of general plural sound sources.

Additionally, the signal control unit 560 may convert the decoded signal into the modified decoded signal by employing the analysis parameter and the signal control information without generating the modified component element as another operation example. In this case, the signal control unit 560 outputs the modified parameter used at the moment of converting the decoded signal into the modified decoded signal to the component element information conversion unit 561.

Hereinafter, a specific example of an operation of the signal control unit 560 will be explained.

Upon defining the frequency component of the decoded signal in a certain frequency band f as Xₖ(f), k=1, 2, . . . , P (P is the number of the channels of the decoded signal), the frequency component of the component element as Yⱼ(f), j=1, 2, . . . , M (M is the number of the component elements), the frequency component of the component element modified based upon the signal control information as Y′ⱼ(f), and the modified decoded signal as X′(f), the following relation holds by employing a conversion function F₅₀₁ being specified with the analysis parameter, and a conversion function F₅₀₂ being specified with the signal control information.

Yⱼ(f)=F₅₀₁(X₁(f),X₂(f), . . . , X_{P}(f)) [Numerical equation 9]

Y′ⱼ(f)=F₅₀₂(Yⱼ(f)) [Numerical equation 10]

X′(f)=F₅₀₃(Y′ⱼ(f)) [Numerical equation 11]

Where, the conversion function F₅₀₃ is a function for converting the modified component element into the modified decoded signal, and the modified parameter becomes a parameter indicative of the inverse function of the conversion function F₅₀₃.

As mentioned as another operation example, by integrating the conversion functions F₅₀₀, F₅₀₁, F₅₀₂, and F₅₀₃, the following equation may be yielded.

X′(f)=F₅₀₄(X(f)) [Numerical equation 12]

At this time, the conversion function F₅₀₄ is specified with the analysis parameter, the signal control information, and the modified parameter.

As a specific example of the above-mentioned conversion, upon expressing an analysis parameter B(f) of the frequency band f as the following [Numerical equation 13], and a signal control information A(f) as the following [Numerical equation 14], [Numerical equation 9] to [Numerical equation 12] can be expressed by the following [Numerical equation 15].

$$\begin{matrix}B ( f ) = [ \begin{matrix}{C}_{11} ( f ) & {C}_{12} ( f ) & K & {C}_{1 P} ( f ) \\ {C}_{21} ( f ) & {C}_{22} ( f ) & K & {C}_{2 P} ( f ) \\ M & M & O & M \\ {C}_{M 1} ( f ) & {C}_{M 2} ( f ) & K & {C}_{MP} ( f )\end{matrix} ] & [ Numerical equation 13 ] \\ A ( f ) = [ \begin{matrix}{A}_{1} ( f ) & 0 & K & 0 \\ 0 & {A}_{2} ( f ) & K & 0 \\ M & M & O & M \\ 0 & 0 & K & {A}_{M} ( f )\end{matrix} ] & [ Numerical equation 14 ] \\ X ( f ) = [ \begin{matrix}{X}_{1} ( f ) \\ {X}_{2} ( f ) \\ M \\ {X}_{P} ( f )\end{matrix} ] \\ Y ( f ) = B ( f ) \cdot X ( f ) , \\ \begin{matrix}{Y}^{′} ( f ) = A ( f ) \cdot Y ( f ) \\ = A ( f ) \cdot B ( f ) \cdot X ( f ) ,\end{matrix} \\ \begin{matrix}{X}^{′} ( f ) = D ( f ) \cdot {Y}^{′} ( f ) \\ = D ( f ) \cdot A ( f ) \cdot B ( f ) \cdot X ( f )\end{matrix} & [ Numerical equation 15 ]\end{matrix}$$

That is, a matrix for converting the decoded signal into the modified decoded signal can be calculated as D(f)×A(f)×B(f). Herein, D(f) is an arbitrary P-row and M-column matrix, and upon defining the modified parameter as E(f), the following equation is yielded.

E(f)=D⁻¹(f) [Numerical equation 16]

For example, when the inverse matrix of B(f) is employed as D(f), the modified parameter behaves like E(f)=B(f). Additionally, as apparent from [Numerical equation 15], it is appropriate as a manipulation of converting the modified component element into the modified decoded signal to employ the inverse matrix of B(f) as D(f).

The component element information conversion unit 561 converts the component element rendering information supplied via an input terminal into rendering information by employing the modified parameter outputted from the signal control unit 560, and outputs the rendering information to the rendering unit 562.

As a specific example of converting the component element rendering information into the rendering information, upon expressing the component element rendering information U(f) and the rendering information W(f) as the following equations, respectively, W(f)=U(f) X E(F) can be yielded.

$$U ( f ) = [ \begin{matrix}{U}_{11} ( f ) & {U}_{12} ( f ) & K & {U}_{1 M} ( f ) \\ {U}_{21} ( f ) & {U}_{22} ( f ) & K & {U}_{2 M} ( f ) \\ M & M & O & M \\ {U}_{Q 1} ( f ) & {U}_{Q 2} ( f ) & K & {U}_{QM} ( f )\end{matrix} ] , \\ W ( f ) = [ \begin{matrix}{W}_{11} ( f ) & {W}_{12} ( f ) & K & {W}_{1 P} ( f ) \\ {W}_{21} ( f ) & {W}_{22} ( f ) & K & {W}_{2 P} ( f ) \\ M & M & O & M \\ {W}_{Q 1} ( f ) & {W}_{Q 2} ( f ) & K & {W}_{QP} ( f )\end{matrix} ] , \qquad [ Numerical equation 17 ]$$

Where, Q is the number of the channels of the output signal.

Additionally, the rendering information, which is information indicating a relation between the modified decoded signal and the output signal of the output signal generation unit 550 for each frequency component, can be expressed by employing an energy differences, a time difference, a correlation between the signals, etc. As one example of the rendering information, the information disclosed in Non-patent document 10 is known.

<Non-patent document 10> ISO/IEC 23003-1: 2007 Part 1 MPEG Surround

The rendering unit 562 converts the modified decoded signal outputted from the signal control unit 560 and generates the output signal by employing the rendering information outputted from the component element information conversion unit 561, and outputs it as an output signal of the output signal generation unit 550.

As a method of the conversion, the method disclosed in the Non-patent document 10 is known. When a MPEG Surround decoder disclosed in the Non-patent document 10 is employed, a data stream being supplied to the MPEG Surround decoder is outputted as rendering information. Additionally, the parameter being used within the MPEG Surround decoder may be supplied to the rendering unit without being converted into the data stream.

While, in the foregoing, a configuration was explained in which the modified decoded signal decomposed into the frequency components was supplied to the rendering unit 562 as an output of the signal control unit 560, the rendering unit 562 decomposes the time signal into the frequency components, and then performs a process therefor when the modified decoded signal is inverse-converted and supplied to the rendering unit 562 as a time signal in the output of the signal control unit 560. The rendering unit 562 outputs a signal obtained by inverse-converting the signal decomposed into the frequency components as an output signal.

Upon defining the frequency component of the output signal as Vₖ(f), k=1, 2, . . . , Q (Q is the number of the channels of the output signal), and expressing V(f) by the following equation, an operation of the rendering unit becomes V(f)=W(f)×X′(f).

$$V ( f ) = [ \begin{matrix}{V}_{1} ( f ) \\ {V}_{2} ( f ) \\ M \\ {V}_{Q} ( f )\end{matrix} ] \qquad [ Numerical equation 18 ]$$

Next, a second example will be explained. The second example is characterized in incorporating information for taking a control for each component element into the rendering information, and in realizing the manipulation for each component element in the rendering unit 562. Upon making a reference to FIG. 40, the output signal generation unit 550 in the second example is configured of a component element information conversion unit 563 and a rendering unit 562.

The component element information conversion unit 563 has the analysis information, the signal control information, and the component element rendering information as an input. At first, the component element information conversion unit 563 decodes the analysis information, and generates the analysis parameter corresponding to each frequency component. Next, the component element information conversion unit 563 calculates the modified analysis parameter from the analysis parameter and the signal control information, calculates the rendering information indicating a relation between the decoded signal and the output signal for each frequency component from the modified analysis parameter and the component element rendering information, and outputs it to the rendering unit 562.

Additionally, as another operation, the component element information conversion unit 563 may generate the rendering information indicating a relation between the decoded signal and the output signal for each frequency component from the analysis parameter, the signal control information, and the component element rendering information without generating the modified analysis parameter.

As a specific example of the above-mentioned conversion, upon defining a modified analysis parameter B′(f) of a frequency band f as the following equation, the modified analysis parameter B′(f) can be calculated as A(f)×B(f).

$${B}^{′} ( f ) = [ \begin{matrix}{C}_{11}^{′} ( f ) & {C}_{12}^{′} ( f ) & K & {C}_{1 P}^{′} ( f ) \\ {C}_{21}^{′} ( f ) & {C}_{22}^{′} ( f ) & K & {C}_{2 P}^{′} ( f ) \\ M & M & O & M \\ {C}_{M 1}^{′} ( f ) & {C}_{M 2}^{′} ( f ) & K & {C}_{MP}^{′} ( f )\end{matrix} ] \qquad [ Numerical equation 19 ]$$

In addition, the rendering information W(f) expressed by [Numerical equation 17] can be defined as W(f)=U(f) X B′(f) by employing the component element rendering information U(f) and the modified analysis parameter B′(f). As mentioned as another operation example, the rendering information W(f) may be defined as W(f)=U(f) X A(f) X B(f) without the modified analysis parameter B′(f) calculated.

An operation of the rendering unit 562 is identical to the operation explained in the first configuration example of this embodiment. Specifically, the operation behaves like V(f)=W(f) X X(f).

Making such a configuration makes it possible to incorporate the information for controlling each component element, which is included in the decoded signal, into the rendering information.

Next, a third example will be explained. The third example is characterized in manipulating each component element based upon the signal control information by employing the signal in which the decoded signal has been rendered. Upon making a reference to FIG. 41, the output signal generation unit 550 in the third example is configured of a component element information conversion unit 564, a rendering unit 562, and a signal control unit 565.

The component element information conversion unit 564, into which the analysis information and the component element rendering information are inputted, outputs the rendering information. At first, the component element information conversion unit 564 decodes the analysis information, and generates the analysis parameter corresponding to each frequency component. Next, the component element information conversion unit 564 calculates the rendering information indicating a relation between the decoded signal and the output signal for each frequency component from the analysis parameter and the component element rendering information. As a specific example of the above-mentioned conversion, the rendering information W(f) can be defined as W(f)=U(f) X B(f) from the analysis parameter B(f) and the component element rendering information U(f) defined in [Numerical equation 13] and [Numerical equation 17], respectively.

The rendering unit 562 generates a rendering signal from the decoded signal and the rendering information, and outputs it to the signal control unit 565. The rendering unit 562 operates as explained in the first configuration of this embodiment. Upon defining the frequency component of the rendering signal in a certain frequency band f as Iₖ(f), k=1, 2, . . . , Q (Q is the number of the channels of the output signal), the rendering signal behaves like I(f)=[I₁(f)I₂(f) . . . I_{Q}(f)]^{T}=W(f)×X(f).

The signal control unit 565 generates the output signal from the rendering signal, the component element rendering information, and the signal control information. The following relation of the output signal V(f) holds by employing a conversion function F₅₀₅ that is specified with the component element rendering information and the signal control information.

V(f)=F₅₀₅(I(f)) [Numerical equation 20]

As a specific example of the above-mentioned conversion, when the signal control information A(f) and the component element rendering information U(f) defined in [Numerical equation 14] and [Numerical equation 17], respectively, are employed, [Numerical equation 20] is expressed as follows.

V(f)=U(f)·A(f)·U⁻¹(f)·I(f) [Numerical equation 21]

As explained above, the fifth embodiment of the present invention enables the receiving unit to control the input signal independently for each component element corresponding to each sound source of the input signal based upon the analysis information. Further, the localization of each component element can be controlled based upon the component element rendering information. Further, only a specific sound source can be also controlled independently based upon the signal control information.

In addition, the receiving unit can curtail the arithmetic quantity relating to the calculation of the analysis information because the transmission unit calculates the analysis information.

A sixth embodiment of the present invention will be explained. This embodiment is for controlling the objective sound and the background sound by employing the transmission signal, the component element rendering information, and the signal control information with the input signal, in which the objective sound and the background sound coexist, targeted as a sound source. This embodiment, which is represented in FIG. 38 similarly to the fifth embodiment, differs in configurations of a signal analysis unit 101 and an output signal generation unit 550. Thereupon, the signal analysis unit 101 and the output signal generation unit 550 will be explained in details.

A first example of this embodiment relates to the case that the analysis information is suppression coefficient information. In FIG. 38, the signal analysis unit 101 outputs the suppression coefficient information as analysis information. The output signal generation unit 550, responding to this, controls the decoded signal based upon the signal control information and the component element rendering information by employing the suppression coefficient information. The configuration of the signal analysis unit 101 was explained in details in the first example of the second embodiment, so its explanation is omitted. Hereinafter, the output signal generation unit 550 will be explained in details.

While a configuration of the output signal generation unit 550 of FIG. 38 for controlling the objective sound and the background sound by employing the suppression coefficient information is represented in FIG. 40 similarly to the second example of the output signal generation unit 550 in the fifth embodiment, the former differs from the latter in a configuration of a component element information conversion unit 563. Thereupon, hereinafter, the component element information conversion unit 563 will be explained.

A configuration example of the component element information conversion unit 563 is shown in FIG. 42. The component element information conversion unit 563 is configured of a component element parameter generation unit 651 and a rendering information generation unit 652. The component element parameter generation unit 651 decodes the suppression coefficient and the coefficient correction lower-limit value from the suppression coefficient information, generates the corrected suppression coefficient responding to each frequency component, calculates the component element parameter based upon the signal control information, and supplies it to the rendering information generation unit 652. Additionally, the method of calculating the corrected suppression coefficient was already explained in the first example of the second embodiment.

As a specific example of the above-mentioned conversion, upon defining the corrected suppression coefficient corresponding to each frequency component of the frequency band f as gᵢ(f), i=1, 2, . . . , P (P is the number of the channels of the decoded signal), the signal control information for controlling the objective sound as Aₘₐᵢₙ(f), and the signal control information for controlling the background sound as A_{sub}(f), a component element parameter H(f) is expressed with the following equation.

$$\begin{matrix}H ( f ) = [ \begin{matrix}{A}_{main} ( f ) & 0 \\ 0 & {A}_{sub} ( f )\end{matrix} ] \\ [ \begin{matrix}{g}_{1} ( f ) & Λ & {g}_{P} ( f ) \\ 1 - {g}_{1} ( f ) & Λ & 1 - {g}_{P} ( f )\end{matrix} ]\end{matrix} \qquad [ Numerical equation 22 ]$$

The rendering information generation unit 652 outputs the rendering information indicating a relation between the decoded signal and the output signal based upon the component element parameter and the component element rendering information. Now think about the case that M=2 in [Numerical equation 17] as a specific example of the above-mentioned conversion, the rendering information W(f) can be defined as W(f)=U(f)×H(f).

Additionally, as another configuration example of the component element information conversion unit 563, the component element parameter generation unit 651 and the rendering information generation unit 652 in FIG. 42 can be also integrated. In this case, the suppression coefficient and the coefficient correction lower-limit value is decoded from the suppression coefficient information, the corrected suppression coefficient corresponding to each frequency component is calculated, the rendering information is calculated from the corrected suppression coefficient, the signal control information, and the component element rendering information, and the rendering information is outputted.

Now think about the case that M=2 in [Numerical equation 17] as a specific example of the above-mentioned conversion, the rendering information W(f) can be expressed with the following equation.

$$\begin{matrix}W ( f ) = U ( f ) \cdot [ \begin{matrix}{A}_{main} ( f ) & 0 \\ 0 & {A}_{sub} ( f )\end{matrix} ] \\ [ \begin{matrix}{g}_{1} ( f ) & Λ & {g}_{P} ( f ) \\ 1 - {g}_{1} ( f ) & Λ & 1 - {g}_{P} ( f )\end{matrix} ]\end{matrix} \qquad [ Numerical equation 23 ]$$

A second example of this embodiment relates to the case that the analysis information is signal versus background sound ratio information. In FIG. 38, the signal analysis unit 101 outputs the signal versus background sound ratio information as analysis information. The output signal generation unit 550, responding to this, controls the decoded signal based upon the signal control information and the component element rendering information by employing the signal versus background sound ratio information. The second example differs from the first example only in configurations of the signal analysis unit 101 and the output signal generation unit 550. The signal analysis unit 101 for calculating the signal versus background sound ratio information as analysis information was explained in details in the second example of the second embodiment, so its explanation is omitted. Hereinafter, an operation of the output signal generation unit 550 will be explained in details.

A configuration of the output signal generation unit 550 of FIG. 38 for controlling the objective sound and the background sound by employing the signal versus background sound ratio information is represented in FIG. 40 and FIG. 42 similarly to case of the first example. Upon making a comparison with the first example, this example differs in a configuration of the component element parameter generation unit 651 of FIG. 42. Thereupon, hereinafter, the component element parameter generation unit 651 will be explained.

The component element parameter generation unit 651 decodes the signal versus background sound ratio and the coefficient correction lower-limit value from the signal versus background sound ratio information, calculates the signal versus background sound ratio corresponding to each frequency component, calculates the component element parameter for controlling the objective sound and the background sound based upon the signal control information from the signal versus background sound ratio, and supplies it to the rendering information generation unit 652. For example, after the corrected suppression coefficient is calculated from the signal versus background sound ratio and the coefficient correction lower-limit value as explained in the second embodiment, the component element parameter can be calculated based upon the signal control information by employing [Numerical equation 22] as explained in the first example. Further, the method of, after manipulating the signal versus background sound ratio based upon the signal control information, and converting the manipulated signal versus background sound ratio and the coefficient correction lower-limit value into the modified suppression coefficient, calculating the component element parameter as explained in the fourth embodiment may be employed as another method. In this case, upon defining the converted modified suppression coefficient as g′ᵢ(f), a component element parameter H(f) behaves like the following equation.

$$H ( f ) = [ \begin{matrix}{g}_{1}^{′} ( f ) & Λ & {g}_{P}^{′} ( f ) \\ 1 - {g}_{1}^{′} ( f ) & Λ & 1 - {g}_{P}^{′} ( f )\end{matrix} ] \qquad [ Numerical equation 24 ]$$

As another configuration example of the component element information conversion unit 563 of FIG. 40, the component element parameter generation unit 651 and the rendering information generation unit 652 of FIG. 42 can be also integrated. In this case, the signal versus background sound ratio and the coefficient correction lower-limit value are decoded from the signal versus background sound ratio information, the signal versus background sound ratio corresponding to each frequency component is calculated, the rendering information is calculated from the signal versus background sound ratio, the coefficient correction lower-limit value, the signal control information, and the component element rendering information, and the rendering information is outputted to the rendering unit 562. As a specific example, for example, after the corrected suppression coefficient is calculated from the signal versus background sound ratio and the coefficient correction lower-limit value as explained in the second embodiment, the rendering information is calculated from the corrected suppression coefficient, the signal control information, and the component element rendering information by employing [Numerical equation 23], and the rendering information is outputted to the rendering unit 562 as explained in the first example. Further, the method of, after manipulating the signal versus background sound ratio based upon the signal control information, and converting the manipulated signal versus background sound ratio and the coefficient correction lower-limit value into the corrected suppression coefficient, calculating the rendering information from the converted modified suppression coefficient and the component element rendering information as explained in the fourth embodiment may be employed as another method. In this case, the rendering information W(f) behaves like the following equation.

$$W ( f ) = U ( f ) \cdot [ \begin{matrix}{g}_{1}^{′} ( f ) & Λ & {g}_{P}^{′} ( f ) \\ 1 - {g}_{1}^{′} ( f ) & Λ & 1 - {g}_{P}^{′} ( f )\end{matrix} ] \qquad [ Numerical equation 25 ]$$

In the first example or the second example, it is also possible that, at the moment of calculating the rendering information from the suppression coefficient information or the signal versus background sound ratio information, the signal control information, and the component element rendering information, after the component element information conversion unit 563 modifies the coefficient correction lower-limit value, which is included in the suppression coefficient information or the signal versus background sound ratio information, with the signal control information, it calculates the modified suppression coefficient from the modified coefficient correction lower-limit value and the suppression coefficient, and calculates the rendering information with [Numerical equation 25] by employing the modified suppression coefficient and the component element rendering information as described in the fourth embodiment.

A third example of this embodiment relates to the case that the analysis information is background sound information. Upon making a reference to FIG. 38, the signal analysis unit 101 calculates the background sound information as analysis information. The output signal generation unit 550, responding to this, controls the decoded signal based upon the signal control information and the component element rendering information by employing the background sound information. The third example differs from the first example only in configurations of the signal analysis unit 101 and the output signal generation unit 550. The signal analysis unit 101 for calculating the background sound information as analysis information was explained in details in the third example of the second embodiment, so its explanation is omitted. Thereupon, hereinafter, an operation of the output signal generation unit 550 will be explained in details.

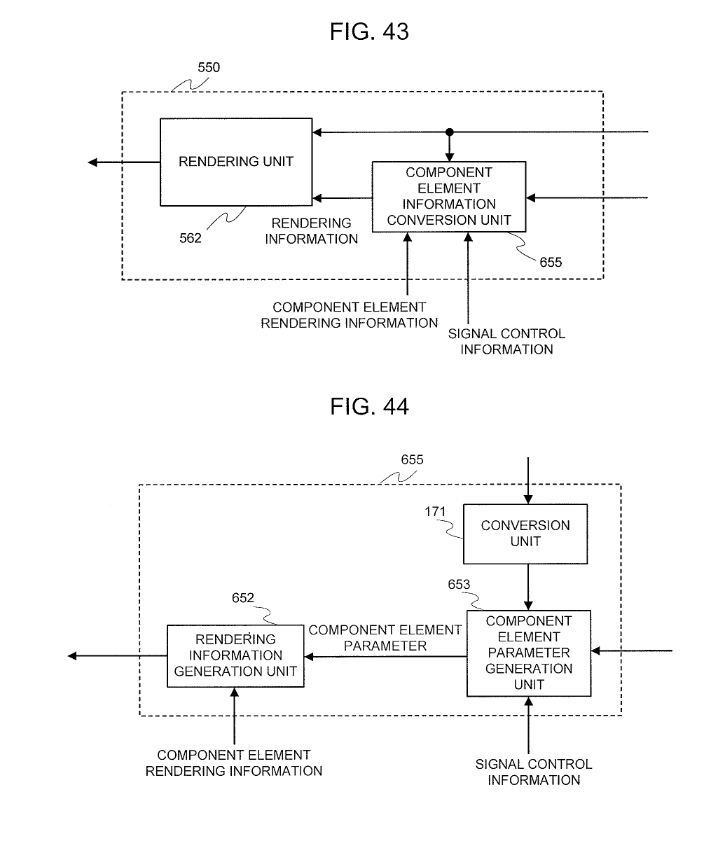

A configuration example of the output signal generation unit 550 of FIG. 38 for controlling the objective sound and the background sound by employing the background sound information is shown in FIG. 43. The third example of FIG. 43 differs from the first example shown in FIG. 40 in a point that the component element information conversion unit 563 is replaced with a component element information conversion unit 655. Hereinafter, the component element information conversion unit 655 will be explained.

The component element information conversion unit 655, into which the decoded signal, the background sound information, the signal control information, and the component element rendering information are inputted, generates the rendering information indicating a relation between the decoded signal and the output signal for each frequency component, and outputs it to the rendering unit 562. A configuration example of the component element information conversion unit 655 is shown in FIG. 44. The component element information conversion unit 655 is configured of a conversion unit 171, a component element parameter generation unit 653, and a rendering information generation unit 652. The conversion unit 171 decomposes the decoded signal into the respective frequency components, generates the second converted signal, and outputs the second converted signal to the component element parameter generation unit 653.

The component element parameter generation unit 653 has the second converted signal, the background sound information, and the signal control information as an input. The component element parameter generation unit 653 calculates the background sound estimation result and the coefficient correction lower-limit value by decoding the background sound information, calculates the component element parameter for controlling the objective sound and the background sound based upon the signal control information from the second converted signal, the background sound estimation result and the coefficient correction lower-limit value, and outputs it to the rendering information generation unit 652.

Hereinafter, a specific example of the method of calculating the component element parameter is shown. In a first method, the corrected suppression coefficient is calculated from the background sound estimation result, the coefficient correction lower-limit value, and the second converted signal as explained in the third example of the second embodiment. In addition, the component element parameter is calculated based upon the signal control information by applying [Numerical equation 22] for the corrected suppression coefficient. In a second method, the modified suppression coefficient is calculated from the background sound estimation result, the coefficient correction lower-limit value, the signal control information, and the second converted signal with the method explained in the fourth example and the fifth example of the fourth embodiment. The component element parameter is calculated by applying [Numerical equation 24] for the modified suppression coefficient calculated with the foregoing methods.

Additionally, the component element parameter generation unit 653 and the rendering information generation unit 652 of FIG. 44 can be also integrated as another configuration example of the component element information conversion unit 655 of FIG. 43. In this case, the rendering information is calculated from the second converted signal corresponding to each frequency component,

the background sound estimation result corresponding to each frequency component in which the background sound information has been decoded, the coefficient correction lower-limit value, the signal control information, and the component element rendering information, and the rendering information is outputted to the rendering unit 562.

Hereinafter, a specific example of the method of calculating the rendering information is shown. In a first method, the corrected suppression coefficient is calculated from the background sound estimation result and the coefficient correction lower-limit value by employing the decoded signal as explained in the third example of the second embodiment. In addition, the rendering information is calculated from the corrected suppression coefficient, the signal control information, and the component element rendering information by employing [Numerical equation 23]. In a second method, the modified suppression coefficient is calculated from the background sound estimation result, the coefficient correction lower-limit value, the signal control information, and the second converted signal with the method explained in the fourth example and the fifth example of the fourth embodiment. The rendering information is calculated from the suppression coefficient and the component element rendering information by employing [Numerical equation 25] for the modified suppression coefficient calculated with the foregoing methods.

In the third example, it is also possible that, at the moment of calculating the rendering information from the background sound information, the signal control information and the component element rendering information, and the second converted signal, after the component element information conversion unit 655 modifies the coefficient correction lower-limit value, which is included in the background sound information, with the signal control information, it calculates the modified suppression coefficient from the modified coefficient correction lower-limit value, the background sound estimation result, and the second converted signal, and calculates the rendering information with [Numerical equation 25] by employing the modified suppression coefficient and the component element rendering information as described in the fourth embodiment.

A fourth example of this embodiment relates to the case that the analysis information is suppression coefficient information. The component element parameter was generated based upon the suppression coefficient and the coefficient correction lower-limit value in the first example. The fourth example differs from the first example in a point of generating the component element parameter based upon the suppression coefficient, the coefficient correction lower-limit value, and the objective sound existence probability. In FIG. 38, the signal analysis unit 101 outputs the suppression coefficient information as analysis information. The output signal generation unit 550, responding to this, controls the decoded signal based upon the signal control information and the component element rendering information by employing the suppression coefficient information. A configuration of the signal analysis unit 101 was explained in details in the fourth example of the second embodiment, so its explanation is omitted. Hereinafter, an operation of the output signal generation unit 550 will be explained in details.

A configuration of the output signal generation unit 550 of FIG. 38 for controlling the objective sound and the background sound by employing the suppression coefficient information, which is represented in FIG. 40 similarly to case of the second configuration example of the output signal generation unit 550 in the fifth embodiment, differs in a configuration of the component element information conversion unit 563. Thereupon, hereinafter, the component element information conversion unit 563 will be explained.

A configuration example of the component element information conversion unit 563 is shown in FIG. 42. The component element information conversion unit 563 is comprised of a component element parameter generation unit 651 and a rendering information generation unit 652. The component element parameter generation unit 651 decodes the suppression coefficient, the coefficient correction lower-limit value, and the objective sound existence probability from the suppression coefficient information, generates the corrected suppression coefficient responding to each frequency component, calculates the component element parameter based upon the signal control information, and outputs it to the rendering information generation unit 652. Additionally, the method of calculating the corrected suppression coefficient is explained in the first example of the second embodiment.

As a specific example of the above-mentioned conversion, upon defining the corrected suppression coefficient corresponding to each frequency component of the frequency band f as gᵢ(f), i=1, 2, . . . , P (P is the number of the channels of the decoded signal), the signal control information for controlling the objective sound as Aₘₐᵢₙ(f), and the signal control information for controlling the background sound as A_{sub}(f), a component element parameter H(f) can be expressed with [Numerical equation 22].

The rendering information generation unit 652 outputs the rendering information indicating a relation between the decoded signal and the output signal based upon the component element parameter and the component element rendering information. Now think about the case that M=2 in [Numerical equation 17] as a specific example of the above-mentioned conversion, the rendering information W(f) can be defined as W(f)=U(f) X H(f).

Additionally, as another configuration example of the component element information conversion unit 563, the component element parameter generation unit 651 and the rendering information generation unit 652 in FIG. 42 can be also integrated. In this case, the suppression coefficient, the coefficient correction lower-limit value, and the objective sound existence probability are decoded from the suppression coefficient information, the corrected suppression coefficient corresponding to each frequency component is calculated, the rendering information is calculated from the corrected suppression coefficient, the signal control information, and the component element rendering information, and the rendering information is outputted to the rendering unit 562.

Now think about the case that M=2 in [Numerical equation 17] as a specific example of the above-mentioned conversion, the rendering information W(f) can be expressed with [Numerical equation 23].

A fifth example of this embodiment relates to the case that the analysis information is signal versus background sound ratio information. The component element parameter was generated based upon the suppression coefficient and the coefficient correction lower-limit value in the second example. The fifth example differs from the second example in a point of generating the component element parameter based upon the suppression coefficient, the coefficient correction lower-limit value, and the objective sound existence probability. In FIG. 38, the signal analysis unit 101 outputs the signal versus background sound ratio information as analysis information. The output signal generation unit 550, responding to this, controls the decoded signal based upon the signal control information and the component element rendering information by employing the signal versus background sound ratio information. The fifth example differs from the fourth example only in configurations of the signal analysis unit 101 and the output signal generation unit 550. The signal analysis unit 101 for calculating the signal versus background sound ratio information as analysis information was explained in details in the fifth example of the second embodiment, so its explanation is omitted. Hereinafter, an operation of the output signal generation unit 550 will be explained in details.

A configuration of the output signal generation unit 550 of FIG. 38 for controlling the objective sound and the background sound by employing the signal versus background sound ratio information is represented in FIG. 40 and FIG. 42 similarly to case of the first example. Upon making a comparison with the first example, this example differs in a configuration of the component element parameter generation unit 651 of FIG. 42. Thereupon, hereinafter, the component element parameter generation unit 651 will be explained.

The component element parameter generation unit 651 decodes the signal versus background sound ratio, the coefficient correction lower-limit value, and the objective sound existence probability from the signal versus background sound ratio information, calculates the signal versus background sound ratio corresponding to each frequency component, calculates the component element parameter for controlling the objective sound and the background sound based upon the signal control information from the signal versus background sound ratio, and outputs it to the rendering information generation unit 652. For example, after the corrected suppression coefficient is calculated from the signal versus background sound ratio, the coefficient correction lower-limit value, and the objective sound existence probability as explained in the second embodiment, the component element parameter can be calculated based upon the signal control information by employing [Numerical equation 22] as explained in the first example. Further, as explained in the fourth embodiment, the method of, after manipulating the signal versus background sound ratio based upon the signal control information and converting the manipulated signal versus background sound ratio, the coefficient correction lower-limit value, and the objective sound existence probability into the modified suppression coefficient, calculating the component element parameter may be employed as another method. In this case, upon defining the converted modified suppression coefficient as g′ᵢ(f), a component element parameter H(f) behaves like [Numerical equation 24].

As another configuration example of the component element information conversion unit 563 of FIG. 40, the component element parameter generation unit 651 and the rendering information generation unit 652 of FIG. 42 can be integrated. In this case, the component element information conversion unit 563 decodes the signal versus background sound ratio, the coefficient correction lower-limit value, and the objective sound existence probability from the signal versus background sound ratio information, and calculates the signal versus background sound ratio corresponding to each frequency component. And, the component element information conversion unit 563 calculates the rendering information from the signal versus background sound ratio, the coefficient correction lower-limit value, the objective sound existence probability, the signal control information, and the component element rendering information, and outputs the rendering information to the rendering unit 562. As a specific example, for example, after calculating the corrected suppression coefficient from the signal versus background sound ratio, the coefficient correction lower-limit value, and the objective sound existence probability as explained in the second embodiment, the rendering information is calculated from the corrected suppression coefficient, the signal control information, and the component element rendering information by employing [Numerical equation 23], and the rendering information is outputted to the rendering unit 562 as explained in the fourth example. Further, as another method, as explained in the fourth embodiment, the method of, after manipulating the signal versus background sound ratio based upon the signal control information and converting the manipulated signal versus background sound ratio, the coefficient correction lower-limit value, and the objective sound existence probability into the modified suppression coefficient, calculating the rendering information from the converted modified suppression coefficient and the component element rendering information may be employed. In this case, the rendering information W(f) behaves like [Numerical equation 25].

In the fourth example or the fifth example, the method described in the fourth embodiment may be employed when the component element information conversion unit 563 calculates the rendering information from the suppression coefficient information or the signal versus background sound ratio information, the signal control information, and the component element rendering information. That is, in the above method, after the component element information conversion unit 563 modifies the coefficient correction lower-limit value, which is included in the suppression coefficient information or the signal versus background sound ratio information, by employing the objective sound existence probability and the signal control information, it calculates the modified suppression coefficient from the modified coefficient correction lower-limit value and the suppression coefficient, and calculates the rendering information with [Numerical equation 25] by employing the modified suppression coefficient and the component element rendering information.

A sixth example of this embodiment relates to the case that the analysis information is background sound information. The component element parameter was generated based upon the suppression coefficient and the coefficient correction lower-limit value in the third example. The sixth example differs from the third example in a point of generating the component element parameter based upon the suppression coefficient, the coefficient correction lower-limit value, and the objective sound existence probability. Upon making a reference to FIG. 38, the signal analysis unit 101 calculates the background sound information as analysis information. The output signal generation unit 550, responding to this, controls the decoded signal based upon the signal control information and the component element rendering information by employing the background sound information. The sixth example differs from the fourth example only in configurations of the signal analysis unit 101 and the output signal generation unit 550. The signal analysis unit 101 for calculating the background sound information as analysis information was explained in details in the sixth example of the second embodiment, so its explanation is omitted. Thereupon, hereinafter, an operation of the output signal generation unit 550 will be explained in details.

A configuration example of the output signal generation unit 550 of FIG. 38 for controlling the objective sound and the background sound by employing the background sound information is shown in FIG. 43. The third example of FIG. 43 differs from the fourth example shown in FIG. 40 in a point that the component element information conversion unit 563 is replaced with a component element information conversion unit 655. Hereinafter, the component element information conversion unit 655 will be explained.

The component element information conversion unit 655 receives the decoded signal, the background sound information, the signal control information, and the component element rendering information, generates the rendering information indicating a relation between the decoded signal and the output signal for each frequency component, and outputs it to the rendering unit 562. A configuration example of the component element information conversion unit 655 is shown in FIG. 44. The component element information conversion unit 655 is configured of a conversion unit 171, a component element parameter generation unit 653, and a rendering information generation unit 652. The conversion unit 171 decomposes the decoded signal into the respective frequency components, generates the second converted signal, and outputs the second converted signal to the component element parameter generation unit 653.

The component element parameter generation unit 653 receives the second converted signal, the background sound information, and the signal control information. The component element parameter generation unit 653 decodes the background sound information, calculates the background sound estimation result, the coefficient correction lower-limit value, and the objective sound existence probability, calculates the component element parameter for controlling the objective sound and the background sound based upon the signal control information from the second converted signal, the background sound estimation result, the coefficient correction lower-limit value, and the objective sound existence probability, and outputs it to the rendering information generation unit 652.

Hereinafter, a specific example of the method of calculating the component element parameter is shown. In a first method, the corrected suppression coefficient is calculated from the background sound estimation result, the coefficient correction lower-limit value, the objective sound existence probability, and the second converted signal as explained in the sixth example of the second embodiment. In addition, the component element parameter is calculated based upon the signal control information by applying [Numerical equation 22] for the corrected suppression coefficient. In a second method, the modified suppression coefficient is calculated from the background sound estimation result, the coefficient correction lower-limit value, the objective sound existence probability, the signal control information, and the second converted signal with the method explained in the ninth example and the tenth example of the fourth embodiment. The component element parameter is calculated by applying [Numerical equation 24] for the modified suppression coefficient calculated with the foregoing methods.

Additionally, the component element parameter generation unit 653 and the rendering information generation unit 652 of FIG. 44 can be also integrated as another configuration example of the component element information conversion unit 655 of FIG. 43. In this case, the rendering information is calculated from the second converted signal corresponding to each frequency component, the background sound estimation result corresponding to each frequency component in which the background sound information has been decoded, the coefficient correction lower-limit value, the objective sound existence probability, the signal control information, and the component element rendering information, and the rendering information is outputted to the rendering unit 562.

Hereinafter, a specific example of the method of calculating the rendering information is shown. In a first method, the corrected suppression coefficient is calculated from the background sound estimation result, the coefficient correction lower-limit value, and the objective sound existence probability by employing the decoded signal as explained in the sixth example of the second embodiment. In addition, the rendering information is calculated from the corrected suppression coefficient, the signal control information, and the component element rendering information by employing [Numerical equation 23]. In a second method, the modified suppression coefficient is calculated from the background sound estimation result, the coefficient correction lower-limit value, the objective sound existence probability, the signal control information, and the second converted signal with the method explained in the ninth example and the tenth example of the fourth embodiment. The rendering information is calculated from the suppression coefficient and the component element rendering information by employing [Numerical equation 25] for the modified suppression coefficient calculated with the foregoing methods.

In the sixth example, it is also possible that, at the moment of calculating the rendering information from the background sound information, the signal control information, the component element rendering information, and the second converted signal, after the component element information conversion unit 655 modifies the coefficient correction lower-limit value, which is included in the background sound information, with the objective sound existence probability and the signal control information similarly to the case of the fourth embodiment, it calculates the modified suppression coefficient from the modified coefficient correction lower-limit value, the background sound estimation result, and the second converted signal, and calculates the rendering information with [Numerical equation 25] by employing the modified suppression coefficient and the component element rendering information.

The sixth embodiment corresponds to each of the second embodiment and the fourth embodiment in its examples, and as explained already, the background sound upper-limit value and the signal versus background sound ratio lower-limit value may be employed instead of the coefficient correction lower-limit value.

As explained above, the sixth embodiment of the present invention enables the receiving unit to control the input signal, which is configured of the objective sound and the background sound, independently based upon the analysis information. Further, the localization of the objective sound and the background sound can be controlled based upon the component element rendering information. Further, only a specific sound source can be also controlled independently based upon the signal control information.

In addition, the receiving unit can curtail the arithmetic quantity relating to the calculation of the analysis information because the transmission unit calculates the analysis information.

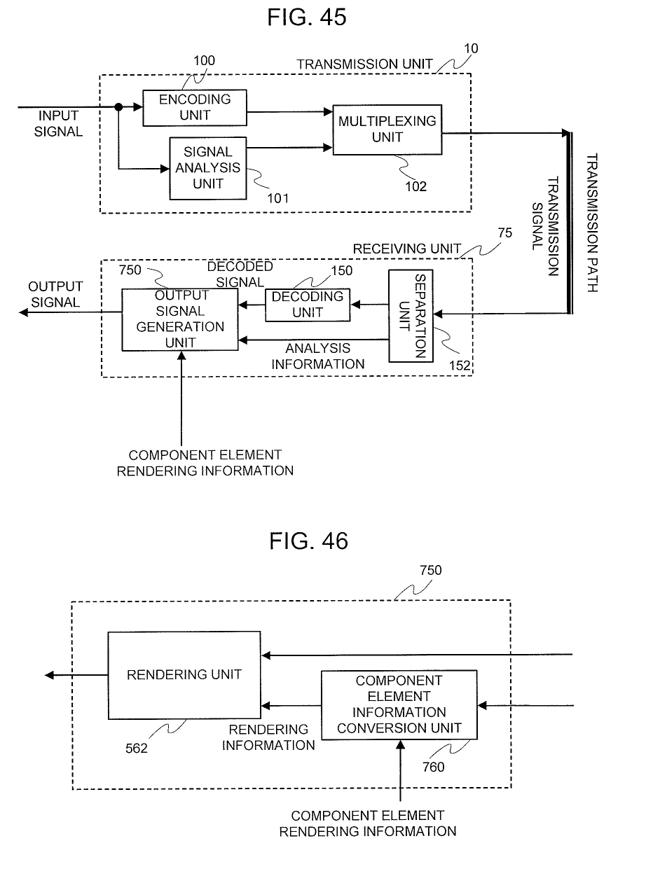

A seventh embodiment of the present invention is for incorporating the signal control information for controlling separation of the signal, namely, for independently controlling the component element into the component element rendering information. The seventh embodiment of the present invention will be explained by making a reference to FIG. 45. Upon comparing FIG. 45 with FIG. 38 indicative of the fifth embodiment, the former differs from the latter in a point that the receiving unit 55 of FIG. 38 is replaced with a receiving unit 75 in FIG. 45. The receiving unit 75, into which the transmission signal and the component element rendering information are inputted, outputs the signal, which is configured of a plurality of the channels, as an output signal. The receiving unit 75 differs from the receiving unit 55 of the fifth embodiment in a point of not having the signal control signal as an input, and a point that the output signal generation unit 550 is replaced with an output signal generation unit 750. Additionally, the component element rendering information of this embodiment may include the information for manipulating each component element that is included in the decoded signal. The output signal generation unit 750 can manipulate the decoded signal with the component element group, which is configured of a plurality of the component element, defined as a unit instead of each component element corresponding to the sound source. Hereinafter, a configuration example of the output signal generation unit 750, which is characteristic of this embodiment, will be explained.

In FIG. 46, a configuration example of the output signal generation unit 750 of FIG. 45 is shown. The output signal generation unit 750 is configured of a component element information conversion unit 760 and a rendering unit 562. The output signal generation unit 750 differs from the output signal generation unit 550 shown in FIG. 40 of the fifth embodiment in a point that the component element information conversion unit 563 is replaced with the component element information conversion unit 760. Hereinafter, a configuration example of the component element information conversion unit 760 will be explained.

The component element information conversion unit 760, into which the analysis information and the component element rendering information are inputted, outputs the rendering information. At first, the component element information conversion unit 760 decodes the analysis information, and calculates the analysis parameter corresponding to each frequency component. In addition, the component element information conversion unit 760 generates the rendering information indicating a relation between the decoded signal and the output signal of the output signal generation unit 750 for each frequency component by employing the analysis parameter and the component element rendering information.

As a specific example of the above-mentioned conversion, the rendering information W(f) can be expresses by W(f)=U(f) X B(f) by employing [Numerical equation 13] and [Numerical equation 17]. Where B(f) is an analysis parameter of the frequency band f, and U(f) is component element rendering information.

This configuration example is characterized in incorporating the information for taking a control for each component element into the rendering information, and realizing the manipulation for each component element in the rendering unit 562. For this, the kind of pieces of the information for taking a control is curtailed and the control becomes easy.

The sixth embodiment corresponds to each of the second embodiment and the fourth embodiment example in its examples, and as explained already, the background sound upper-limit value and the signal versus background sound ratio lower-limit value may be employed instead of the coefficient correction lower-limit value.

As explained above, the seventh embodiment of the present invention enables the receiving unit to control the input signal independently for each component element corresponding to each sound source of the input signal based upon the analysis information. In addition, the localization of each component element can be controlled based upon the component element rendering information.

In addition, the receiving unit can curtail the arithmetic quantity relating to the calculation of the analysis information because the transmission unit calculates the analysis information.

An eighth embodiment of the present invention makes it possible to control the objective sound and the background sound independently, and to control the localization of the objective sound and the background sound by employing the component element rendering information supplied to the receiving unit with the input signal, in which the objective sound and the background sound coexist as a sound source, targeted. This embodiment, which is represented in FIG. 45 similarly to the seventh embodiment, differs in configurations of the signal analysis unit 101 and the output signal generation unit 750. Hereinafter, the signal analysis unit 101 and the output signal generation unit 750 will be explained in details.

A first example of this embodiment relates to the case that the analysis information is suppression coefficient information. The signal analysis unit 101 of the transmission unit 10 outputs the suppression coefficient information as analysis information. The output signal generation unit 750, responding to this, controls the decoded signal by employing the component element rendering information and the suppression coefficient information. The signal analysis unit 101 in the case of employing the suppression coefficient information as analysis information was explained in details in the first example of the second embodiment, so its explanation is omitted. Hereinafter, an operation of the output signal generation unit 750 will be explained in details.

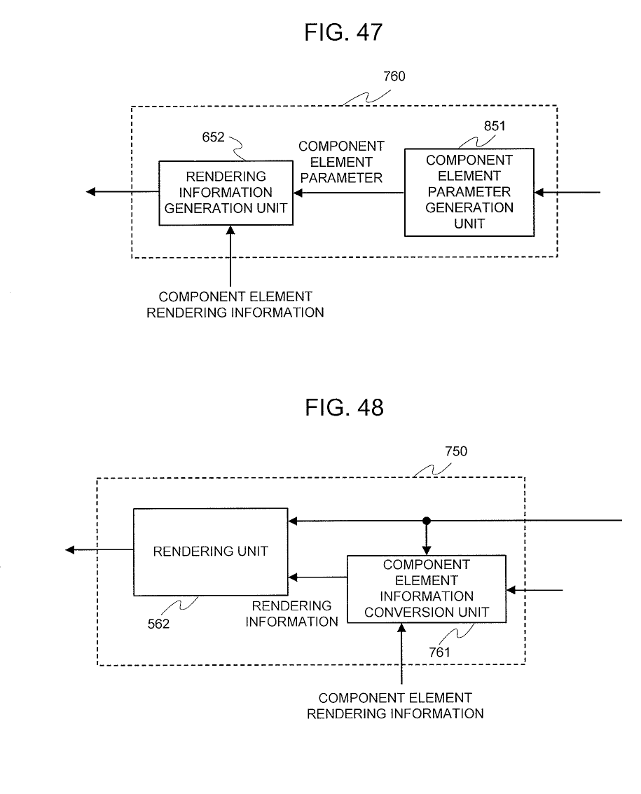

While a configuration example of the output signal generation unit 750 of FIG. 45 for controlling the objective sound and the background sound by employing the suppression coefficient information is represented in FIG. 46 similarly to that of the output signal generation unit 750 of the seventh embodiment, the former differs from the latter in a configuration of a component element information conversion unit 760. A configuration example of the component element information conversion unit 760 is shown in FIG. 47. The component element information conversion unit 760 is configured of a component element parameter generation unit 851 and a rendering information generation unit 652.

The component element parameter generation unit 851 has the suppression coefficient information as an input. The component element parameter generation unit 851 decodes the suppression coefficient information, and calculates the suppression coefficient corresponding to each frequency component and the coefficient correction lower-limit value. In addition, the component element parameter generation unit 851 calculates the component element parameter from the suppression coefficient and the coefficient correction lower-limit value, and outputs it to the rendering information generation unit 652. As a specific example of this conversion, upon defining the corrected suppression coefficient corresponding to each frequency component of the frequency band f as gᵢ(f), a component element parameter H(f) is equivalent to the case that Aₘₐᵢₙ(f)=1 and A_{sub}(f)=1 in [Numerical equation 22], namely, behaves like [Numerical equation 26].

$$H ( f ) = [ \begin{matrix}{g}_{1} ( f ) & Λ & {g}_{P} ( f ) \\ 1 - {g}_{1} ( f ) & Λ & 1 - {g}_{P} ( f )\end{matrix} ]$$

The rendering information generation unit 652 was already explained in the sixth embodiment by employing FIG. 42, so its explanation is omitted.

A second example of this embodiment relates to the case that the analysis information is signal versus background sound ratio information. The signal analysis unit 101 of the transmission unit 10 outputs the signal versus background sound ratio information as analysis information. The output signal generation unit 750, responding to this, controls the decoded signal based upon the component element rendering information by employing the signal versus background sound ratio information. The signal analysis unit 101 in the case of employing the signal versus background sound ratio information as analysis information was explained in details in the second example of the second embodiment, so its explanation is omitted. Hereinafter, an operation of the output signal generation unit 750 will be explained in details.

A configuration example of the output signal generation unit 750 of FIG. 45 for controlling the objective sound and the background sound by employing the signal versus background sound ratio information is represented in FIG. 46 similarly to the case of the first example. This example differs from the first example in a configuration of a component element parameter generation unit 851 of FIG. 47 indicative of a configuration of the component element information conversion unit 760. Hereinafter, the component element parameter generation unit 851 will be explained.

The component element parameter generation unit 851, which has the signal versus background sound ratio information as an input, decodes the signal versus background sound ratio information, and calculates the signal versus background sound ratio corresponding to each frequency component and the coefficient correction lower-limit value. In addition, the component element parameter generation unit 851 calculates the component element parameter from the signal versus background sound ratio and the coefficient correction lower-limit value, and outputs it to the rendering information generation unit 652. As a method of calculating the component element parameter, for example, the signal versus background sound ratio and the coefficient correction lower-limit value are converted into the corrected suppression coefficient as explained in the second example of the second embodiment. In addition, the component element parameter is calculated from the suppression coefficient by employing [Numerical equation 26] as explained in the first example of this embodiment.

A third example of this embodiment relates to the case that the analysis information is background sound information. The component element parameter was generated based upon the suppression coefficient and the coefficient correction lower-limit value in the first example. The fourth example differs from the first example in a point of generating the component element parameter based upon the suppression coefficient, the coefficient correction lower-limit value, and the objective sound existence probability. The signal analysis unit 101 of the transmission unit 10 outputs the background sound information as analysis information. The output signal generation unit 750, responding to this, controls the decoded signal based upon the background sound information and the component element rendering information. The signal analysis unit 101 in the case of employing the signal versus background sound ratio information as analysis information was explained in details in the third example of the second embodiment, so its explanation is omitted. Thereupon, hereinafter, an operation of the output signal generation unit 750 will be explained in details.

A configuration example of the output signal generation unit 750 of FIG. 45 for controlling the objective sound and the background sound by employing the background sound information is shown in FIG. 48. The third example of FIG. 48 differs from the first example shown in FIG. 46 in a point that the component element information conversion unit 760 is replaced with a component element information conversion unit 761. The rendering information generation unit 652 was already explained by employing FIG. 42, so its explanation is omitted.

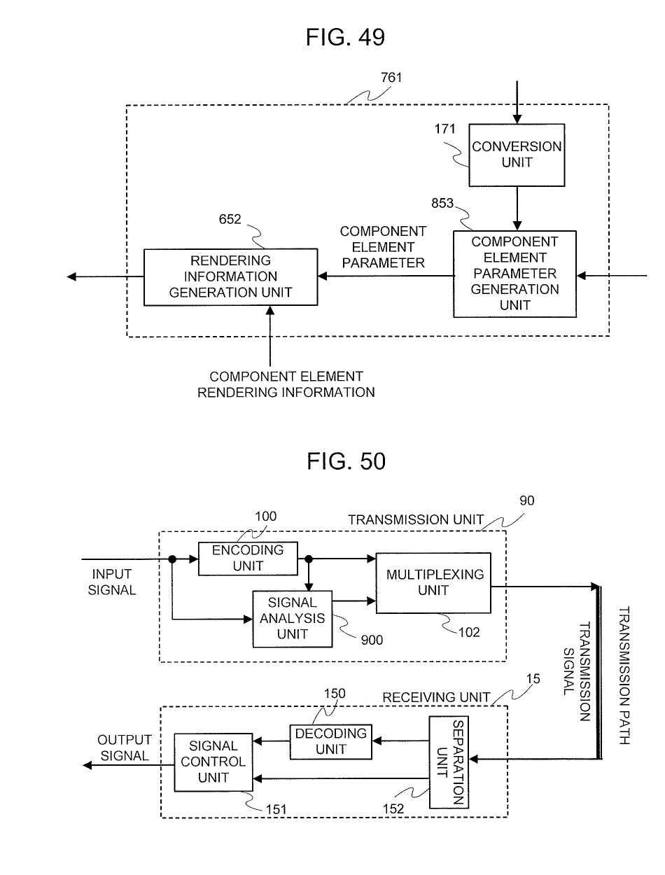

The component element information conversion unit 761 generates the rendering information indicating a relation between the decoded signal and the output signal for each frequency component from the decoded signal, the background sound information, and the component element rendering information, and supplies it to the rendering unit 562. A configuration example of the component element information conversion unit 761 is shown in FIG. 49. The component element information conversion unit 761 is configured of a conversion unit 171, a component element parameter generation unit 853, and a rendering information generation unit 652. The conversion unit 171 decomposes the decoded signal into the respective frequency components, generates the second converted signal, and outputs the second converted signal to the component element parameter generation unit 853.

The component element parameter generation unit 853 has the background sound information and the second converted signal as an input. The component element parameter generation unit 853 decodes the background sound information, and calculates the background sound estimation result and the coefficient correction lower-limit value, calculates the component element parameter based upon the second converted signal, the background sound estimation result and the coefficient correction lower-limit value, and outputs it to the rendering information generation unit 652. As a method of calculating the component element parameter, for example, the background sound estimation result and the coefficient correction lower-limit value are converted into the corrected suppression coefficient as explained in the third example of the second embodiment. In addition, the component element parameter is calculated from the corrected suppression coefficient by applying [Numerical equation 26] as explained in the first example of this embodiment.

A fourth example of this embodiment relates to the case that the analysis information is suppression coefficient information. The signal analysis unit 101 of the transmission unit 10 outputs the suppression coefficient information as analysis information. The output signal generation unit 750, responding to this, controls the decoded signal by employing the component element rendering information and the suppression coefficient information. The signal analysis unit 101 in the case of employing the suppression coefficient information as analysis information was explained in details in the fourth example of the second embodiment, so its explanation is omitted. Hereinafter, an operation of the output signal generation unit 750 will be explained in details.

While a configuration example of the output signal generation unit 750 of FIG. 45 for controlling the objective sound and the background sound by employing the suppression coefficient information is shown in FIG. 46 similarly to the case of the output signal generation unit 750 of the seventh embodiment, the former differs from the latter in a configuration of the component element information conversion unit 760. A configuration example of the component element information conversion unit 760 is shown in FIG. 47. The component element information conversion unit 760 is configured of a component element parameter generation unit 851 and a rendering information generation unit 652.

The component element parameter generation unit 851 has the suppression coefficient information as an input. The component element parameter generation unit 851 decodes the suppression coefficient information, and calculates the suppression coefficient corresponding to each frequency component, the coefficient correction lower-limit value, and the objective sound existence probability. In addition, the component element parameter generation unit 851 calculates the component element parameter from the suppression coefficient, the coefficient correction lower-limit value, and the objective sound existence probability, and outputs it to the rendering information generation unit 652. As a specific example of this conversion, upon defining the corrected suppression coefficient corresponding to each frequency component of the frequency band f as gᵢ(f), a component element parameter H(f) is equivalent to the case that Aₘₐᵢₙ(f)=1 and A_{sub}(f)=1 in [Numerical equation 22]. That is, it behaves like [Numerical equation 26]. The rendering information generation unit 652 was already explained in the sixth embodiment by employing FIG. 42, so its explanation is omitted.

A fifth example of this embodiment relates to the case that the analysis information is signal versus background sound ratio information. The component element parameter was generated based upon the suppression coefficient and the coefficient correction lower-limit value in the second example. The fifth example differs from the second example in a point of generating the component element parameter based upon the suppression coefficient, the coefficient correction lower-limit value, and the objective sound existence probability. The signal analysis unit 101 of the transmission unit 10 outputs the signal versus background sound ratio information as analysis information. The output signal generation unit 750, responding to this, controls the decoded signal based upon the component element rendering information by employing the signal versus background sound ratio information. The signal analysis unit 101 in the case of employing the signal versus background sound ratio information as analysis information was explained in details in the fifth example of the second embodiment, so its explanation is omitted. Hereinafter, an operation of the output signal generation unit 750 will be explained in details.

A configuration example of the output signal generation unit 750 of FIG. 45 for controlling the objective sound and the background sound by employing the signal versus background sound ratio information is represented in FIG. 46 similarly to the case of the fourth example. This example differs from the fourth example in a configuration of the component element parameter generation unit 851 of FIG. 47 indicative of a configuration of the component element information conversion unit 760. Hereinafter, the component element parameter generation unit 851 will be explained.

The component element parameter generation unit 851, which has the signal versus background sound ratio information as an input, decodes the signal versus background sound ratio information, and calculates the signal versus background sound ratio corresponding to each frequency component, the coefficient correction lower-limit value, and the objective sound existence probability. In addition, the component element parameter generation unit 851 calculates the component element parameter from the signal versus background sound ratio, the coefficient correction lower-limit value, and the objective sound existence probability, and outputs it to the rendering information generation unit 652. As a method of calculating the component element parameter, for example, the signal versus background sound ratio, the coefficient correction lower-limit value, and the objective sound existence probability are converted into the corrected suppression coefficient as explained in the fifth example of the second embodiment. In addition, the component element parameter is calculated from the suppression coefficient by employing [Numerical equation 26] as explained in the first example of this embodiment.

A sixth example of this embodiment relates to the case that the analysis information is background sound information. The component element parameter was generated based upon the suppression coefficient and the coefficient correction lower-limit value in the third example. The sixth example differs from the third example in a point of generating the component element parameter based upon the suppression coefficient, the coefficient correction lower-limit value, and the objective sound existence probability. The signal analysis unit 101 of the transmission unit 10 outputs the background sound information as analysis information. The output signal generation unit 750, responding to this, controls the decoded signal based upon the background sound information and the component element rendering information. The signal analysis unit 101 in the case of employing the signal versus background sound ratio information as analysis information was explained in details in the sixth example of the second embodiment, so its explanation is omitted. Hereinafter, an operation of the output signal generation unit 750 will be explained in details.

A configuration example of the output signal generation unit 750 of FIG. 45 for controlling the objective sound and the background sound by employing the background sound information is shown in FIG. 48. This example differs from the fourth example of FIG. 46 in a point that the component element information conversion unit 760 is replaced with a component element information conversion unit 761. The rendering information generation unit 652 was already explained by employing FIG. 42, so its explanation is omitted.

The component element information conversion unit 761 generates the rendering information indicating a relation between the decoded signal and the output signal for each frequency component from the decoded signal, the background sound information, and the component element rendering information, and outputs it to the rendering unit 562. A configuration example of the component element information conversion unit 761 is shown in FIG. 49. The component element information conversion unit 761 is configured of a conversion unit 171, a component element parameter generation unit 853, and a rendering information generation unit 652. The conversion unit 171 decomposes the decoded signal into the frequency components, generates the second converted signal, and outputs the second converted signal to the component element parameter generation unit 853.

The component element parameter generation unit 853 receives the background sound information and the second converted signal. The component element parameter generation unit 853 decodes the background sound information, and calculates the background sound estimation result, the coefficient correction lower-limit value, and the objective sound existence probability. And, the component element parameter generation unit 853 calculates the component element parameter based upon the second converted signal, the background sound estimation result, the coefficient correction lower-limit value, and the objective sound existence probability, and outputs it to the rendering information generation unit 652. As a method of calculating the component element parameter, for example, the background sound estimation result, the coefficient correction lower-limit value, and the objective sound existence probability are converted into the corrected suppression coefficient as explained in the sixth example of the second embodiment. In addition, the component element parameter is calculated from the corrected suppression coefficient by employing [Numerical equation 26] as explained in the first example of this embodiment.

As explained above, the eighth embodiment of the present invention enables the receiving unit to independently control the input signal that is configured of the objective sound and the background sound based upon the analysis information. In addition, the localization of the objective sound and the background sound can be controlled based upon the component element rendering information.

In addition, the receiving unit can curtail the arithmetic quantity relating to the calculation of the analysis information because the transmission unit calculates the analysis information such as the suppression coefficient and the signal versus background sound ratio.

The ninth embodiment of the present invention is characterized in making an analysis taking into consideration an influence of quantizing distortion that has occurred in the encoding unit. The ninth embodiment of the present invention will be explained in details by making a reference to FIG. 50. Upon making a comparison with the first embodiment of the present invention shown in FIG. 1, the transmission unit 10 of the first embodiment is replaced with a transmission unit 90. In addition, while the transmission unit 10 is configured of the signal analysis unit 101, the transmission unit 90 is configured of a signal analysis unit 900. Further, the input signal and the encoded signal coming from an encoding unit 100 are inputted into the signal analysis unit 900.

Further, in the second embodiment and the eighth embodiment, the signal analysis unit 101 being included in the transmission unit 10 may be replaced with the signal analysis unit 900 of this embodiment. In this case, it is enough for the input signal and the encoded signal coming from an encoding unit 100 to be inputted into the signal analysis unit 900.

With the ninth embodiment, the signal analysis unit 900 makes an analysis taking into consideration an influence of quantizing distortion that has occurred in the encoding unit, thereby enabling the quantizing distortion, which occurs at the moment that the receiving unit 15 performs the decoding, to be reduced.

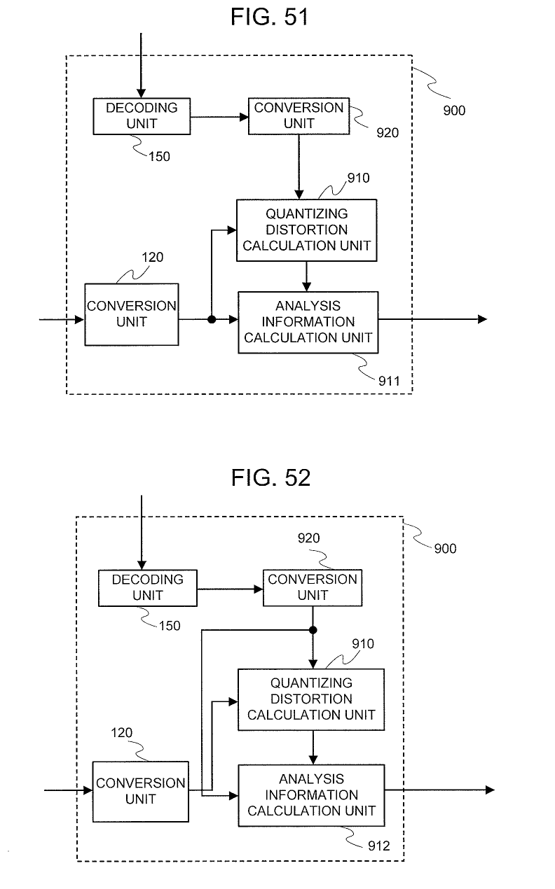

A first configuration example of the signal analysis unit 900 will be explained in details by making a reference to FIG. 51. The signal analysis unit 900 receives the input signal and the encoded signal coming from an encoding unit 100, and outputs the analysis information. The signal analysis unit 900 generates the analysis information from the input signal and the encoded signal coming from an encoding unit 100. The signal analysis unit 900 can generate the analysis information by taking the quantizing distortion quantity into consideration because the encoded signal is a signal to which the quantizing distortion has been added.

The signal analysis unit 900 receives the input signal and the encoded signal coming from the encoding unit 100, and outputs the analysis information. The signal analysis unit 900 is configured of a conversion unit 120, a decoding unit 150, a quantizing distortion calculation unit 910, an analysis information calculation unit 911, and a conversion unit 920.

The input signal is inputted into the conversion unit 120. Further, the encoded signal coming from the encoding unit 100 is inputted into the decoding unit 150.

The decoding unit 150 decodes the encoded signal inputted from the encoding unit 100. The decoding unit 150 outputs the decoded signal to the conversion unit 920. The conversion unit 920 decomposes the decoded signal into the frequency components. The conversion unit 920 outputs the decoded signal decomposed into the frequency components to the quantizing distortion calculation unit 910.

The conversion unit 120 decomposes the input signal into the frequency components. The conversion unit 120 outputs the input signal decomposed into the frequency components to the quantizing distortion calculation unit 910 and the analysis information calculation unit 911. The quantizing distortion calculation unit 910 compares the decoded signal decomposed into the frequency components with the input signal decomposed into the frequency components, and calculates the quantizing distortion quantity for each frequency component. For this, normally, each of the conversion unit 920 and the conversion unit 120 executes the identical conversion. Unless each of them executes the identical conversion, a process of taking a matching of the frequency band, the converted component, etc. becomes necessary so that at least the quantizing distortion calculation unit 910 can calculate the quantizing distortion that occurs in the identical signal. With the calculation of the quantizing distortion, for example, a difference between magnitude of each frequency component of the decoded signal decomposed into the frequency components and magnitude of each frequency component of the input signal decomposed into the frequency components could be the quantizing distortion in the above frequency. The quantizing distortion calculation unit 910 outputs the quantizing distortion quantity of each frequency to the analysis information calculation unit 911.

The analysis information calculation unit 911 receives the input signal decomposed into the frequency components from the conversion unit 120, and receives the quantizing distortion quantity of each frequency from the quantizing distortion calculation unit 910. With regard to the input signal decomposed into the frequency components, the analysis information calculation unit 911 decomposes the input signal corresponding to each frequency component for each component element corresponding to the sound source. And, the analysis information calculation unit 911 generates the analysis information indicative of a relation between a plurality of the component elements. The analysis information calculation unit 911 outputs the analysis information. Further, With regard to the input signal decomposed into the frequency components, the analysis information calculation unit 911 may decompose the input signal for each component element group that is configured of a plurality of the component elements.

The analysis information calculation unit 911, taking the quantizing distortion quantity into consideration, calculates the analysis information so that the quantizing distortion quantity is reduced at the moment that the receiving unit performs the decoding. For example, the analysis information calculation unit 911 may calculate the analysis information from magnitude of each frequency component of the input signal decomposed into the frequency components and magnitude of the quantizing distortion in the above frequency so that the quantizing distortion is auditorily masked. Herein, the analysis information calculation unit 911 may utilize the fact that the small component becomes hard to hear in a frequency neighboring the frequency of which the frequency component is large due to the auditory masking. The magnitude of the component, which becomes hard to hear in the neighboring frequency due to the magnitude of each frequency component, is defined as a masking characteristic. The analysis information calculation unit 911 may calculate the masking characteristic in terms of all frequencies in some cases, and may calculate it only in terms of a specific frequency band in some cases. The analysis information calculation unit 911 corrects the analysis information by taking an influence of the quantizing distortion into consideration in each frequency. The quantizing distortion is hard to hear when the magnitude of the quantizing distortion is smaller than the masking characteristic. In this case, the analysis information calculation unit 911 does not correct the analysis information because an influence of the quantizing distortion is small. The quantizing distortion is not masked when the magnitude of the quantizing distortion is larger than the masking characteristic. In this case, the analysis information calculation unit 911 corrects the analysis information so that the quantizing distortion is reduced. For example, when the suppression coefficient is employed as analysis information, the suppression coefficient, which is relatively small, should be employed so as to suppress the quantizing distortion as well simultaneously with the background sound.

As mentioned above, the analysis information calculation unit 911 corrects the analysis information, thereby allowing quantizing distortion to be auditorily masked, and the distortion and the noise to be reduced at the moment that the receiving unit performs the decoding.

So far, the correction of the analysis information such that the quantizing distortion was reduced by taking the auditory masking into consideration was explained. However, a configuration for correcting the analysis information so that the quantizing distortion is reduced in all frequencies without the auditory masking taken into consideration may be employed.

A second configuration example of the signal analysis unit 900 will be explained in details by making a reference to FIG. 52.

The signal analysis unit 900 receives the input signal and the encoded signal coming from the encoding unit 100, and outputs the analysis information. The signal analysis unit 900 is configured of a conversion unit 120, a decoding unit 150, a quantizing distortion calculation unit 910, an analysis information calculation unit 912, and a conversion unit 920.

The input signal is inputted into the conversion unit 120. Further, the encoded signal coming from the encoding unit 100 is inputted into the decoding unit 150.

The decoding unit 150 decodes the encoded signal inputted from the encoding unit 100. The decoding unit 150 outputs the decoded signal to the conversion unit 920. The conversion unit 920 decomposes the decoded signal into the frequency components. The conversion unit 920 outputs the decoded signal decomposed into the frequency components to the quantizing distortion calculation unit 910 and the analysis information calculation unit 912.

The conversion unit 120 decomposes the input signal into the frequency components. The conversion unit 120 outputs the input signal decomposed into the frequency components to the quantizing distortion calculation unit 910. The quantizing distortion calculation unit 910 compares the decoded signal decomposed into the frequency components with the input signal decomposed into the frequency components, and calculates the quantizing distortion quantity for each frequency component. For this, normally, each of the conversion unit 920 and the conversion unit 120 executes the identical conversion. Unless each of them executes the identical conversion, a process of taking a matching of the frequency band, the converted component, etc. becomes necessary so that at least the quantizing distortion calculation unit 910 can calculate the quantizing distortion that occurs in the identical signal. With the calculation of the quantizing distortion, for example, a difference between the magnitude of each frequency component of the decoded signal decomposed into the frequency components and the magnitude of each frequency component of the input signal decomposed into the frequency components could be the quantizing distortion in the above frequency. The quantizing distortion calculation unit 910 outputs the quantizing distortion quantity of each frequency to the analysis information calculation unit 912.

The analysis information calculation unit 912 receives the decoded signal decomposed into the frequency components from the conversion unit 920, and receives the quantizing distortion quantity of each frequency from the quantizing distortion calculation unit 910. With regard to the decoded signal decomposed into the frequency components, the analysis information calculation unit 912 decomposes the input signal corresponding to each frequency component for each component element that corresponds to the sound source. And, the analysis information calculation unit 912 generates the analysis information indicative of a relation between a plurality of the component elements. The analysis information calculation unit 912 outputs the analysis information corrected so that the quantizing distortion is reduced. The calculation of the analysis information such that the quantizing distortion is reduced is similar to the case of the first configuration example, so its explanation is omitted.

As explained above, in the first configuration example and the second configuration example, the signal analysis unit 900 generates the analysis information so as to reduce an influence of the encoding distortion that occurred in the encoding unit 100. With this, the first configuration example and the second configuration example have an effect that the quantizing distortion that occurs at the moment that the receiving unit 15 performs the decoding can be reduced.

Continuously, a tenth embodiment of the present invention will be explained. The tenth embodiment of the present invention is for controlling the input signal that is configured of the objective sound and the background sound as a sound source. A configuration of the tenth embodiment of the present invention is shown in FIG. 50 and FIG. 51 similarly to that of the ninth embodiment of the present invention. The tenth embodiment differs from the ninth embodiment of the present invention in FIG. 51 in a configuration of an analysis information calculation unit 911. Hereinafter, explanation of a portion which overlaps the portion explained in FIG. 51 is omitted.

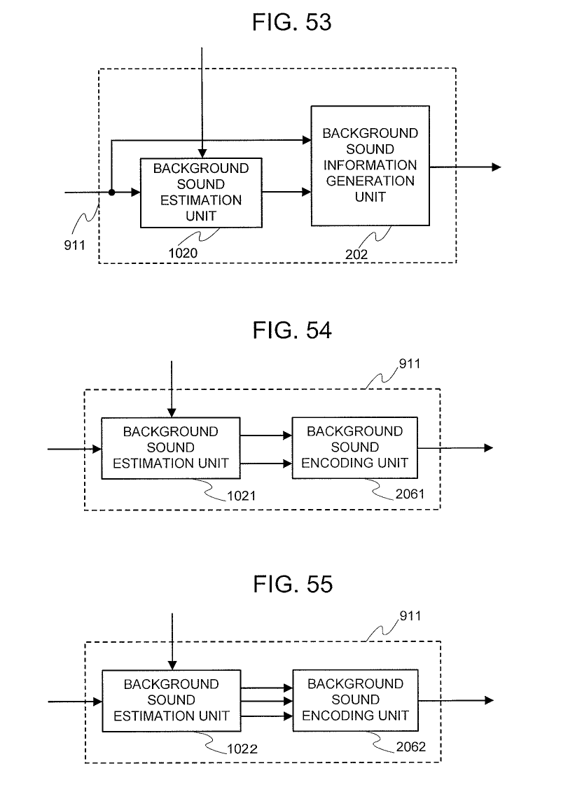

A configuration example of the analysis information calculation unit 911 in the tenth embodiment of the present invention will be explained in details by making a reference FIG. 53. The analysis information calculation unit 911 receives the input signal decomposed into the frequency components and the quantizing distortion quantity of each frequency, and outputs the analysis information. The analysis information calculation unit 911 is configured of a background sound information generation unit 202 and a background sound estimation unit 1020.

The background sound estimation unit 1020 receives the input signal decomposed into the frequency components and the quantizing distortion quantity of each frequency. The background sound estimation unit 1020 estimates the background sound by taking the quantizing distortion quantity into consideration. For example, the background sound estimation unit 1020 may perform a process similar to the process, which the background sound estimation unit 200 being included in the analysis information calculation unit 121 performs, with the background sound obtained by adding the quantizing distortion to the estimated background sound defined as an estimated background sound. The background sound estimation unit 1020 outputs the background sound estimation result in which the quantizing distortion has been taken into consideration to the background sound information generation unit 202. The background sound information generation unit 202 generates the analysis information based upon the background sound estimation result. And, the background sound information generation unit 202 outputs the analysis information in which the quantizing distortion has been taken into consideration. Additionally, the background sound information generation unit 202 may be adapted to output the suppression coefficient, or the information, which is obtained by adding the coefficient correction lower-limit value or both of the coefficient correction lower-limit value and the objective sound existence provability to the signal versus background sound ratio, as analysis information. In this case, the background sound information generation unit 202 is configured of the suppression coefficient calculation units 2011 and 2012 explained in the second embodiment, the suppression coefficient encoding units 2021 and 2022, the signal versus background sound ratio calculation units 203, 2071, and 2072, the signal versus background sound ratio encoding units 2041 and 2042, and so on.

A second configuration example of the analysis information calculation unit 911 of the tenth embodiment of the present invention will be explained in details by making a reference to FIG. 54. In this configuration example, the coefficient correction lower-limit value is calculated as analysis information besides the background sound estimation result. The analysis information calculation unit 911 receives the input signal decomposed into the frequency components and the quantizing distortion quantity of each frequency, and outputs the analysis information. The analysis information calculation unit 911 is configured of a background sound encoding unit 2061 and a background sound estimation unit 1021.

The background sound estimation unit 1021 receives the input signal decomposed into the frequency components and the quantizing distortion quantity of each frequency. The background sound estimation unit 1021 estimates the background sound by taking the quantizing distortion quantity into consideration. For example, the background sound estimation unit 1021 may perform a process similar to the process, which the background sound estimation unit 2051 being included in the analysis information calculation unit 121 performs, with the background sound obtained by adding the quantizing distortion to the estimated background sound defined as an estimated background sound. The background sound estimation unit 1021 outputs the background sound estimation result in which the quantizing distortion has been taken into consideration, and the coefficient correction lower-limit value to the background sound encoding unit 2061. A specific value may be pre-stored in a memory as the coefficient correction lower-limit value in some cases, and the coefficient correction lower-limit value may be calculated responding to the background sound estimation result. Such a calculation includes a manipulation of selecting an appropriate value from among a plurality of values stored in a memory. The coefficient correction lower-limit value should be set so that it is a small value when the background sound estimation result is small. The reason is that the small background sound estimation result signifies that the objective sound is dominant in the input signal, and hence, the distortion hardly occurs at the moment of manipulating the component element. The background sound encoding unit 2061 was already explained by employing FIG. 15.

A third configuration example of the analysis information calculation unit 911 of the tenth embodiment of the present invention will be explained in details by making a reference to FIG. 55. In this configuration example, the coefficient correction lower-limit value and the objective sound existence provability are employed as analysis information besides the background sound estimation result. The analysis information calculation unit 911 receives the input signal decomposed into the frequency components and the quantizing distortion quantity of each frequency, and outputs the analysis information. The analysis information calculation unit 911 is configured of a background sound encoding unit 2062 and a background sound estimation unit 1022.

The background sound estimation unit 1022 receives the input signal decomposed into the frequency components and the quantizing distortion quantity of each frequency. The background sound estimation unit 1022 estimates the background sound by taking the quantizing distortion quantity into consideration. For example, the background sound estimation unit 1022 can perform a process similar to the process, which the background sound estimation unit 2052 being included in the analysis information calculation unit 121 performs, with the background sound obtained by adding the quantizing distortion to the estimated background sound defined as an estimated background sound. The background sound estimation unit 1022 outputs the background sound estimation result in which the quantizing distortion has been taken into consideration, the coefficient correction lower-limit value, and the objective sound existence provability to the background sound encoding unit 2062. The method of setting the coefficient correction lower-limit value was already explained in the second configuration example. The objective sound existence probability can be expressed, for example, with a ratio of the amplitude or the power of the objective sound and the background sound. This ratio itself, a short-time average, a maximum value, a minimum value, and so on may be employed as an objective sound existence probability. The background sound encoding unit 2062 was already explained by employing FIG. 16.

The receiving unit 15 controls the decoded signal based upon the analysis information in which the quantizing distortion has been taken into consideration. This configuration makes it possible to take a high-quality control in which the quantizing distortion has been taken into consideration at the moment of controlling the decoded signal. In addition, this configuration yields an effect that the quantizing distortion, which occurs when the receiving unit 15 performs the decoding, can be reduced.

Above, the tenth embodiment of the present invention is for controlling the decoded signal based upon the coefficient correction lower-limit value or both of the coefficient correction lower-limit value and the objective sound existence provability besides the suppression coefficient in which the quantizing distortion has been taken into consideration, the signal versus background sound ratio, or the background sound. This configuration makes it possible to take a high-quality control in which the quantizing distortion has been taken into consideration at the moment of controlling the decoded signal. In addition, this configuration yields an effect that the quantizing distortion and the encoding distortion, which occur at the moment that the receiving unit 15 performs the decoding, can be reduced.

Next, an eleventh embodiment of the present invention will be explained. The eleventh embodiment of the present invention uses a plurality of conversion units being included in the signal analysis unit 900 and the conversion unit being included in the encoding unit 100 as a common conversion unit, thereby allowing the arithmetic quantity in the transmission side unit, and the arithmetic quantity relating to the control for each component element corresponding to each sound source, which is taken by the receiving side unit based upon the analysis information, to be reduced.

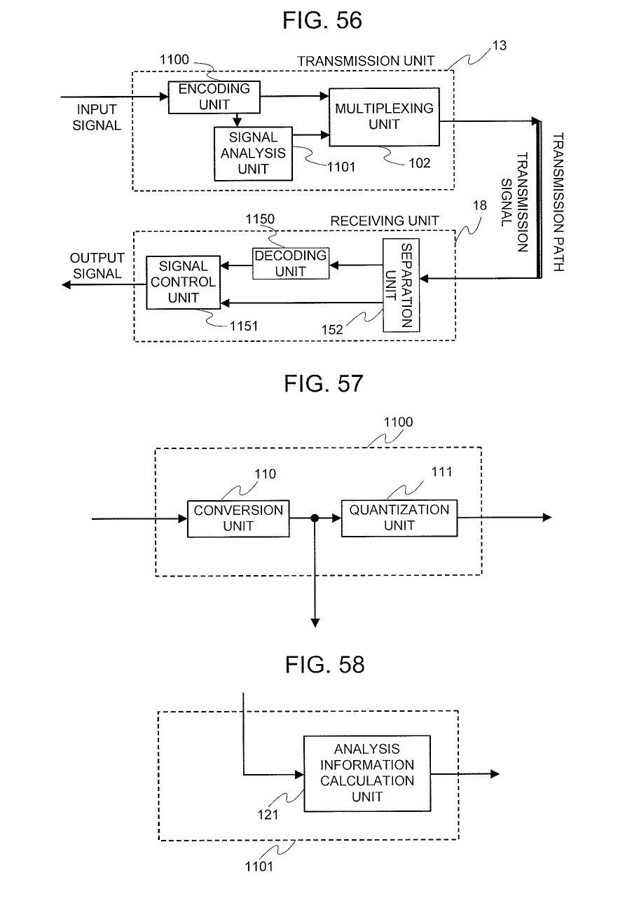

The eleventh embodiment of the present invention will be explained by making a reference to FIG. 56. The eleventh embodiment of the present invention shown in FIG. 56 differs from the first embodiment of the present invention shown in FIG. 1 in a point that the transmission unit 10 is replaced with a transmission unit 13, and a point that the receiving unit 15 is replaced with a receiving unit 18. With this configuration, the eleventh embodiment of the present invention can share the conversion unit existing in the transmission unit, and can share the conversion unit existing in the receiving unit. As a result, the arithmetic quantity of the transmission unit 13 and the receiving unit 18 can be reduced.

The transmission unit 13 shown in FIG. 56 differs from the transmission unit 10 shown in FIG. 1 in a point that the encoding unit 100 is replaced with an encoding unit 1100, and a point that the signal analysis unit 101 is replaced with a signal analysis unit 1101. In this example, the encoding unit 1100 outputs the input signal decomposed into the frequency components to the signal analysis unit 1101.

A configuration example of the encoding unit 1100 will be explained in details by making a reference to FIG. 57. The encoding unit 1100 shown in FIG. 57 differs from the encoding unit 100 shown in FIG. 2 in a point that the first converted signal, being an output of the conversion unit 110, is outputted to the signal analysis unit 1101. An operation of the conversion unit 110 and the quantization unit 111 overlaps the operation explained in FIG. 2, so its explanation is omitted. Herein, the arithmetic quantity of the encoding unit 1100 is almost identical to that of the encoding unit 100 because the encoding unit 1100 differs from the encoding unit 100 shown in FIG. 2 only in the signal being outputted.

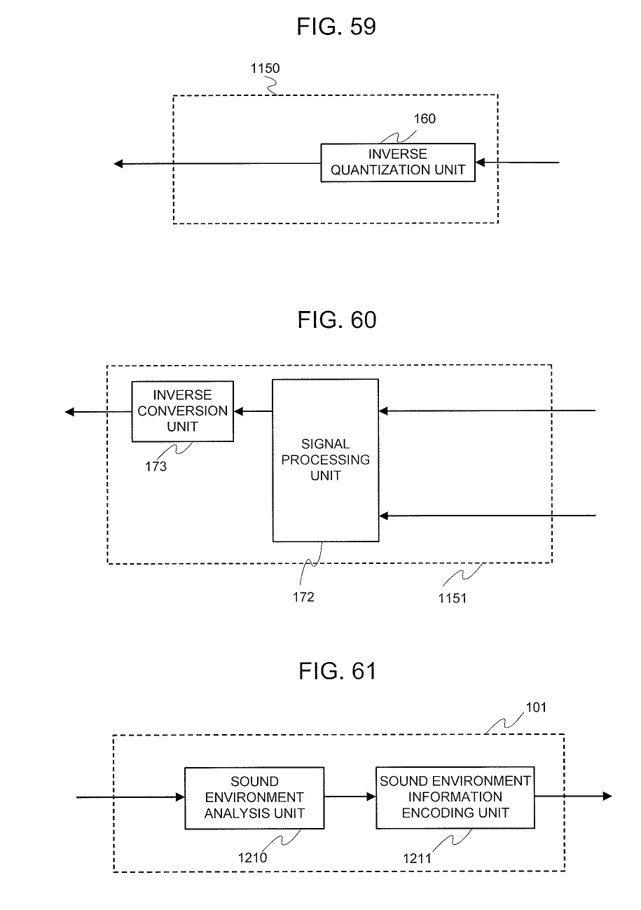

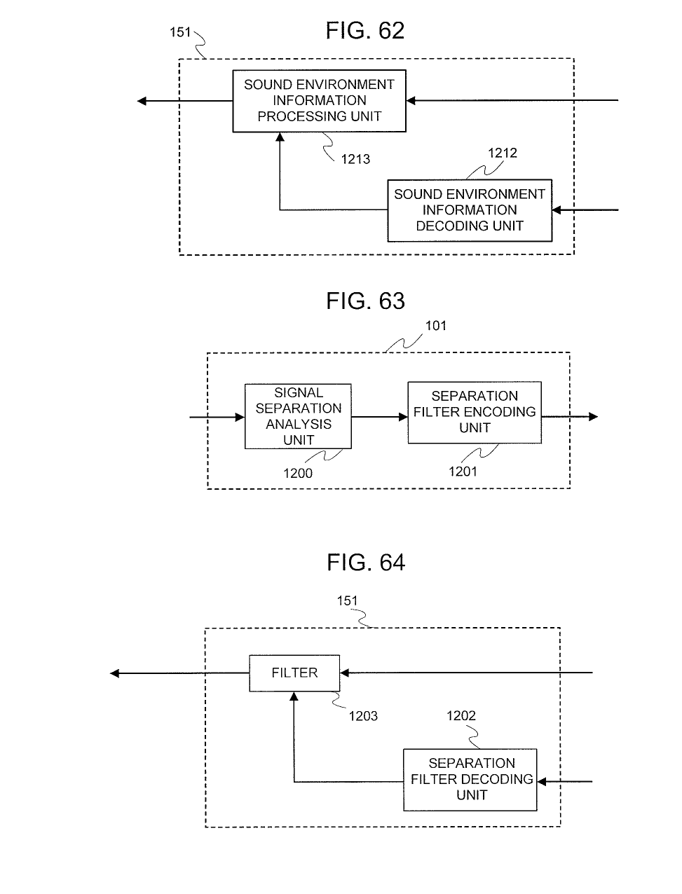

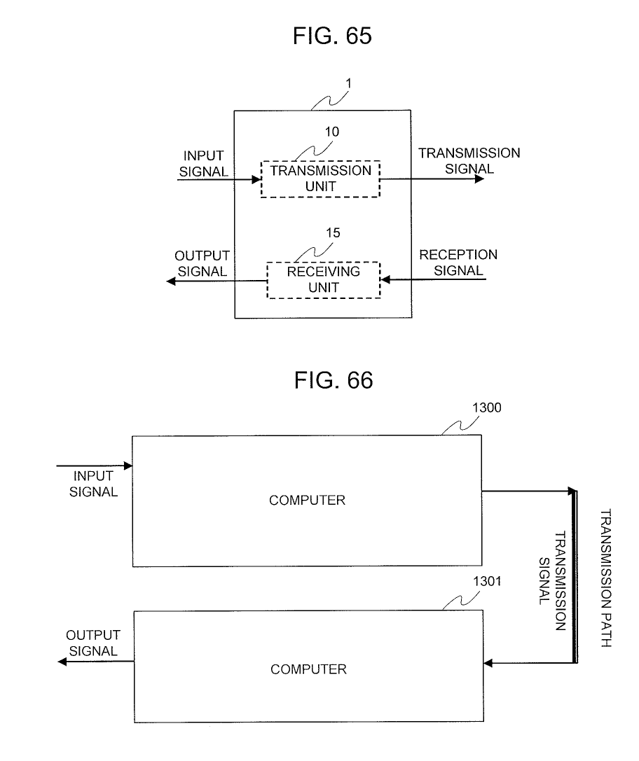

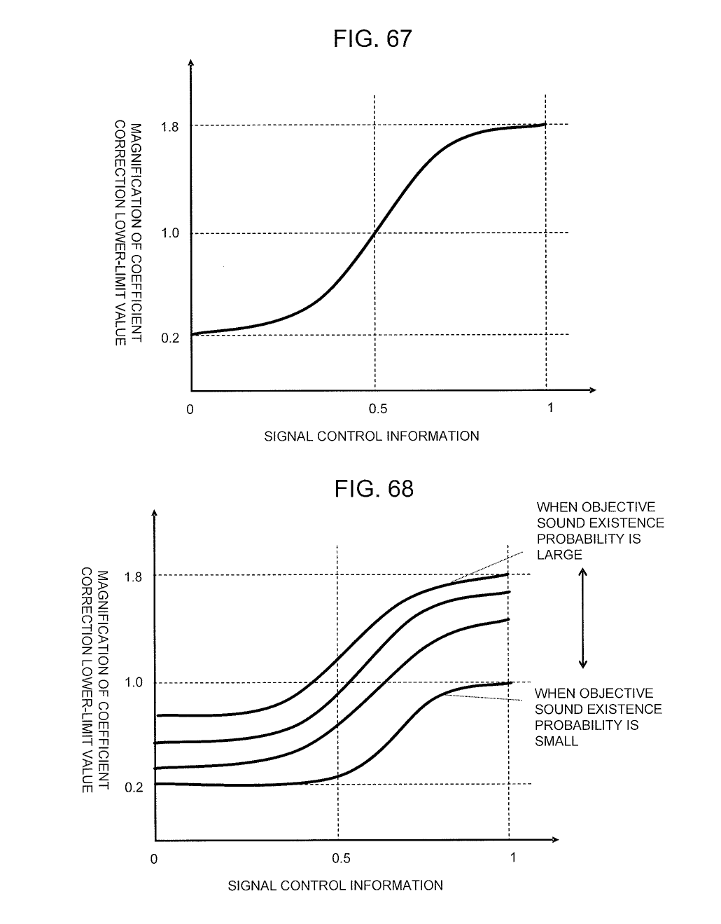

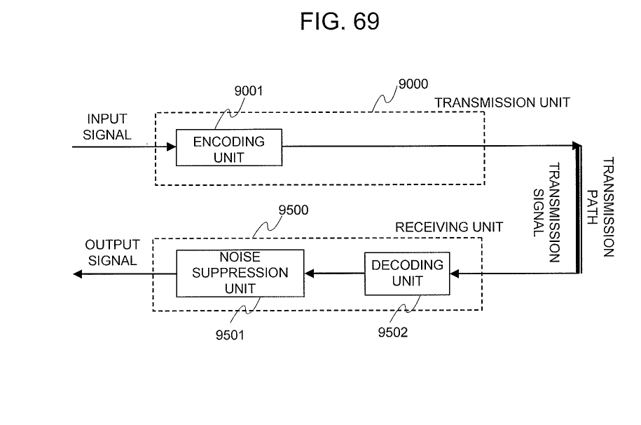

A configuration example of the signal analysis unit 1101 will be explained in details by making a reference to FIG. 58. The signal analysis unit 1101 shown in FIG. 58 differs from the signal analysis unit 101 shown in FIG. 4 in a point that the conversion unit 120 included in the signal analysis unit 101 is deleted.

The signal analysis unit 1101 receives the first converted signal from the encoding unit 1100. The received first converted signal is inputted into the analysis information calculation unit 121. Herein, upon comparing the conversion unit 110 within the encoding unit 1100 shown in FIG. 57 with the conversion unit 120 within the signal analysis unit 101 shown in FIG. 4, the first converted signal, being an output of the former, and the second converted signal, being an output of the latter, become identical to each other when the input signal being supplied to the conversion unit is identical and an operation of the conversion unit is identical. For this, it is possible to delete the conversion unit 120 in the signal analysis unit 1101, and to use the first converted signal being outputted by the signal analysis unit 1101 as the second converted signal when an operation of the conversion unit 110 is identical to that of the conversion unit 120. With this configuration, the arithmetic quantity of the signal analysis unit 1101 is curtailed by a portion equivalent to the arithmetic quantity of the conversion unit 120 as compared with the arithmetic quantity of the signal analysis unit 101. An operation of the analysis information calculation unit 121 overlaps the operation explained in FIG. 4, so its explanation is omitted.

The receiving unit 18 shown in FIG. 56 differs from the receiving unit 15 shown in FIG. 1 in a point that the decoding unit 150 is replaced with a decoding unit 1150, and a point that the signal control unit 151 is replaced with a signal control unit 1151.

A configuration example of the decoding unit 1150 will be explained by making a reference to FIG. 59. The decoding unit 1150 differs from decoding unit 150 shown in FIG. 3 in point that the inverse conversion unit 161 is deleted. An operation of the inverse quantization unit 160 overlap the operation explained in FIG. 3, so its explanation is omitted. In the decoding unit 150 shown in FIG. 3, the inverse conversion unit 161 inverse-converts the first converted signal being outputted by the inverse quantization unit 160 into a time region signal, and outputs it as a decoded signal to the conversion unit 171 shown in FIG. 5. In FIG. 5, the conversion unit 171 performs a process of receiving the decoded signal, and performs a process of converting it into the second converted signal. Herein, as mentioned above, the first converted signal can be used as the second converted signal when an operation of the conversion unit 110 is identical to that of the conversion unit 120. With this, the decoding unit 1150 outputs the first converted signal being outputted by the inverse quantization unit 160 to the signal processing unit 172 being included in the signal control unit 1151 in this embodiment. Thus, in this embodiment, the inverse conversion unit 161 can be deleted.

A configuration example of the signal control unit 1151 will be explained in details by making a reference to FIG. 60. The signal control unit 1151 shown in FIG. 60 differs from the signal control unit 151 shown in FIG. 5 in point that the conversion unit 171 is deleted. An operation of the signal processing unit 172 and the inverse conversion unit 173 overlaps the operation explained in FIG. 5, so its explanation is omitted.

In the signal control unit 151 of FIG. 5, the conversion unit 171 converts the decoded signal inputted as a time region signal into the second converted signal, and outputs it to the signal processing unit 172. As mentioned above, the first converted signal can be used as the second converted signal when an operation of the conversion unit 110 is identical to that of the conversion unit 120. With this, the signal processing unit 172 being included in the signal control unit 1151 can receive the first converted signal being outputted by the inverse quantization unit 160. Thus, in this example, the conversion unit 171 can be deleted.

Herein, upon paying attention to the signal being inputted into the signal control unit 1151 from the decoding unit 1150, it can be seen that a difference between the first embodiment shown in FIG. 1 and the eleventh embodiment shown in FIG. 56 is whether or not the signal being outputted by the inverse quantization unit 160 goes through the inverse conversion unit 161 and the conversion unit 171. When the first converted signal can be used as the second converted signal, the frequency component of the signal being outputted by the inverse quantization unit 160 is identical to the frequency component of the signal being inputted into the signal processing unit 172 in both of the first embodiment and the eleventh embodiment. Thus, the signal processing unit 172 within the signal control unit 1151 outputs a result identical to the result that the signal processing unit 172 shown in FIG. 5 outputs. Further, the arithmetic quantity of the decoding unit 1150 is curtailed by a portion equivalent to the arithmetic quantity of the inverse conversion unit 161 shown in FIG. 3 as compared with the arithmetic quantity of the decoding unit 150. In addition, the arithmetic quantity of the signal control unit 1151 is curtailed by a portion equivalent to the arithmetic quantity of the conversion unit 171 shown in FIG. 5 as compared with the arithmetic quantity of the signal control unit 151.

Above, the eleventh embodiment of the present invention has an effect that the arithmetic quantity is curtailed by a portion equivalent to the respective arithmetic quantities of the conversion unit 120, the inverse conversion unit 161, and the conversion unit 160 as compared with the case of the first embodiment in addition to the effect of the first embodiment of the present invention. In addition, the configuration of the eleventh embodiment capable of curtailing the arithmetic quantity is applicable to the second embodiment to the tenth embodiment. With this, each embodiment has an effect of curtailing the arithmetic quantity that is similar to the effect of the eleventh embodiment of the present invention.

Above, so far, the method of analyzing the input signal that was configured of a plurality of the sound sources, calculating the analysis information, and controlling the decoded signal based upon the analysis information in the receiving side was explained in the first embodiment to the eleventh embodiment of the present invention. Herein, the details will be explained by employing a specific example. As an input signal, for example, there exist sound, musical instrument sound, etc. that differ for each utilization method. In addition to these, operational sound that each machine utters, sound or a foot step of a manipulator, etc. exist in the case of aiming for the monitoring with sound.

The signal analysis control system relating to the present invention is configured to analyze the input signal, and encode the analyzed result as analysis information when a plurality of the component elements exist in the input signal. A configuration similar to the configuration shown in FIG. 1 is applied when a plurality of the component elements exist. The configuration of the signal analysis unit 101 and the signal control unit 151, the information that the signal analysis unit 101 outputs to the multiplexing unit 102, and the information being sent to the signal control unit 151 from the separation unit 152 will be explained in details, respectively.

A second configuration example of the signal analysis unit 101 will be explained in details by making a reference to FIG. 61. The second configuration of the signal analysis unit 101 is applied when a plurality of the component elements exist. This signal analysis unit 101 is configured of a sound environment analysis unit 1210 and a sound environment information encoding unit 1211. The sound environment analysis unit 1210 receives the signal that is configured of a plurality of the elements, and analyzes the information of a plurality of the component elements being included in the input signal. The sound environment analysis unit 1210 outputs the component element analysis information to the sound environment information encoding unit 1211. The sound environment information encoding unit 1211 encodes the component element analysis information inputted from the sound environment analysis unit 1210. And, the sound environment information encoding unit 1211 outputs the encoded component element analysis information to the multiplexing unit 102 shown in FIG. 1. Herein, the multiplexing unit 102 shown in FIG. 1 carries out the multiplexing corresponding to the component element analysis information inputted from the sound environment information encoding unit 1211.

The sound environment analysis unit 1210 will be further explained in details. As a method of analyzing the information of a plurality of the sound sources in the sound environment analysis unit 1210, various methods are employable. For example, as a method of analyzing the information of a plurality of the sound sources, the method of the signal separation disclosed in Non-patent document 11 may be employed. Further, as a method of analyzing the information of a plurality of the sound sources, the method of the signal separation, which is called an auditory scene analysis, a computational auditory scene analysis, a single input signal separation, a single channel signal separation, etc., may be employed. With these methods of the signal separation, the sound environment analysis unit 1210 separates the input signal into a plurality of the component elements. In addition, the sound environment analysis unit 1210 converts each separated component elements into the component element analysis information that should be outputted, and outputs it. This component element analysis information can be outputted in various formats. For example, as component element analysis information, there exist the suppression coefficient for suppressing the background sound, a percentage of each component element in each frequency component, and magnitude of each frequency component of the signal of each component element itself. The percentage of the component element includes, for example, an amplitude ratio with the input signal, an energy ratio with the input signal, an average value, a maximum value and a minimum value thereof, etc. The magnitude of each frequency component of the signal includes, for example, an amplitude absolute value, an energy value, an average value thereof, etc. Further, the analysis result itself that should be outputted, or the signal that can be easily converted into the analysis result that should be outputted can be obtained in a way to the signal separation, depending upon the method of the signal separation. In that case, it is also possible to perform the process of obtaining the analysis result that should be outputted in a way to the signal separation without performing the signal separation to the end.

<Non-patent document 11> Speech Enhancement, Springer, 2005, pp. 371-402

A configuration example of the signal control unit 151 will be explained in details by making a reference to FIG. 62. The configuration example of the signal control unit 151 shown in FIG. 62 is applied when a plurality of the component elements exist. The signal control unit 151 is configured of a sound environment information decoding unit 1212 and a sound environment information processing unit 1213. The signal control unit 151 receives the decoded signal from the decoding unit 150, and the signal of which the analysis information has been encoded from the separation unit 152. The sound environment information decoding unit 1212 receives the encoded analysis information from the separation unit 152, and decodes the analysis information. The sound environment information decoding unit 1212 outputs the decoded analysis information to the sound environment information processing unit 1213. This analysis information is equivalent to the analysis information outputted by the sound environment analysis unit 1210 being included in the signal analysis unit 101 shown in FIG. 61. The sound environment information processing unit 1213 controls the decoded signal based upon the analysis information inputted from the sound environment information decoding unit 1212. This method of the control differs depending upon a purpose of the control. For example, the sound environment information processing unit 1213 may take a control for suppressing the background sound similarly to the case of the second embodiment. Further, the localization can be also modified by emphasizing/attenuating individual component elements by giving a gain hereto, and changing the phase thereof.

Above, when the component elements being included in the input signal exist in plural, applying the present invention yields the effect that is gained in the first embodiment of the present invention.

Above, the first embodiment of the present invention was explained with the configuration, which was applied when the component elements being included in the input signal existed in plural, exemplified. Likewise, a scheme for changing the signal analysis unit, the signal control unit, or the output signal generation unit may be employed for the second embodiment to the eleventh embodiment. Further, like the configurations of the fifth embodiment to the eighth embodiment, the control for localizing the output of each component element to the output signal, which is configured of a plurality of the channels, may be taken.

In addition, when the number of the channels of the input signal is plural, as a technique of the analysis in the signal analysis unit 101 of the present invention, the technique, which is called a directivity control, a beamforming, a blind source separation, or an independent component analysis, may be employed. In particular, when the number of the channels of the input signal is larger than the number of the objective sound, the signal may be analyzed not by employing the above-mentioned method of estimating the background sound information or the method of the analysis being employed in a thirteenth embodiment, but by employing only the directivity control, the beamforming, the blind source separation, or the independent component analysis. For example, the technology relating to the directivity control and the beamforming is disclosed in Non-patent document 12 and Non-patent document 13. Further, the technology relating to the method of the blind source separation and the independent component analysis is disclosed in Non-patent document 14.

<Non-patent document 12> Microphone arrays, Springer, 2001)<

<Non-patent document 13> Speech Enhancement, Springer, 2005, pp. 229-246

<Non-patent document 14> Speech Enhancement, Springer, 2005, pp. 271-369

The configuration shown in FIG. 1 is applied for the first embodiment of the present invention when the foregoing method of the analysis is applied. In addition, the configuration of the signal analysis unit 101, the configuration of the signal control unit 151, the information that the signal analysis unit 101 outputs to the multiplexing unit 102, and the information being sent to the signal control unit 151 from the separation unit 152 will be explained in details. The input signal is a signal of a plurality of the channels. A basic operation, which is similar to the operation of the first embodiment, overlaps the operation explained in FIG. 1, so its explanation is omitted.

A third configuration example of the signal analysis unit 101 will be explained in details by making a reference to FIG. 63. The third configuration example of the signal analysis unit 101 corresponds to the case that the number of the channels of the input signal is plural. The signal analysis unit 101 of this configuration example employs the method of the independent component analysis as a method of analyzing the input signal. The signal analysis unit 101 of this configuration example outputs a filter coefficient for separating the component element corresponding to each sound source being included in the input signal as analysis information.

The signal analysis unit 101 is configured of a signal separation analysis unit 1200 and a separation filter encoding unit 1201. The signal separation analysis unit 1200 calculates a separation filter coefficient with the independent component analysis. The separation filter coefficient is a filter coefficient that is employed for performing the signal separation of the component element corresponding to each sound source being included in the input signal. And, the signal separation analysis unit 1200 outputs the separation filter coefficient to the separation filter encoding unit 1201. The separation filter encoding unit 1201 encodes the separation filter coefficient inputted from the signal separation analysis unit 1200. The separation filter encoding unit 1201 outputs the encoded separation filter coefficient as analysis information.

A third configuration example of the signal control unit 151 will be explained in details by making a reference to FIG. 64. The third configuration example of the signal control unit 151 corresponds to the case that the number of the channels of the input signal is plural.

The signal control unit 151 is configured of a separation filter decoding unit 1202 and a filter 1203. The separation filter decoding unit 1202 receives the encoded separation filter coefficient as analysis information from the separation unit 152. And, the separation filter decoding unit 1202 decodes the encoded separation filter coefficient, and outputs the separation filter coefficient to the filter 1203. The filter 1203 receives the decoded signal of a plurality of the channels from the decoding unit 150, and receives the separation filter coefficient from the separation filter decoding unit 1202. And, the filter 1203 performs the filtering process based upon the separation filter coefficient for the decoded signal of a plurality of the channels. The filter 1203 outputs the signal in which the signal of the component element corresponding to each sound source has been separated.

As explained above, in the signal analysis control system of the present invention, the transmission unit analyzes the input signal when the number of the channels of the input signal is plural. This configuration enables the receiving unit to control the input signal, which is configured of a plurality of the sound sources, for each component element corresponding to each sound source based upon the information of the signal analysis made by the transmission unit also when the number of the channels of the input signal is plural. In addition, the receiving unit can curtail the arithmetic quantity relating to the signal analysis because the transmission unit analyzes the signal.

Further, while the filter coefficient of the separation filter was employed as analysis information of the input signal in the configuration examples shown in FIG. 63 and FIG. 64, the analysis information employed in the first embodiment to the eleventh embodiment may be employed. For this, it is enough for the signal separation analysis unit 1200 shown in FIG. 63 to be configured so as to calculate the separation filter coefficient, and to perform the signal separation employing the separation filter. With this, the separation filter encoding unit 1201 is configured of the sound environment information encoding unit 1211 shown in FIG. 61.

In addition, not only of the method of the independent component analysis but also the methods disclosed in the Non-patent documents 12 to 15 may be employed as a method of analyzing the input signal in the signal analysis unit 101. Further, these methods of the analysis may be combined with the methods of the analysis in the first embodiment to the eleventh embodiment of the present invention, and employed. In addition, the analysis result that should be outputted, or the signal that can be easily converted into the analysis result that should be outputted can be obtained in a way to the analysis, depending upon the method of the analysis. In that case, the process of the analysis may be changed so that the analysis result is outputted without the analysis performed to the end.

A twelfth embodiment of the present invention will be explained by making a reference to FIG. 65. Only One-way communication was taken into consideration in the embodiments ranging from the first embodiment up to the eleventh embodiment. That is, the communication between the transmission unit integrally built in a terminal and the receiving unit integrally built in another terminal was explained. In the twelfth embodiment, which takes bilateral communication into consideration, both of the transmission unit and the receiving unit for which the present invention has been applied are integrally built in one transmission/reception terminal. As a terminal having both of the transmission unit and the receiving unit integrally built therein, for which the present invention has been applied, a combination of any of the transmission units of the first embodiment to the eleventh embodiment, and any of the receiving units of the first embodiment to the eleventh embodiment may be employed. In the twelfth embodiment of the present invention, incorporating both of the transmission unit and the receiving unit into the terminal yields an effect of the present invention at the moment of utilizing it for the bilateral communication apparatuses such as a television conference terminal and a mobile telephone.

The signal analysis control system of the present invention is applicable in the case that the one-way sound communication is made, for example, in the case of a broadcast. It is enough for the transmission terminal of a broadcast station to have, for example, at least the transmission unit 10 shown in FIG. 1. The so-called broadcast station includes not only a licensed broadcast station but also a point in which sound is transmitted and no reception is almost performed, for example, a main site of a multi-point television conference. Any of the transmission units of the second embodiment to the eleventh embodiment of the present invention may be employed for this transmission terminal.

Further, the signal analysis control system of the present invention is applicable to a point as well in which only the reception is performed. It is enough for the reception terminal in a point in which only the reception is performed to have, for example, at least the receiving unit 15 shown in FIG. 1. Any of the receiving units of the second embodiment to the eleventh embodiment of the present invention may be employed for this reception terminal.

In addition, the signal process apparatus based upon the thirteenth embodiment of the present invention will be explained in details by making a reference to FIG. 66. The thirteenth embodiment of the present invention is configured of computers 1300 and 1301 each of which operates under a program control. The computer could be any of a central processing apparatus, a processor, and a data processing apparatus.

The computer 1300, which performs a process relating to any of the first embodiment to the twelfth embodiment, operates based upon a program for receiving the input signal and outputting the transmission signal. On the other hand, the computer 1301, which performs a process relating to any of the first embodiment to the twelfth embodiment, operates based upon a program for receiving the transmission signal and outputting the output signal. Additionally, in the case of having both of the transmission unit and receiving unit explained in the twelfth embodiment, the transmission process and the reception process may be executed by employing the identical computer.

While in the first embodiment to the thirteenth embodiment explained above, the operations of the transmission unit, the transmission path, and the receiving unit were exemplified, they may be replaced with the recoding unit, the storage medium, and the reproduction unit, respectively. For example, the transmission unit 10 shown in FIG. 1 may output the transmission signal as a bit stream to the storage medium, and record the bit stream into the storage medium. Further, the receiving unit 15 may take out the bit stream recorded into the storage medium, and generate the output signal by decoding the bit stream and performing a process therefor.

The 1st mode of the present invention is characterized in that a signal analysis method, comprising: generating analysis information including component element control information for controlling a component element of a signal including a plurality of component elements and a correction value for correcting said component element control information; and multiplexing said signal and said analysis information and generating a multiplexed signal.

The 2nd mode of the present invention, in the above-mentioned mode, is characterized in that said correction value is a lower-limit value of said component element control information.

The 3rd mode of the present invention, in the above-mentioned mode, is characterized in that said correction value is an upper-limit value of said component element control information.

The 4th mode of the present invention, in the above-mentioned modes, is characterized in that said plurality of component elements include a main signal and a background signal.

The 5th mode of the present invention, in the above-mentioned modes, is characterized in that said component element control information includes a suppression coefficient for suppressing said background signal.

The 6th mode of the present invention, in the above-mentioned modes, is characterized in that said component element control information includes a signal versus background signal ratio.

The 7th mode of the present invention, in the above-mentioned modes, is characterized in that said component element control information includes an estimated background signal.

The 8th mode of the present invention, in the above-mentioned modes, is characterized in that said analysis information includes a main signal existence probability.

The 9th mode of the present invention is characterized in that a signal control method, comprising: receiving a multiplexed signal including a signal including a plurality of component elements, and analysis information including component element control information for controlling a component element of said signal and a correction value for correcting said component element control information; generating said signal and said analysis information from said multiplexed signal; correcting said component element control information based upon said correction value; and controlling the component element of said signal based upon said corrected component element control information.

The 10th mode of the present invention, in the above-mentioned modes, is characterized in that a signal control method, comprising: receiving a multiplexed signal including a signal including a plurality of component elements, and analysis information including component element control information for controlling a component element of said signal and a correction value for correcting said component element control information, and component element rendering information; generating said signal and said analysis information from said multiplexed signal; correcting said component element control information based upon said correction value being included in said analysis information; and controlling the component element of said signal based upon said corrected component element control information and said component element rendering information.

The 11th mode of the present invention, in the above-mentioned modes, is characterized in that said correction value is a lower-limit value of said component element control information.

The 12th mode of the present invention, in the above-mentioned modes, is characterized in that said correction value is an upper-limit value of said component element control information.

The 13th mode of the present invention, in the above-mentioned modes, is characterized in that said A signal control method comprising: further receiving signal control information, and modifying said correction value; and correcting said component element control information based upon said modified correction value.

The 14th mode of the present invention, in the above-mentioned modes, is characterized in that said plurality of component elements include a main signal and a background signal.

The 15th mode of the present invention, in the above-mentioned modes, is characterized in that said component element control information includes a suppression coefficient.

The 16th mode of the present invention, in the above-mentioned modes, is characterized in that said component element control information includes a signal versus background sound ratio.

The 17th mode of the present invention, in the above-mentioned modes, is characterized in that said component element control information includes estimated background sound.

The 17th mode of the present invention, in the above-mentioned modes, is characterized in that said analysis information includes a main signal existence probability.

The 19th mode of the present invention is characterized in that a signal analysis control method, comprising: generating analysis information including component element control information for controlling a component element of a signal including a plurality of component elements and a correction value for correcting said component element control information; multiplexing said signal and said analysis information, and generating a multiplexed signal; receiving said multiplexed signal; generating said signal and said analysis information from said multiplexed signal; correcting said component element control information based upon said correction value; and controlling the component element of said signal based upon said corrected component element control information.

The 20th mode of the present invention is characterized in that a signal analysis control method, comprising: generating analysis information including component element control information for controlling a component element of a signal including a plurality of component elements and a correction value for correcting said component element control information; multiplexing said signal and said analysis information, and generating a multiplexed signal; receiving said multiplexed signal and component element rendering information; generating said signal and said analysis information from said multiplexed signal; correcting said component element control information based upon said correction value; and controlling the component element of said signal based upon said corrected component element control information and said component element rendering information.

The 21st mode of the present invention is characterized in that a signal analysis apparatus, comprising: a signal analysis unit for generating analysis information including component element control information for controlling a component element of a signal including a plurality of component elements and a correction value for correcting said component element control information; and a multiplexing unit for multiplexing said signal and said analysis information and generating a multiplexed signal.

The 22nd mode of the present invention, in the above-mentioned modes, is characterized in that said correction value is a lower-limit value of said component element control information.

The 23rd mode of the present invention, in the above-mentioned modes, is characterized in that said correction value is an upper-limit value of said component element control information.

The 24th mode of the present invention, in the above-mentioned modes, is characterized in that said plurality of component elements include a main signal and a background signal.

The 25th mode of the present invention, in the above-mentioned modes, is characterized in that said component element control information includes a suppression coefficient for suppressing said background signal.

The 26th mode of the present invention, in the above-mentioned modes, is characterized in that said component element control information includes a signal versus sound signal ratio.

The 27th mode of the present invention, in the above-mentioned modes, is characterized in that said component element control information includes an estimated background signal.

The 28th mode of the present invention, in the above-mentioned modes, is characterized in that said analysis information includes a main signal existence probability.

The 29th mode of the present invention is characterized in that a signal control apparatus, comprising: a multiplexed signal separation unit for, from a multiplexed signal including a signal including a plurality of component elements, and analysis information including component element control information for controlling a component element of said signal and a correction value for correcting said component element control information, generating said signal and said analysis information; a component element control information correction unit for correcting said component element control information based upon said correction value; and a signal control unit for controlling the component element of said signal based upon said corrected component element control information.

The 30th mode of the present invention is characterized in that a signal control apparatus, comprising: a multiplexed signal separation unit for, from a multiplexed signal including a signal including a plurality of component elements, and analysis information including component element control information for controlling a component element of said signal and a correction value for correcting said component element control information, generating said signal and said analysis information; a component element control information correction unit for correcting said component element control information based upon said correction value being included in said analysis information; and a signal control unit for receiving component element rendering information, and controlling the component element of said signal based upon said corrected component element control information and said component element rendering information.

The 31st mode of the present invention, in the above-mentioned modes, is characterized in that said correction value is a lower-limit value of said component element control information.

The 32nd mode of the present invention, in the above-mentioned modes, is characterized in that said correction value is an upper-limit value of said component element control information.

The 33rd mode of the present invention, in the above-mentioned modes, is characterized in that said component element control information correction unit further receives signal control information, modifies said correction value, and corrects said component element control information based upon said modified correction value.

The 34th mode of the present invention, in the above-mentioned modes, is characterized in that said plurality of component elements include a main signal and a background signal.

The 35th mode of the present invention, in the above-mentioned modes, is characterized in that said component element control information includes a suppression coefficient.

The 36th mode of the present invention, in the above-mentioned modes, is characterized in that said component element control information includes a signal versus background sound ratio.

The 37th mode of the present invention, in the above-mentioned modes, is characterized in that said component element control information includes estimated background sound.

The 38th mode of the present invention, in the above-mentioned modes, is characterized in that said analysis information includes a main signal existence probability.

The 39th mode of the present invention is characterized in that a signal analysis control system including a signal analysis apparatus and a signal control apparatus: wherein said signal analysis apparatus comprises: a signal analysis unit for generating analysis information including component element control information for controlling a component element of a signal including a plurality of component elements and a correction value for correcting said component element control information; and a multiplexing unit for multiplexing said signal and said analysis information and generating a multiplexed signal; and wherein said signal control apparatus comprises: a multiplexed signal separation unit for generating said signal and said analysis information from said multiplexed signal; a component element control information correction unit for correcting said component element control information based upon said correction value; and a signal control unit for controlling the component element of said signal based upon said corrected component element control information.

The 40th mode of the present invention is characterized in that a signal analysis control system including a signal analysis apparatus and a signal control apparatus: wherein said signal analysis apparatus comprises: a signal analysis unit for generating analysis information including component element control information for controlling a component element of a signal including a plurality of component elements and a correction value for correcting said component element control information; and a multiplexing unit for multiplexing said signal and said analysis information, and generating a multiplexed signal; and wherein said signal control apparatus comprises: a multiplexed signal separation unit for generating said signal and said analysis information from said multiplexed signal; a component element control information correction unit for correcting said component element control information based upon said correction value; and a signal control unit for receiving component element rendering information, and controlling the component element of said signal based upon said corrected component element control information and said component element rendering information.

The 41st mode of the present invention is characterized in that a signal analysis program for causing a computer to execute: a signal analysis process of generating analysis information including component element control information for controlling a component element of a signal including a plurality of component elements and a correction value for correcting said component element control information; and a multiplexing process of multiplexing said signal and said analysis information and generating a multiplexed signal.

The 42nd mode of the present invention, in the above-mentioned modes, is characterized in that said correction value is a lower-limit value of said component element control information.

The 43rd mode of the present invention, in the above-mentioned modes, is characterized in that said correction value is an upper-limit value of said component element control information.

The 44th mode of the present invention, in the above-mentioned modes, is characterized in that said plurality of component elements include a main signal and a background signal.

The 45th mode of the present invention, in the above-mentioned modes, is characterized in that said component element control information includes a suppression coefficient for suppressing said background signal.

The 46th mode of the present invention, in the above-mentioned modes, is characterized in that said component element control information includes a signal versus background signal ratio.

The 47th mode of the present invention, in the above-mentioned modes, is characterized in that said component element control information includes an estimated background signal.

The 45th mode of the present invention, in the above-mentioned modes, is characterized in that said analysis information includes a main signal existence probability.

The 49th mode of the present invention is characterized in that a signal control program causing a computer to execute: a multiplexed signal separation process of, from a multiplexed signal including a signal including a plurality of component elements, and analysis information including component element control information for controlling a component element of said signal and a correction value for correcting said component element control information, generating said signal and said analysis information; a component element control information correction process of correcting said component element control information based upon said correction value; and a signal control process of controlling the component element of said signal based upon said corrected component element control information.

The 50th mode of the present invention is characterized in that a signal control program for causing a computer to execute: a multiplexed signal separation process of, from a multiplexed signal including a signal including a plurality of component elements, and analysis information including component element control information for controlling a component element of said signal and a correction value for correcting said component element control information, generating said signal and said analysis information; a component element control information correction process of correcting said component element control information based upon said correction value being included in said analysis information; and a signal control process of receiving component element rendering information, and controlling the component element of said signal based upon said corrected component element control information and said component element rendering information.

The 51st mode of the present invention, in the above-mentioned modes, is characterized in that said correction value is a lower-limit value of said component element control information.

The 52nd mode of the present invention, in the above-mentioned modes, is characterized in that said correction value is an upper-limit value of said component element control information.

The 53rd mode of the present invention, in the above-mentioned modes, is characterized in that said component element control information correction process further receives signal control information, modifies said correction value, and corrects said component element control information based upon said modified correction value.

The 54th mode of the present invention, in the above-mentioned modes, is characterized in that said plurality of component elements include a main signal and a background signal.

The 55th mode of the present invention, in the above-mentioned modes, is characterized in that said component element control information includes a suppression coefficient.

The 56th mode of the present invention, in the above-mentioned modes, is characterized in that said component element control information includes a signal versus background sound ratio.

The 57th mode of the present invention, in the above-mentioned modes, is characterized in that said component element control information includes estimated background sound.

The 58th mode of the present invention, in the above-mentioned modes, is characterized in that said analysis information includes a main signal existence probability.

The 59th mode of the present invention is characterized in that a signal analysis control program for causing a computer to execute: a signal analysis process of generating analysis information including component element control information for controlling a component element of a signal including a plurality of component elements and a correction value for correcting said component element control information; a multiplexing process of multiplexing said signal and said analysis information, and generating a multiplexed signal; a multiplexed signal separation process of generating said signal and said analysis information from said multiplexed signal; a component element control information correction process of correcting said component element control information based upon said correction value; and a signal control process of controlling the component element of said signal based upon said corrected component element control information.

The 60th mode of the present invention, in the above-mentioned modes, is characterized in that a signal analysis control program for causing a computer to execute: a signal analysis process of generating analysis information including component element control information for controlling a component element of a signal including a plurality of component elements and a correction value for correcting said component element control information; a multiplexing process of multiplexing said signal and said analysis information, and generating a multiplexed signal; a multiplexed signal separation unit for generating said signal and said analysis information from said multiplexed signal; a component element control information correction process of correcting said component element control information based upon said correction value; and a signal control process of receiving component element rendering information, and controlling the component element of said signal based upon said corrected component element control information and said component element rendering information.

Above, although the present invention has been particularly described with reference to the preferred embodiments, examples and modes thereof, it should be readily apparent to those of ordinary skill in the art that the present invention is not always limited to the above-mentioned embodiment and modes, and changes and modifications in the form and details may be made without departing from the spirit and scope of the invention.

This application is based upon and claims the benefit of priority from Japanese patent application No. 2008-3933, filed on Jan. 11, 2008, the disclosure of which is incorporated herein in its entirety by reference.

### APPLICABILITY IN INDUSTRY

The present invention may be applied to an apparatus that performs signal analysis or signal control. The present invention may also be applied to a program that causes a computer to execute signal analysis or signal control.

1. A signal analysis method, comprising:
generating analysis information including component element control information for controlling a component element of a signal including a plurality of component elements and a correction value for correcting said component element control information; and
transmitting said signal and said analysis information.

2. A signal analysis method according to claim 1, wherein said correction value is a lower-limit value of said component element control information.

3. (canceled)

4. A signal analysis method according to claim 1, wherein said plurality of component elements include a main signal and a background signal.

5. A signal analysis method according to claim 4, wherein said component element control information includes a suppression coefficient for suppressing said background signal.

6. (canceled)

7. (canceled)

8. (canceled)

9. A signal control method, comprising:
receiving a signal including a plurality of component elements, and analysis information including component element control information for controlling a component element of said signal and a correction value for correcting said component element control information;
correcting said component element control information based upon said correction value; and
controlling the component element of said signal based upon said corrected component element control information.

10. A signal control method, comprising:
receiving a multiplexed signal including a signal including a plurality of component elements, and analysis information including component element control information for controlling a component element of said signal and a correction value for correcting said component element control information, and component element rendering information;
generating said signal and said analysis information from said multiplexed signal;
correcting said component element control information based upon said correction value being included in said analysis information; and
controlling the component element of said signal based upon said corrected component element control information and said component element rendering information.

11. A signal control method according to claim 9, wherein said correction value is a lower-limit value of said component element control information.

12. (canceled)

13. A signal control method according to claim 9, comprising:
further receiving signal control information, and modifying said correction value; and
correcting said component element control information based upon said modified correction value.

14. A signal control method according to claim 9, wherein said plurality of component elements include a main signal and a background signal.

15. A signal control method according to claim 14, wherein said component element control information includes a suppression coefficient.

16. (canceled)

17. (canceled)

18. (canceled)

19. (canceled)

20. (canceled)

21. A signal analysis apparatus, comprising:
a signal analysis unit that generates analysis information including component element control information for controlling a component element of a signal including a plurality of component elements and a correction value for correcting said component element control information; and
a transmission unit that transmits said signal and said analysis information.

22. A signal analysis apparatus according to claim 21, wherein said correction value is a lower-limit value of said component element control information.

23. (canceled)

24. A signal analysis apparatus according to claim 20, wherein said plurality of component elements include a main signal and a background signal.

25. A signal analysis apparatus according to claim 24, wherein said component element control information includes a suppression coefficient for suppressing said background signal.

26. (canceled)

27. (canceled)

28. (canceled)

29. A signal control apparatus, comprising:
a receiving unit that receives a signal including a plurality of component elements, and analysis information including component element control information for controlling a component element of said signal and a correction value for correcting said component element control information;
a component element control information correction unit that corrects said component element control information based upon said correction value; and
a signal control unit that controls the component element of said signal based upon said corrected component element control information.

30. A signal control apparatus, comprising:
a multiplexed signal separation unit that, from a multiplexed signal including a signal including a plurality of component elements, and analysis information including component element control information for controlling a component element of said signal and a correction value for correcting said component element control information, generates said signal and said analysis information;
a component element control information correction unit that corrects said component element control information based upon said correction value being included in said analysis information; and
a signal control unit that receives component element rendering information, and controlling the component element of said signal based upon said corrected component element control information and said component element rendering information.

31. A signal control apparatus according to claim 29, wherein said correction value is a lower-limit value of said component element control information.

32. (canceled)

33. A signal control apparatus according to one of claim 29, wherein said component element control information correction unit further receives signal control information, modifies said correction value, and corrects said component element control information based upon said modified correction value.

34. A signal control apparatus according to one of claim 29, wherein said plurality of component elements include a main signal and a background signal.

35. A signal control apparatus according to claim 34, wherein said component element control information includes a suppression coefficient.

36. (canceled)

37. (canceled)

38. (canceled)

39. (canceled)

40. (canceled)

41. A non-transitory computer readable storage medium storing signal analysis program for causing a computer to execute:
a signal analysis process of generating analysis information including component element control information for controlling a component element of a signal including a plurality of component elements and a correction value for correcting said component element control information; and
a process of transmitting said signal and said analysis information.

42. A non-transitory computer readable storage medium storing signal analysis program according to claim 41, wherein said correction value is a lower-limit value of said component element control information.

43. (canceled)

44. A non-transitory computer readable storage medium storing signal analysis program according to claim 41, wherein said plurality of component elements include a main signal and a background signal.

45. A non-transitory computer readable storage medium storing signal analysis program according to claim 44, wherein said component element control information includes a suppression coefficient for suppressing said background signal.

46. (canceled)

47. (canceled)

48. (canceled)

49. A non-transitory computer readable storage medium storing signal control program causing a computer to execute:
a process of receiving a signal including a plurality of component elements, and analysis information including component element control information for controlling a component element of said signal and a correction value for correcting said component element control information;
a component element control information correction process of correcting said component element control information based upon said correction value; and
a signal control process of controlling the component element of said signal based upon said corrected component element control information.

50. A non-transitory computer readable storage medium storing signal control program for causing a computer to execute:
a multiplexed signal separation process of, from a multiplexed signal including a signal including a plurality of component elements, and analysis information including component element control information for controlling a component element of said signal and a correction value for correcting said component element control information, generating said signal and said analysis information;
a component element control information correction process of correcting said component element control information based upon said correction value being included in said analysis information; and
a signal control process of receiving component element rendering information, and controlling the component element of said signal based upon said corrected component element control information and said component element rendering information.

51. A non-transitory computer readable storage medium storing signal control program according to claim 49, wherein said correction value is a lower-limit value of said component element control information.

52. (canceled)

53. A non-transitory computer readable storage medium storing signal control program according to one of claim 49, wherein said component element control information correction process further receives signal control information, modifies said correction value, and corrects said component element control information based upon said modified correction value.

54. A non-transitory computer readable storage medium storing signal control program according to one of claim 49, wherein said plurality of component elements include a main signal and a background signal.

55. A non-transitory computer readable storage medium storing signal control program according to claim 54, wherein said component element control information includes a suppression coefficient.

56. (canceled)

57. (canceled)

58. (canceled)

59. (canceled)

60. (canceled)

61. A signal control method according to claim 10, wherein said correction value is a lower-limit value of said component element control information.

62. A signal control method according to claim 10, comprising:
further receiving signal control information, and modifying said correction value; and
correcting said component element control information based upon said modified correction value.

63. A signal control method according to claim 10, wherein said plurality of component elements include a main signal and a background signal.

64. A signal control method according to claim 10, wherein said component element control information includes a suppression coefficient.

65. A signal control apparatus according to claim 30, wherein said correction value is a lower-limit value of said component element control information.

66. A signal control apparatus according to claim 30, wherein said component element control information correction unit further receives signal control information, modifies said correction value, and corrects said component element control information based upon said modified correction value.

67. A signal control apparatus according to claim 30, wherein said plurality of component elements include a main signal and a background signal.

68. A signal control apparatus according to claim 67, wherein said component element control information includes a suppression coefficient.

69. A non-transitory computer readable storage medium storing signal control program according to claim 50, wherein said correction value is a lower-limit value of said component element control information.

70. A non-transitory computer readable storage medium storing signal control program according to one of claim 50, wherein said component element control information correction process further receives signal control information, modifies said correction value, and corrects said component element control information based upon said modified correction value.

71. A non-transitory computer readable storage medium storing signal control program according to one of claim 50, wherein said plurality of component elements include a main signal and a background signal.

72. A non-transitory computer readable storage medium storing signal control program according to claim 71, wherein said component element control information includes a suppression coefficient.
